(19) United States
(12) Patent Application Publication
(10) Pub. No.: US 2017/0059990 A1
(43) Pub. Date: Mar. 2, 2017

(54) RADIATION-SENSITIVE OR ACTINIC RAY-SENSITIVE RESIN COMPOSITION, RESIST FILM USING THE SAME, MASK BLANK, RESIST PATTERN FORMING METHOD, ELECTRONIC DEVICE MANUFACTURING METHOD, AND ELECTRONIC DEVICE

(71) Applicant: FUJIFILM Corporation, Tokyo (JP)

(72) Inventor: Tomotaka TSUCHIMURA, Shizuoka (JP)

(73) Assignee: FUJIFILM Corporation, Tokyo (JP)

(21) Appl. No.: 15/352,662

(22) Filed: Nov. 16, 2016

Related U.S. Application Data
(63) Continuation of application No. PCT/JP2015/065083, filed on May 26, 2015.

(30) Foreign Application Priority Data
Jun. 19, 2014 (JP) 2014-126652

(51) Int. Cl. G03F 7/038; G03F 7/20; G03F 1/22; G03F 7/16; G03F 1/20; G03F 7/32; C08F 212/14

(52) U.S. Cl. CPC G03F 7/0382; G03F 7/322; G03F 7/2004; G03F 7/2037; C08F 212/14; G03F 7/162; G03F 1/20; G03F 1/22

(57) ABSTRACT

A radiation-sensitive or actinic ray-sensitive resin composition contains a polymer compound (A) including a structural part (a) that is decomposed by irradiation with actinic rays or radiation to generate an acid anion on a side chain and a repeating unit (b) that is represented by the following Formula (I), in the formula, R₃ represents a hydrogen atom, an organic group, or a halogen atom, A₁ represents an aromatic ring group or an alicyclic group. R₁ and R₂ each independently represent an alkyl group, a cycloalkyl group, or an aryl group, at least two of A₁, R₁, or R₂ may be bonded to each other to form a ring. B₁ and L₁ each independently represent a single bond or a divalent linking group, X represents a hydrogen atom or an organic group, n represents an integer of 1 or greater.

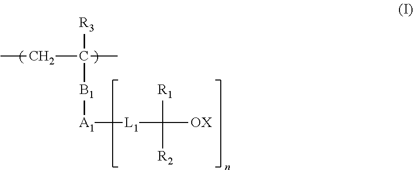

### CROSS-REFERENCE TO RELATED APPLICATIONS

This application is a Continuation of PCT International Application No. PCT/JP2015/065083 filed on May 26, 2015, which claims priority under 35 U.S.C §119(a) to Japanese Patent Application No. 2014-126652 filed on Jun. 19, 2014. Each of the above application(s) is hereby expressly incorporated by reference, in its entirety, into the present application.

### BACKGROUND OF THE INVENTION

1. Field of the Invention

The present invention relates to a radiation-sensitive or actinic ray-sensitive resin composition that is suitable for use in an ultramicro-lithographic process that can be applied to manufacturing processes for manufacturing a VLSI or a high-capacity microchip, nanoimprint mold forming processes, high-density information recording medium manufacturing processes, and the like, and in other photofabrication processes, and is capable of forming a high-definition pattern using electron beams or extreme ultraviolet rays, a resist film using the radiation-sensitive or actinic ray-sensitive resin composition, a mask blank, a resist pattern forming method, an electronic device manufacturing method, and an electronic device.

2. Description of the Related Art

In the past, fine processing by lithography using a photoresist composition has been performed in a process of manufacturing an electronic device such as an IC or a LSI. In recent years, with an increase in the integration degree of an integrated circuit, the formation of an ultrafine pattern has been required in the sub-micron or quarter-micron region. Together with this requirement, the exposure wavelength has also tended to become shorter, for example, from g line to i line or further to excimer laser light. At present, development of lithography using electron beams or X-rays is proceeding.

Particularly, electron or extreme ultraviolet lithography is positioned as a next-generation or next-next-generation pattern formation technology, and is widely used for high resolution in the formation of a photo mask that is used in semiconductor exposure. For example, in the process of forming a photo mask by electron lithography, a resist layer is formed on a shielding substrate in which a transparent substrate is provided with a shielding layer mainly containing chromium, exposure to electron beams is selectively further performed, and then alkali development is performed to form a resist pattern. Next, the shielding layer is subjected to etching using the resist pattern as a mask to form a pattern on the shielding layer, and thus it is possible to obtain a photo mask in which the shielding layer having a predetermined pattern is provided on the transparent substrate.

However, since batch exposure cannot be performed with electron beams unlike with ultraviolet rays, a highly-sensitive resist is required to shorten the processing time, and as a resist suitable for electron lithography, a so-called positive tone resist composition obtained by combining an acid decomposable polymer compound and a photoacid generator, or a so-called negative tone resist composition obtained by combining a crosslinking polymer compound and a crosslinking agent is effectively used.

For example, in JP2013-164588A, a chemically amplified negative resist composition that contains an acid generator and a polymer compound containing repeating units in which an acid releasable group causes an elimination reaction by the action of acid to induce a crosslinking reaction between polymers is described.

In JP2013-254081A, a chemically amplified resist composition that contains a polymer compound having a structural part that is decomposed by irradiation with actinic rays or radiation to generate an acid anion on a side chain, a repeating unit having a phenolic hydroxyl group, and a repeating unit having an acid-crosslinking group is described.

### SUMMARY OF THE INVENTION

However, regarding the chemically amplified negative tone resist compositions described in JP2013-164588A and JP2013-254081A, there is room for further improvement to achieve extreme excellence in all of sensitivity, resolving power, pattern shape, line edge roughness (LER) performance, scum reducing property, PEB time dependence, PED stability (coating stability in a case where the coating is left after irradiation with actinic rays or radiation and before a heating operation (PEB)), in-plane uniformity of line width (critical dimension uniformity: CDU), and dry etching resistance.

That is, an object of the invention is to provide a radiation-sensitive or actinic ray-sensitive resin composition that is extremely excellent in all of sensitivity, resolving power, pattern shape, line edge roughness performance, scum reducing property, PEB time dependence, PED stability, in-plane uniformity of line width (CDU), and dry etching resistance in the formation of, particularly, an ultrafine pattern (having a line width of, for example, 50 nm or less), a resist film using the radiation-sensitive or actinic ray-sensitive resin composition, a mask blank, a resist pattern forming method, an electronic device manufacturing method, and an electronic device.

That is, the invention is as follows.

[1]

A radiation-sensitive or actinic ray-sensitive resin composition containing a polymer compound (A) including a structural part (a) that is decomposed by irradiation with actinic rays or radiation to generate an acid anion on a side chain and a repeating unit (b) that is represented by the following Formula (I),

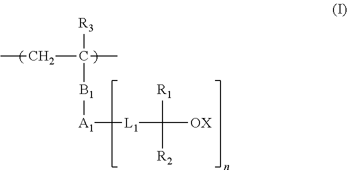

in the formula, R₃ represents a hydrogen atom, an organic group, or a halogen atom, A₁ represents an aromatic ring group or an alicyclic group, R₁ and R₂ each independently represent an alkyl group, a cycloalkyl group, or an aryl group, at least two of A₁, R₁, or R₂ may be bonded to each other to form a ring, B₁ and L₁ each independently represent a single bond or a divalent linking group, X represents a hydrogen atom or an organic group, n represents an integer of 1 or greater, and in a case where n represents an integer of 2 or greater, a plurality of L₁'s, a plurality of R₁'s, a plurality of R₂'s, and a plurality of X's may be the same as or different from each other, respectively.

[2]

The radiation-sensitive or actinic ray-sensitive resin composition according to [1], in which the structural part (a) that is decomposed by irradiation with actinic rays or radiation to generate an acid anion on a side chain has a sulfonium salt structure that is represented by the following Formula (PZI) or an iodonium salt structure that is represented by the following Formula (PZII),

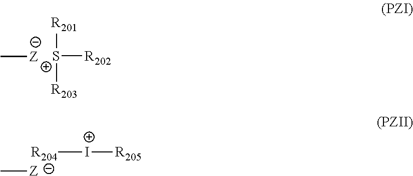

in Formula (PZI). R₂₀₁ to R₂₀₃ each independently represent an organic group, two of R₂₀₁ to R₂₀₃ may be bonded to each other to form a ring structure, the ring structure may include an oxygen atom, a sulfur atom, an ester bond, an amido bond, or a carbonyl group, and Z⁻ represents an acid anion that is generated by decomposition by irradiation with actinic rays or radiation, and in Formula (PZII), R₂₀₄ and R₂₀₅ each independently represent an aryl group, an alkyl group, or a cycloalkyl group, the aryl group of R₂₀₄ and R₂₀₅ may be an aromatic hetero ring group having an oxygen atom, a nitrogen atom, or a sulfur atom, and Z⁻ represents an acid anion that is generated by decomposition by irradiation with actinic rays or radiation.

[3]

The radiation-sensitive or actinic ray-sensitive resin composition according to [1] or [2], in which the structural part (a) that is decomposed by irradiation with actinic rays or radiation to generate an acid anion on a side chain has the sulfonium salt structure that is represented by Formula (PZI).

[4]

The radiation-sensitive or actinic ray-sensitive resin composition according to any one of [1] to [3], in which the polymer compound (A) has a repeating unit (A1) including a structural part (a) that is decomposed by irradiation with actinic rays or radiation to generate an acid anion on a side chain.

[5]

The radiation-sensitive or actinic ray-sensitive resin composition according to [4], in which the repeating unit (A1) including the structural part (a) that is decomposed by irradiation with actinic rays or radiation to generate an acid anion on a side chain is a repeating unit that is represented by the following Formula (4),

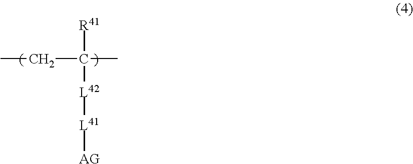

in the formula. R⁴¹ represents a hydrogen atom or a methyl group, L⁴¹ represents a single bond or a divalent linking group, L⁴² represents a divalent linking group, and AG represents a structural part that is decomposed by irradiation with actinic rays or radiation to generate an acid anion on a side chain.

[6]

The radiation-sensitive or actinic ray-sensitive resin composition according to any one of [1] to [5], in which the polymer compound (A) contains a repeating unit (c) that is represented by the following Formula (II),

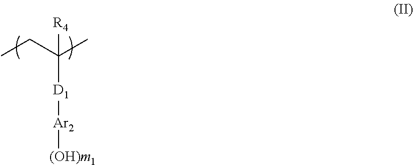

in the formula, R₄ represents a hydrogen atom, an organic group, or a halogen atom, D₁ represents a single bond or a divalent linking group, Ar₂ represents an aromatic ring group, and m₁ represents an integer of 1 or greater.

[7]

The radiation-sensitive or actinic ray-sensitive resin composition according to any one of [1] to [6], in which the above Formula (I) is the following Formula (I-2),

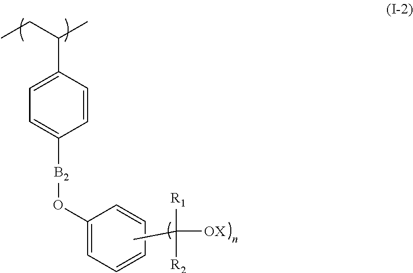

in the formula, R₁ and R₂ each independently represent an alkyl group, a cycloalkyl group, or an aryl group, B₂ represents a single bond or a divalent linking group, X represents a hydrogen atom or an organic group, n represents an integer of 1 or greater, and in a case where n represents an integer of 2 or greater, a plurality of R₁'s, a plurality of R₂'s, and a plurality of X's may be the same as or different from each other, respectively.

[8]

The radiation-sensitive or actinic ray-sensitive resin composition according to any one of [1] to [7], that is a chemically amplified negative tone resist composition.

[9]

The radiation-sensitive or actinic ray-sensitive resin composition according to any one of [1] to [8], that is for exposure to electron beams or extreme ultraviolet rays.

[10]

A resist film that is formed of the radiation-sensitive or actinic ray-sensitive resin composition according to any one of [1] to [9].

[11]

A mask blank having the resist film according to [10].

[12]

A resist pattern forming method including exposing the resist film according to [10], and developing the exposed resist film.

[13]

A resist pattern forming method including exposing the mask blank having the resist film according to [10], and developing the exposed mask blank.

[14]

The resist pattern forming method according to [12] or [13], in which the exposure is performed using electron beams or extreme ultraviolet rays.

[15]

An electronic device manufacturing method including the resist pattern forming method according to any one of [12] to [14].

[16]

An electronic device that is manufactured by the electronic device manufacturing method according to [15].

According to the invention, it is possible to provide a radiation-sensitive or actinic ray-sensitive resin composition that is extremely excellent in all of sensitivity, resolving power, pattern shape, line edge roughness performance, scum reducing property, PEB time dependence, PED stability, in-plane uniformity of line width (CDU), and dry etching resistance in the formation of, particularly, an ultrafine pattern (having a line width of, for example, 50 nm or less), a resist composition for forming a chemically amplified negative tone resist composition for pattern formation, a resist film using the radiation-sensitive or actinic ray-sensitive resin composition, a mask blank, a resist pattern forming method, an electronic device manufacturing method, and an electronic device.

### DESCRIPTION OF THE PREFERRED EMBODIMENTS

Hereinafter, embodiments of the invention will be described in detail.

In this specification, in a case where a group (atomic group) is denoted without specifying whether substituted or unsubstituted, the group includes both a group having no substituent and a group having a substituent. For example, an “alkyl group” includes not only an alkyl group having no substituent (unsubstituted alkyl group), but also an alkyl group having a substituent (substituted alkyl group).

In the invention, the “actinic ray” or “radiation” indicates, for example, a bright line spectrum of mercury lamp, a far ultraviolet ray typified by excimer laser, an extreme ultraviolet ray (EUV light), an X-ray, or an electron beam. Also, in the invention, the “light” means an actinic ray or radiation. In this specification, unless otherwise indicated, the “exposure” encompasses not only exposure to a bright line spectrum of mercury lamp, far ultraviolet rays typified by excimer laser, X-rays, EUV light or the like, but also drawing with particle beams such as electron beams and ion beams.

In this specification, the weight-average molecular weight of a polymer compound is a value in terms of polystyrene measured by a GPC method. The GPC may be equivalent to a method using TSK gel Multipore HXL-M (7.8 mm ID×30.0 cm, manufactured by Tosoh Corporation) as a column and N-methyl-2-pyrrolidone (NMP) as an eluent with the use of HLC-8120 (manufactured by Tosoh Corporation).

The reason why extreme excellence can be achieved in all of sensitivity, resolving power, pattern shape, line edge roughness performance, scum reducing property, PEB time dependence, PED stability, in-plane uniformity of line width (CDU), and dry etching resistance in the formation of, particularly, an ultrafine pattern (having a line width of, for example, 50 nm or less) using a radiation-sensitive or actinic ray-sensitive resin composition of the invention is not completely clear, but is presumed as follows.

It is thought that since a polymer compound (A) contained in the radiation-sensitive or actinic ray-sensitive resin composition of the invention has, in a molecule, a structural part (a) that is decomposed by irradiation with actinic rays or radiation to generate an acid anion on a side chain, diffusibility of the acid generated in the exposed part to an unexposed part is suppressed, and thus the resolution is improved. In addition, it is thought that since an acid generator is connected to the polymer, the distance between the acid generator and the polymer is short, and thus the electron movement efficiency and the decomposition efficiency are improved.

In addition, since the polymer compound (A) of the invention simultaneously also has a repeating unit having a crosslinking group, reaction contrast increases compared to a case of using a low-molecular crosslinking agent, and thus the resolution and the LER performance are efficiently improved.

In addition, since the structural part (a) that is decomposed by irradiation with actinic rays or radiation to generate an acid anion on a side chain and the repeating unit having a crosslinking group are incorporated in one polymer, the polymer is uniformly distributed in a resist composition, and thus excellent LER performance and an excellent pattern shape are obtained.

According to the invention, it is thought that since diffusibility of the acid and the diffusion of the crosslinking group unit in a resist film are suppressed and the crosslinking reaction is suppressed compared to a case of using a low-molecular acid generator or a low-molecular crosslinking agent, it is possible to further improve the post exposure time delay (PED) stability, deterioration in the pattern shape, and the PEB time dependence, particularly, in a case of forming a fine pattern having a line width of 50 nm or less. Here, the PED stability is coating stability in a case where the coating is left after irradiation with radiation and before a heating operation (PEB).

In addition, it is thought that since the structure of the crosslinking group is a specific structure (—CR₁R₂OX), that is, since a carbon atom to which OX is bonded is a tertiary carbon, reaction contrast is improved, and the in-plane uniformity of line width (CDU) is improved.

The radiation-sensitive or actinic ray-sensitive resin composition of the invention is typically a resist composition, and is preferably a negative tone resist composition. In addition, the radiation-sensitive or actinic ray-sensitive resin composition of the invention is typically a chemically amplified resist composition. The radiation-sensitive or actinic ray-sensitive resin composition of the invention is preferably a chemically amplified negative tone resist composition.

The radiation-sensitive or actinic ray-sensitive resin composition of the invention is preferably for exposure to electron beams or extreme ultraviolet rays, and is more preferably for exposure to electron beams.

Hereinafter, components of the radiation-sensitive or actinic ray-sensitive resin composition of the invention will be described in detail.

The radiation-sensitive or actinic ray-sensitive resin composition of the invention contains a polymer compound (A) including a structural part (a) that is decomposed by irradiation with actinic rays or radiation to generate an acid anion on a side chain and a repeating unit (b) that is represented by the following Formula (I).

Here, the expression “generate an acid anion on a side chain” indicates that an acid is generated on a side chain, and an anion part excluding a proton of the generated acid structure is connected to the polymer compound via a covalent bond.

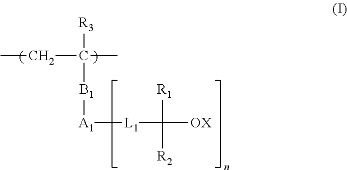

In the formula, R₃ represents a hydrogen atom, an organic group, or a halogen atom.

A₁ represents an aromatic ring group or an alicyclic group.

R₁ and R₂ each independently represent an alkyl group, a cycloalkyl group, or an aryl group.

At least two of A₁, R₁, or R₂ may be bonded to each other to form a ring.

B₁ and L₁ each independently represent a single bond or a divalent linking group.

X represents a hydrogen atom or an organic group.

n represents an integer of 1 or greater.

In a case where n represents an integer of 2 or greater, a plurality of L₁'s, a plurality of R₁'s, a plurality of R₂'s, and a plurality of X's may be the same as or different from each other, respectively.

[Polymer Compound (A)]

<Structural Part (a) that is Decomposed by Irradiation with Actinic Rays or Radiation to Generate Acid Anion on Side Chain>

In the invention, the structural part (a) (hereinafter, also referred to as “acid generating structure (a)”) that is decomposed by irradiation with actinic rays or radiation to generate an acid anion on a side chain represents a structural part that is decomposed by irradiation with actinic rays or radiation to generate an acid anion. The acid generating structure (a) is preferably a structural part that is decomposed by irradiation with actinic rays or radiation to generate an acid anion. More preferred examples thereof include a structural part of a known compound that is used in a photoinitiator of photocationic polymerization, a photoinitiator of photoradical polymerization, a photo-decoloring agent of pigments, a photochromic agent, a microresist, or the like and generates an acid anion by light, and the structural part is even more preferably an ionic structural part.

The acid generating structure (a) preferably has a sulfonium salt structure or an iodonium salt structure (more preferably, a sulfonium salt structure). The acid generating structure is more preferably an ionic structural part including a sulfonium salt or an iodonium salt (more preferably, an ionic structural part including a sulfonium salt). More specifically, a group that is represented by the following Formula (PZI) or (PZII) is preferred as the acid generating structure (a).

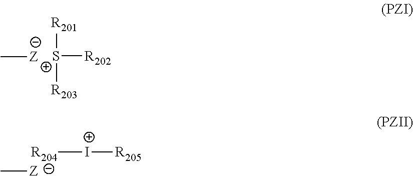

In the above Formula (PZI), R₂₀₁ to R₂₀₃ each independently represent an organic group.

The number of carbon atoms of an organic group as R₂₀₁ to R₂₀₃ is generally 1 to 30, and preferably 1 to 20.

Two of R₂₀₁ to R₂₀₃ may be bonded to each other to form a ring structure, and the ring structure may include an oxygen atom, a sulfur atom, an ester bond, an amido bond, or a carbonyl group. Examples of the group that is formed by bonding two of R₂₀₁ to R₂₀₃ include an alkylene group (for example, a butylene group and a pentylene group). A ring structure formed by bonding two of R₂₀₁ to R₂₀₃ is preferably used since it is possible to expect suppression of contamination of an exposing machine with decomposition product during the exposure.

Z⁻ represents an acid anion that is generated by decomposition by irradiation with actinic rays or radiation, and is preferably a non-nucleophilic anion. Examples of the non-nucleophilic anion include a sulfonate anion, a carboxylate anion, a sulfonylimido anion, a bis(alkylsulfonyl)imido anion, and a tris(alkylsulfonyl)methyl anion.

The non-nucleophilic anion is an anion having extremely low ability of causing a nucleophilic reaction and capable of suppressing the temporal decomposition caused due to an intramolecular nucleophilic reaction. Accordingly, the temporal stability of the resin is improved, and the temporal stability of the composition is also improved.

Examples of the organic group of R₂₀₁ to R₂₀₃ include an aryl group, an alkyl group, a cycloalkyl group, a cycloalkenyl group, and an indolyl group. Here, regarding the cycloalkyl group and the cycloalkenyl group, at least one of carbon atoms of the ring may be a carbonyl carbon.

At least one of R₂₀₁, R₂₀₂, or R₂₀₃ is preferably an aryl group, and all of them are more preferably aryl groups.

As the aryl group of R₂₀₁, R₂₀₂, and R₂₀₃, a phenyl group or a naphthyl group is preferred, and a phenyl group is more preferred.

Preferred examples of the alkyl group, the cycloalkyl group, and the cycloalkenyl group of R₂₀₁, R₂₀₂, and R₂₀₃ include a linear or branched alkyl group having 1 to 10 carbon atoms (for example, a methyl group, an ethyl group, a propyl group, a butyl group, and a pentyl group), a cycloalkyl group having 3 to 10 carbon atoms (for example, a cyclopentyl group, a cyclohexyl group, and a norbornyl group), and a cycloalkenyl group having 3 to 10 carbon atoms (for example, a pentadienyl group and a cyclohexenyl group).

The organic groups such as an aryl group, an alkyl group, a cycloalkyl group, a cycloalkenyl group, and an indolyl group as R₂₀₁, R₂₀₂, and R₂₀₃ may further have a substituent. Examples of the substituent include, but are not limited to, a nitro group, a halogen atom such as a fluorine atom (preferably a fluorine atom), a carboxyl group, a hydroxyl group, an amino group, a cyano group, an alkyl group (preferably having 1 to 15 carbon atoms), an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an arylthio group (preferably having 6 to 14 carbon atoms), a hydroxyalkyl group (preferably having 1 to 15 carbon atoms), an alkylcarbonyl group (preferably having 2 to 15 carbon atoms), a cycloalkylcarbonyl group (preferably 4 to 15 carbon atoms), an arylcarbonyl group (preferably having 7 to 14 carbon atoms), a cycloalkenyloxy group (preferably having 3 to 15 carbon atoms), and a cycloalkenylalkyl group (preferably having 4 to 20 carbon atoms).

Regarding the cycloalkyl group and the cycloalkenyl group as a substituent that may be included in each of the groups of R₂₀₁, R₂₀₂, and R₂₀₃, at least one of carbon atoms of the ring may be a carbonyl carbon.

The substituent that may be included in each of the groups of R₂₀₁, R₂₀₂, and R₂₀₃ may further have a substituent, and examples of such a substituent include the same as those exemplified in the above description as the substituent that may be included in each of the groups of R₂₀₁, R₂₀₂, and R₂₀₃, and an alkyl group and a cycloalkyl group are preferred.

Examples of the preferred structure in a case where at least one of R₂₀₁, R₂₀₂, or R₂₀₃ is not an aryl group include cation structures of the compounds in the paragraphs 0046 and 0047 in JP2004-233661A, the compounds in the paragraphs 0040 to 0046 in JP2003-35948A, the compounds exemplified as Formulae (I-1) to (I-70) in US2003/0224288A, and the compounds exemplified as Formulae (IA-1) to (IA-54) and Formulae (IB-1) to (IB-24) in US2003/0077540A.

In Formula (PZII), R₂₀₄ and R₂₀₅ each independently represent an aryl group, an aromatic hetero ring group, an alkyl group, or a cycloalkyl group. The aryl group, the alkyl group, and the cycloalkyl group are the same as those described as the aryl group, the alkyl group, and the cycloalkyl group of R₂₀₁ to R₂₀₃ in the above-described compound (PZI).

The aryl group of R₂₀₄ and R₂₀₅ may be an aromatic hetero ring group having an oxygen atom, a nitrogen atom, a sulfur atom, or the like. Examples of the aromatic hetero ring group include a pyrrole residue (a group formed by removing one hydrogen atom from a pyrrole), a furan residue (a group formed by removing one hydrogen atom from a furan), a thiophene residue (a group formed by removing one hydrogen atom from a thiophene), an indole residue (a group formed by removing one hydrogen atom from an indole), a benzofuran residue (a group formed by removing one hydrogen atom from a benzofuran), and a benzothiophene residue (a group formed by removing one hydrogen atom from a benzothiophene).

The aryl group, the alkyl group, and the cycloalkyl group of R₂₀₄ and R₂₀₅ may have a substituent. Examples of the substituent include a substituent that may be included in the aryl group, the alkyl group, and the cycloalkyl group of R₂₀₁ to R₂₀₃ of the above-described compound (PZI).

Z⁻ represents an acid anion that is generated by decomposition by irradiation with actinic rays or radiation, and is preferably a non-nucleophilic anion. Examples thereof include the same as those as Z⁻ in Formula (PZI).

Preferred specific examples of the acid generating structure (a) are as follows, but are not particularly limited thereto. Me represents a methyl group.

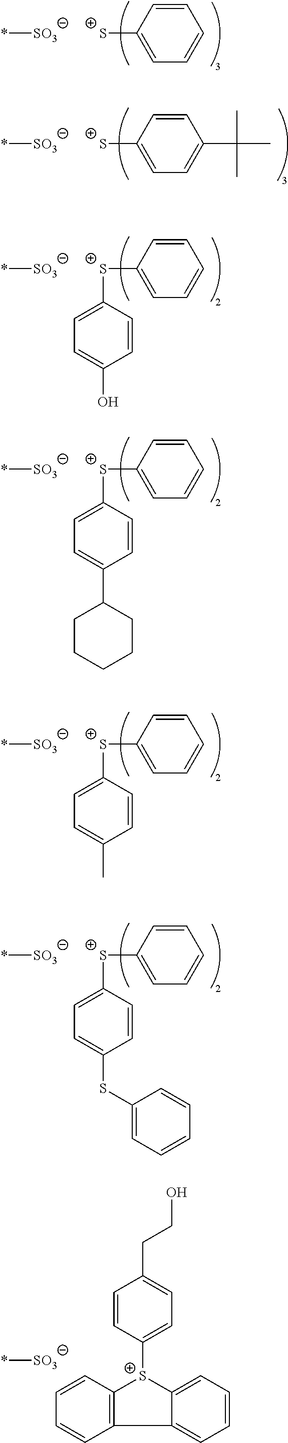

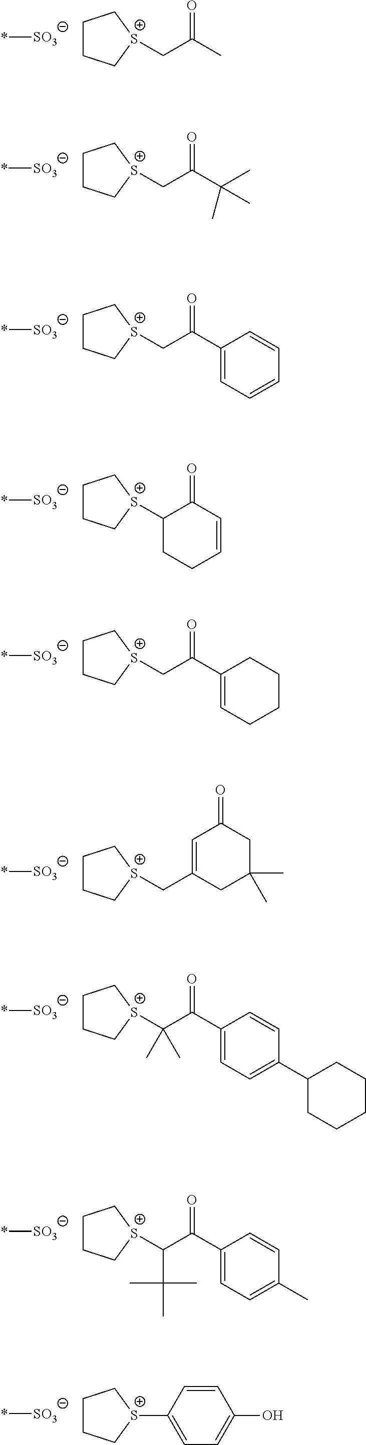

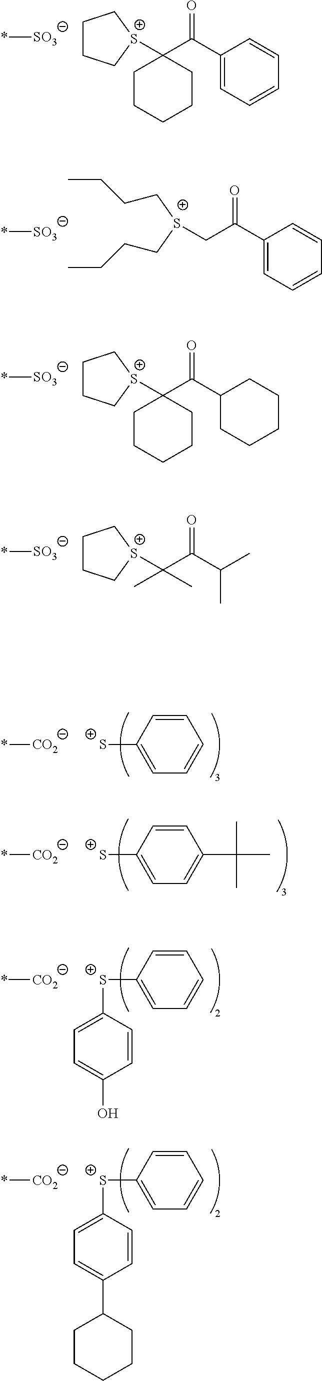

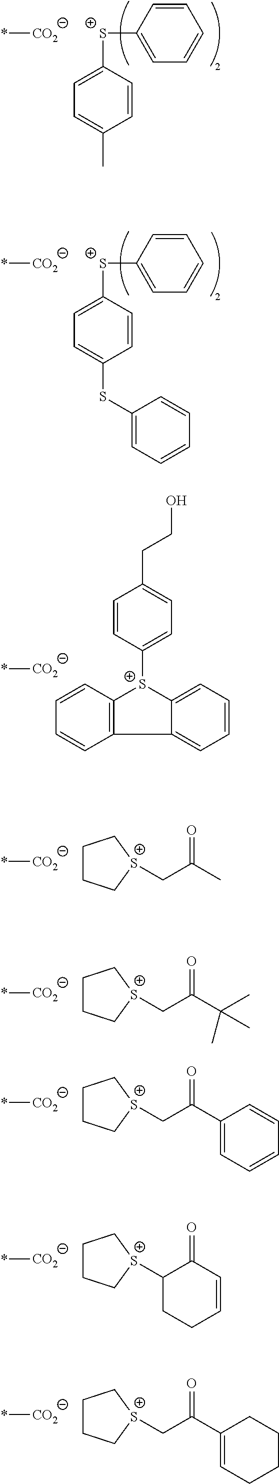

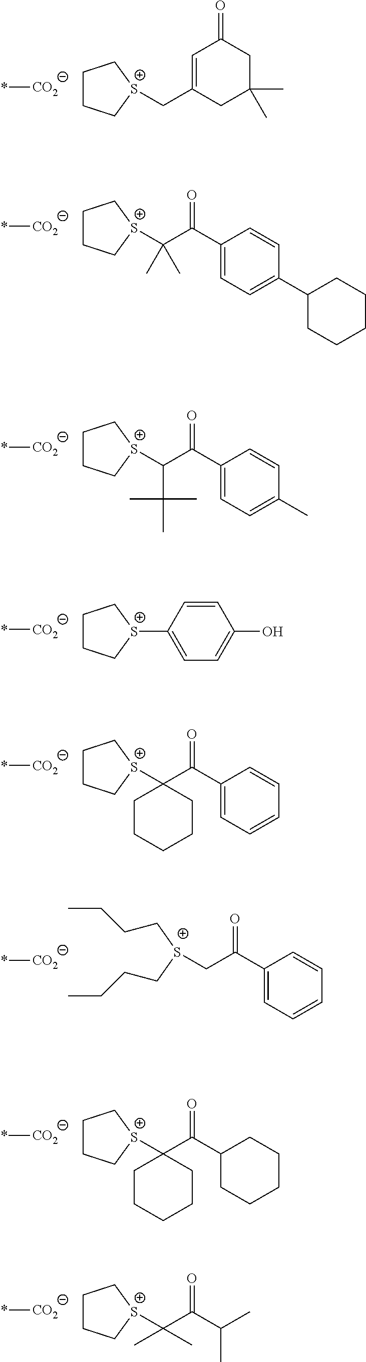

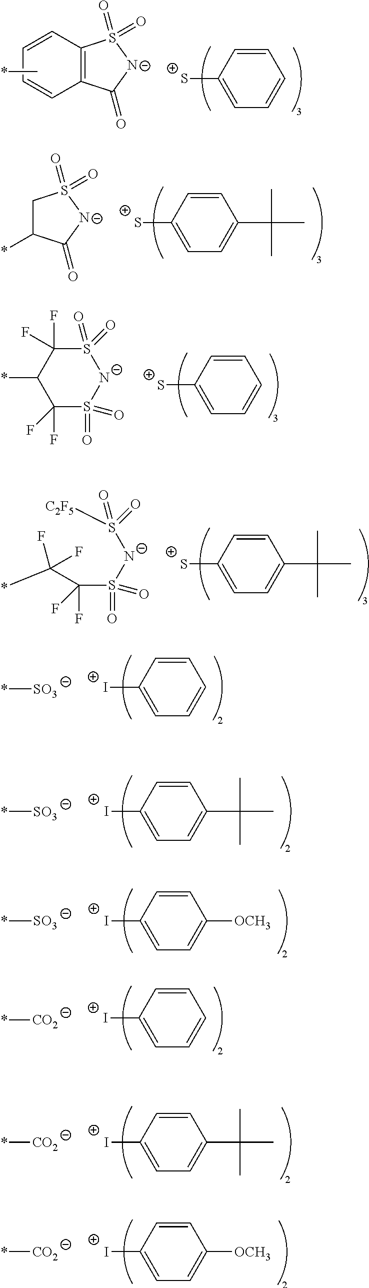

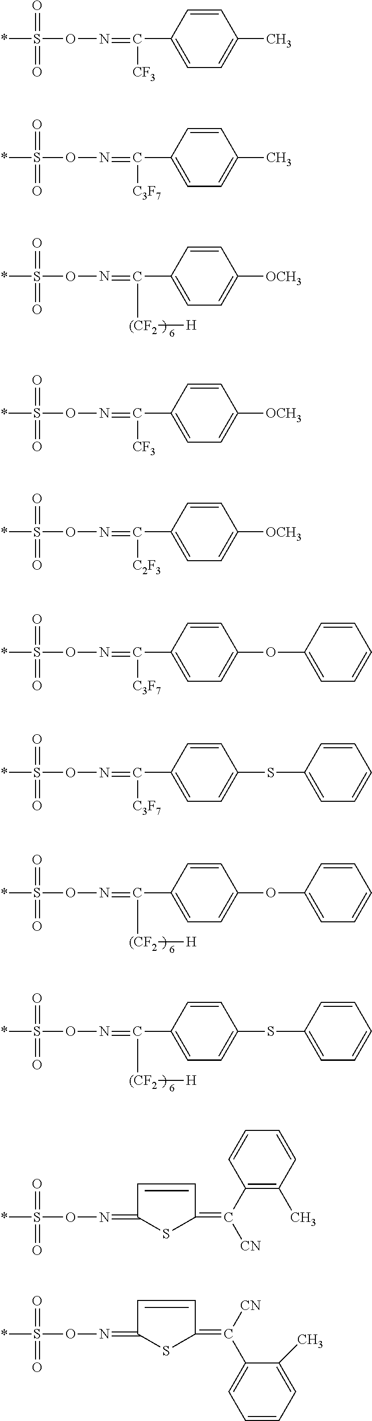

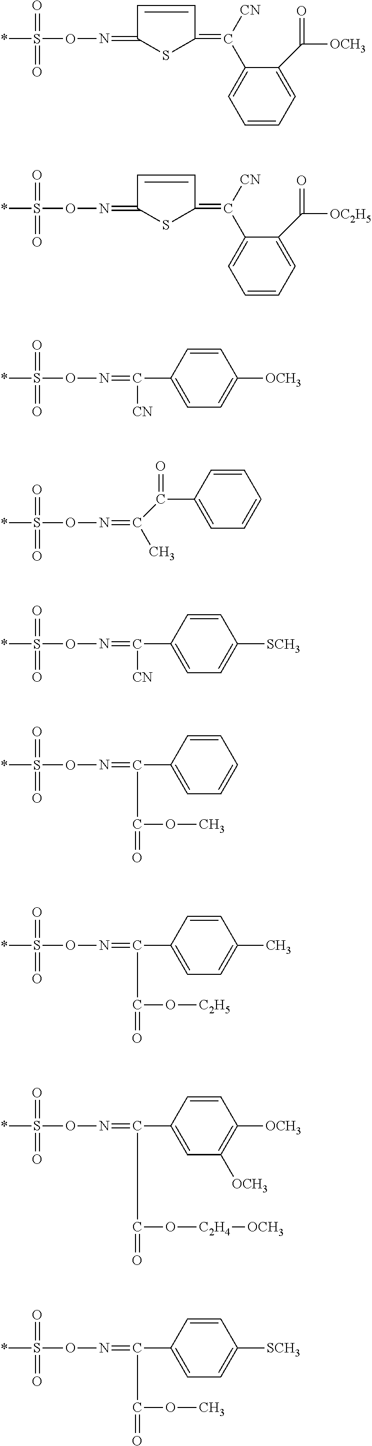

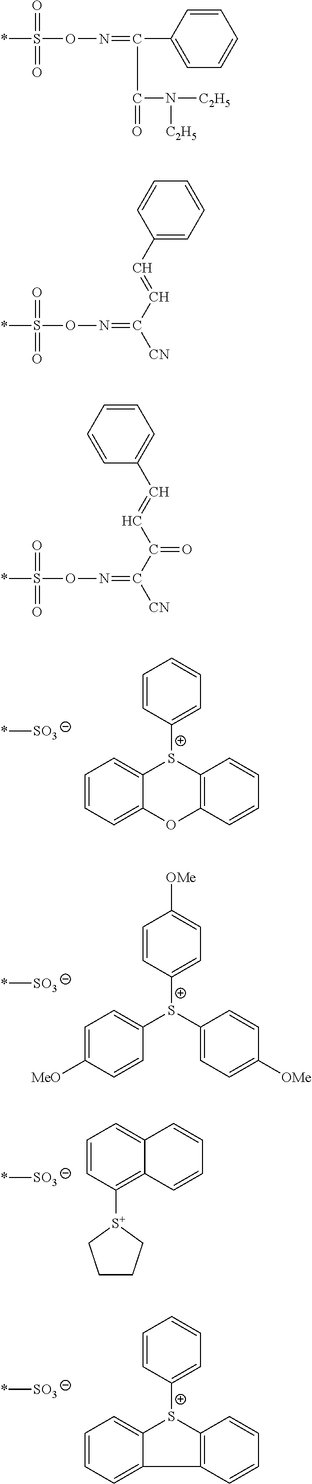

The polymer compound (A) preferably has a repeating unit (A1) including a structural part (a) that is decomposed by irradiation with actinic rays or radiation to generate an acid anion on a side chain, and as the repeating unit (A1), a repeating unit that is represented by the following Formula (4) is preferably provided.

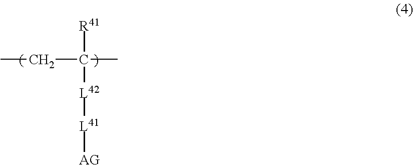

R⁴¹ represents a hydrogen atom or a methyl group. L⁴¹ represents a single bond or a divalent linking group. L⁴² represents a divalent linking group. AG represents a structural part that is decomposed by irradiation with actinic rays or radiation to generate an acid anion on a side chain.

R⁴¹ represents a hydrogen atom or a methyl group as described above, and is preferably a hydrogen atom.

Examples of the divalent linking group of L⁴¹ and L⁴² include an alkylene group, a cycloalkylene group, an arylene group, —O—, —SO₂—, —CO, —N(R)—, —S—, —CS—, and combinations of two or more of these, and the total number of carbon atoms thereof is preferably 20 or less. Here, R represents an aryl group, an alkyl group, or a cycloalkyl group.

The divalent linking group of L⁴² is preferably an arylene group, and preferred examples thereof include arylene groups having 6 to 18 carbon atoms (more preferably having 6 to 10 carbon atoms) such as a phenylene group, a tolylene group, and a naphthylene group, and divalent aromatic ring groups including a hetero ring, such as thiophene, furan, pyrrole, benzothiophene, benzofuran, benzopyrrole, triazine, imidazole, benzimidazole, triazole, thiadiazole, and thiazole.

Preferred examples of the alkylene group of L⁴¹ and L⁴² include alkylene groups having 1 to 12 carbon atoms such as a methylene group, an ethylene group, a propylene group, a butylene group, a hexylene group, an octylene group, and a dodecanylene group.

Preferred examples of the cycloalkylene group of L⁴¹ and L⁴² include cycloalkylene groups having 5 to 8 carbon atoms such as a cyclopentylene group and a cyclohexylene group.

Preferred examples of the arylene group of L⁴¹ and L⁴² include arylene groups having 6 to 14 carbon atoms such as a phenylene group and a naphthylene group.

The alkylene group, cycloalkylene group, and arylene group may further have a substituent. Examples of the substituent include an alkyl group, a cycloalkyl group, aryl group, an amino group, an amido group, an ureido group, a urethane group, a hydroxy group, a carboxy group, a halogen atom, an alkoxy group, a thioether group, an acyl group, an acyloxy group, an alkoxycarbonyl group, a cyano group, and a nitro group.

Specific examples of the structural part as the acid generating structure (a) that is decomposed by irradiation with actinic rays or radiation to generate an acid anion on a side chain are the same as those exemplified in the above description as the structural part (a) that is decomposed by irradiation with actinic rays or radiation to generate an acid anion.

The method for synthesis of the monomer corresponding to the repeating unit (A1) including a structural part that is decomposed by irradiation with actinic rays or radiation to generate an acid anion on a side chain is not particularly limited. In a case of an onium structure, examples thereof include a method for synthesis by exchanging an acid anion containing a polymerizable unsaturated bond corresponding to the repeating unit with a halide of a known onium salt.

More specifically, a metal ion salt (for example, a sodium ion, a potassium ion, or the like) or an ammonium salt (an ammonium, a triethylammonium salt, or the like) of an acid having a polymerizable unsaturated bond corresponding to the repeating unit and an onium salt having a halogen ion (a chloride ion, a bromide ion, an iodide ion, or the like) are stirred in the presence of water or methanol to cause an anion exchange reaction, and the reaction product is subjected to separation and washing operations with an organic solvent such as dichloromethane, chloroform, ethyl acetate, methyl isobutyl ketone, and tetrahydroxyfuran, and water, whereby a target monomer corresponding to the repeating unit that is represented by Formula (4) can be synthesized.

The monomer can also be synthesized by stirring the compounds above in the presence of an organic solvent separable from water, such as dichloromethane, chloroform, ethyl acetate, methyl isobutyl ketone, and tetrahydroxyfuran, and water to cause an anion exchange reaction, and subjecting the reaction product to separation and washing operations with water.

The repeating unit (A1) including a structural part that is decomposed by irradiation with actinic rays or radiation to generate an acid anion on a side chain can also be synthesized by introducing an acid anion part into the side chain by a polymer reaction and introducing an onium salt through salt exchange.

Specific examples of the repeating unit (A1) including a structural part that is decomposed by irradiation with actinic rays or radiation to generate an acid anion on a side chain will be shown below, but are not limited thereto. Me represents a methyl group, Ph represents a phenyl group, t-Bu represents a t-butyl group, and Ac represents an acetyl group.

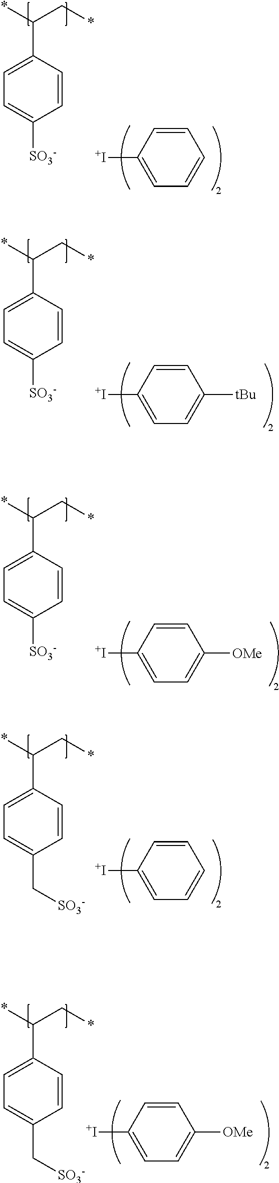

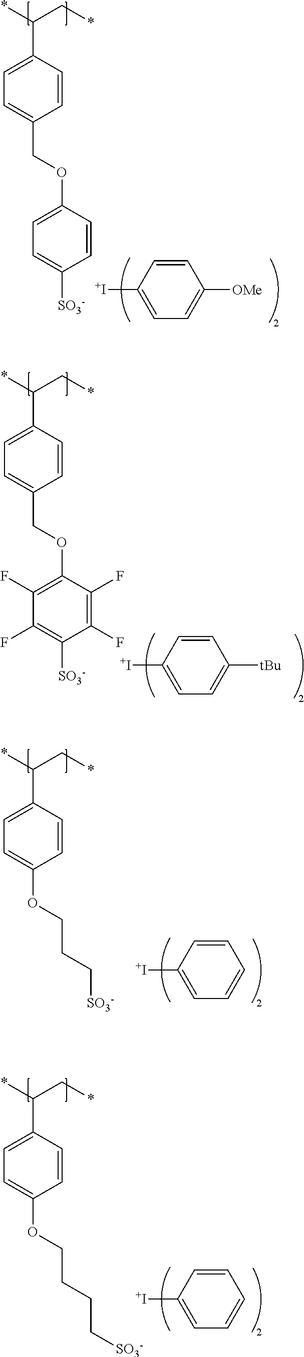

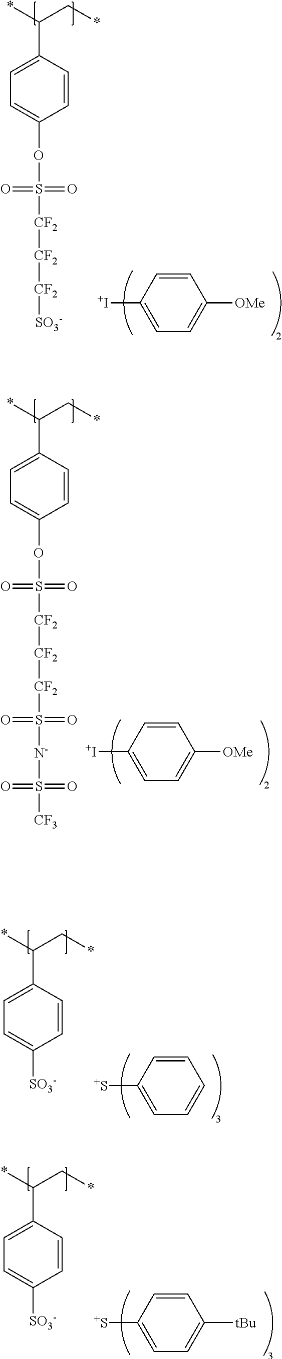

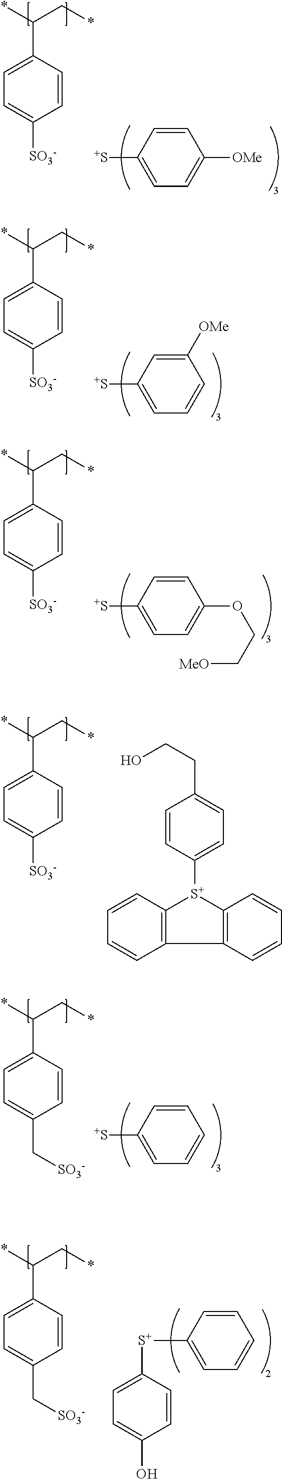

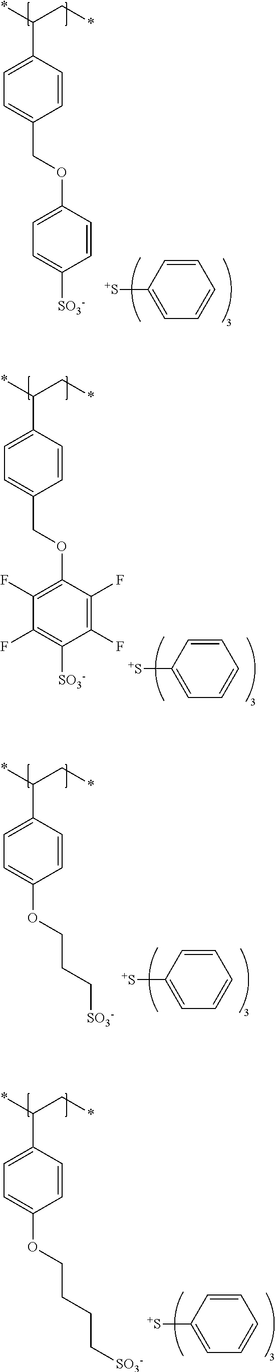

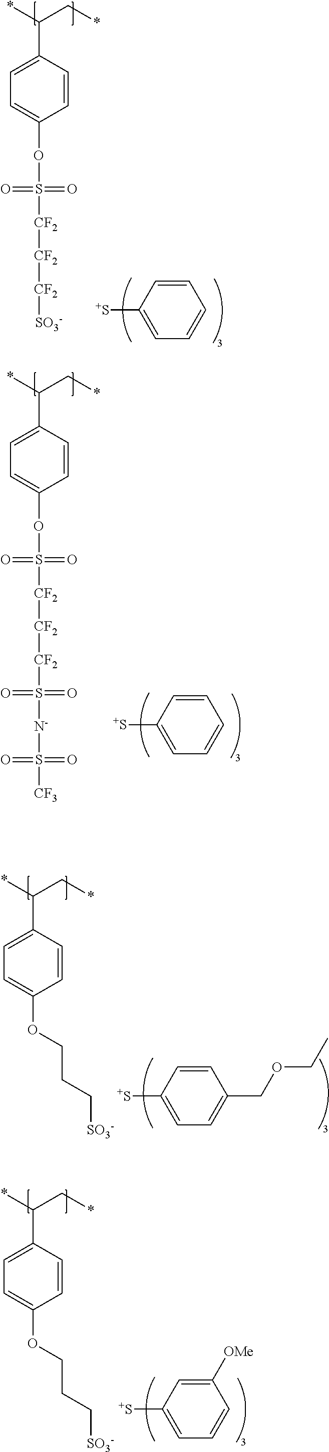

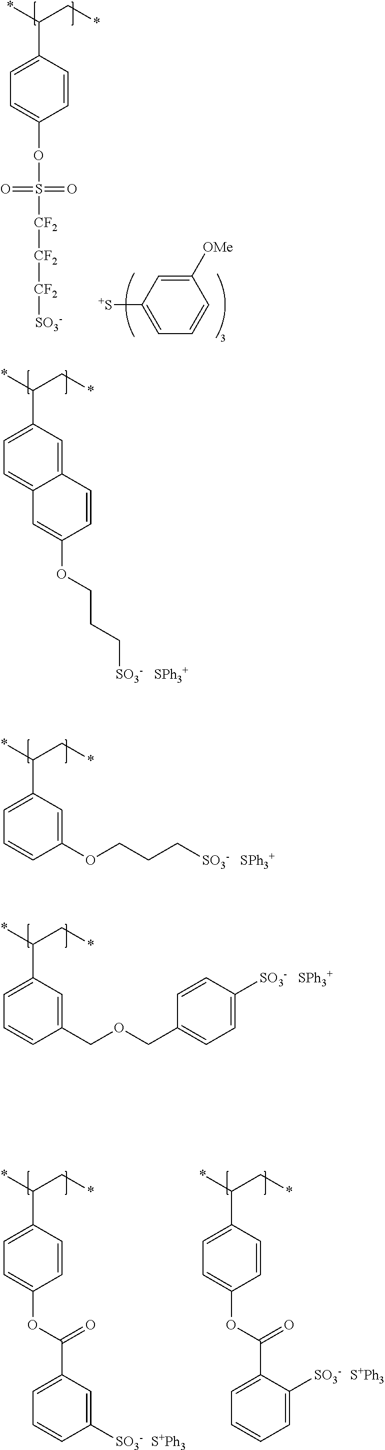

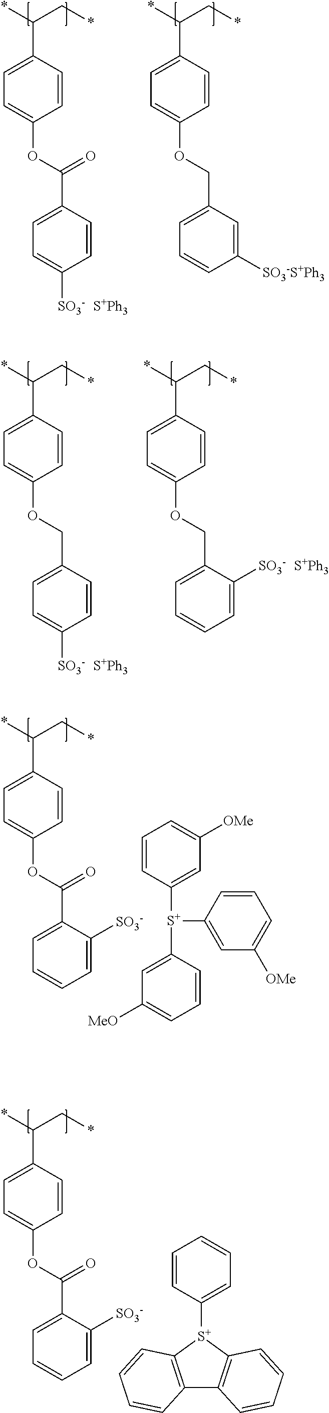

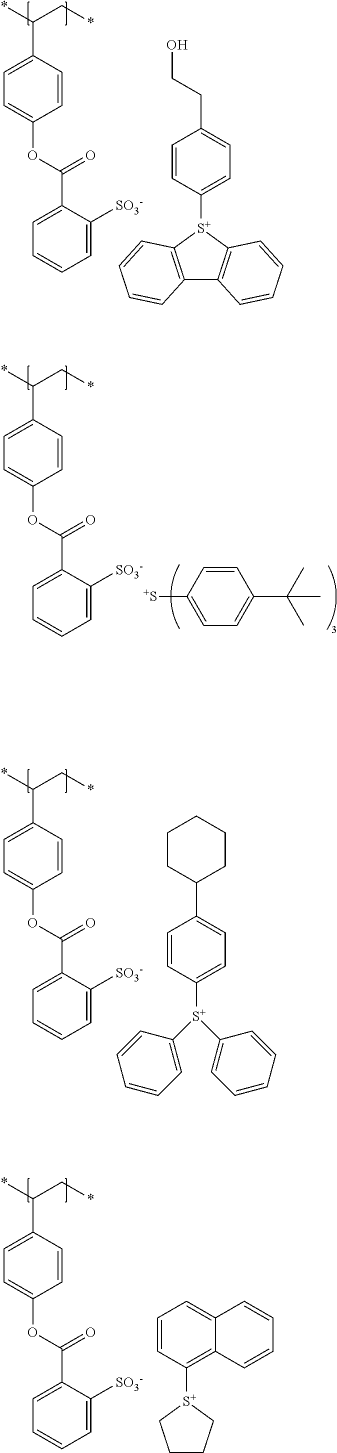

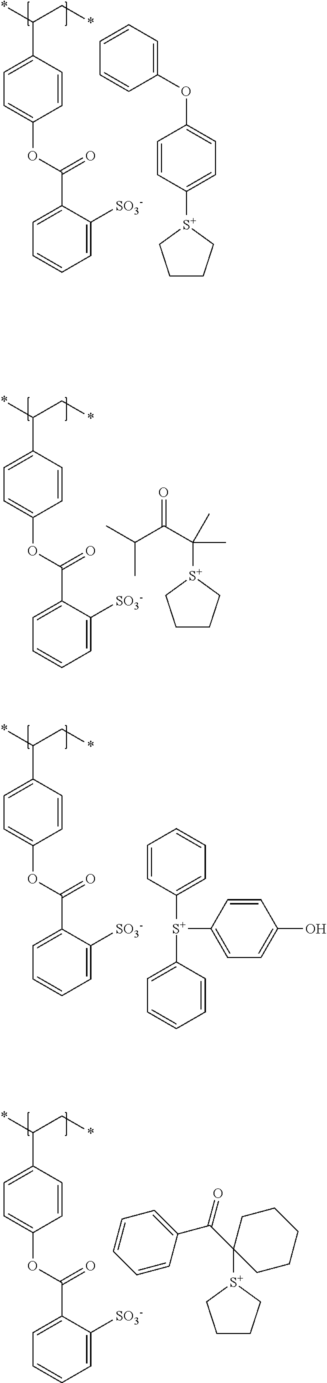

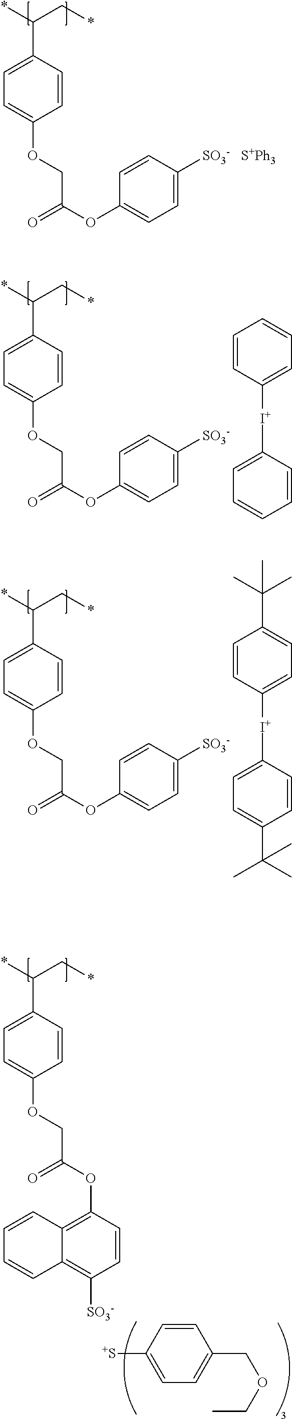

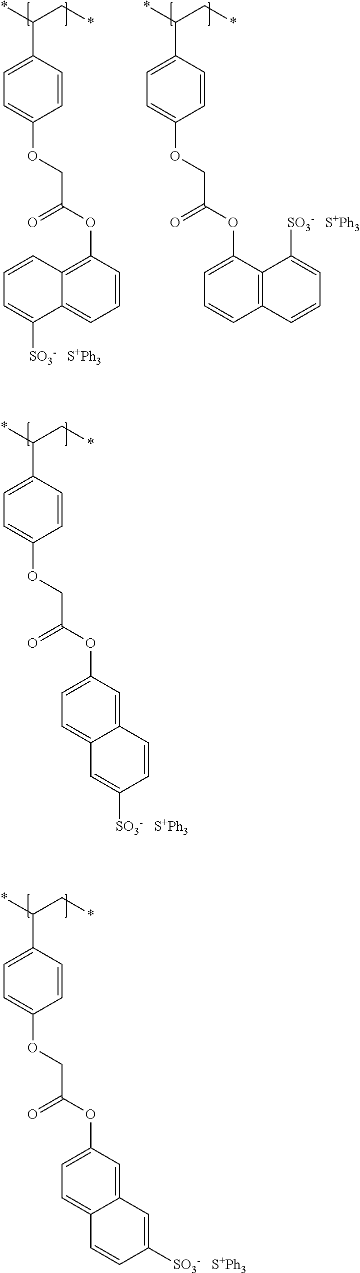

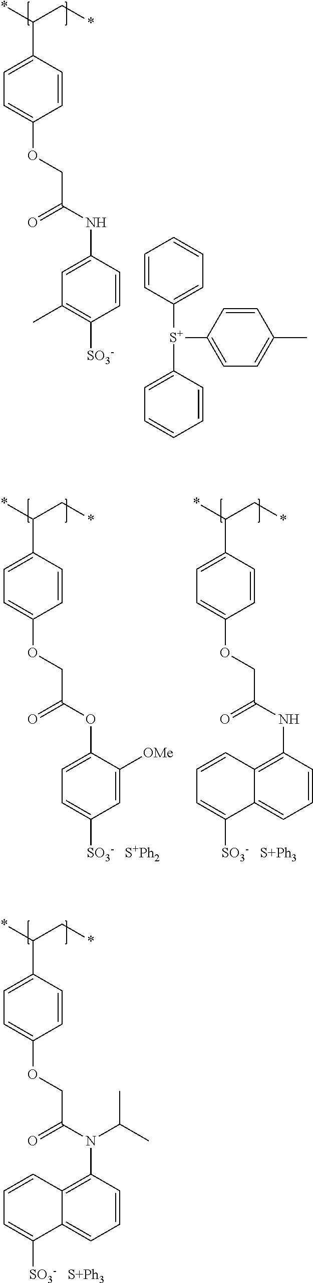

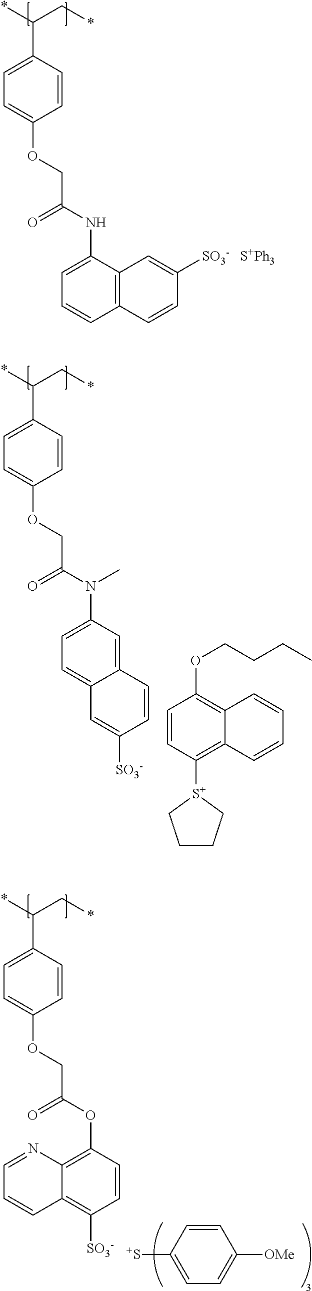

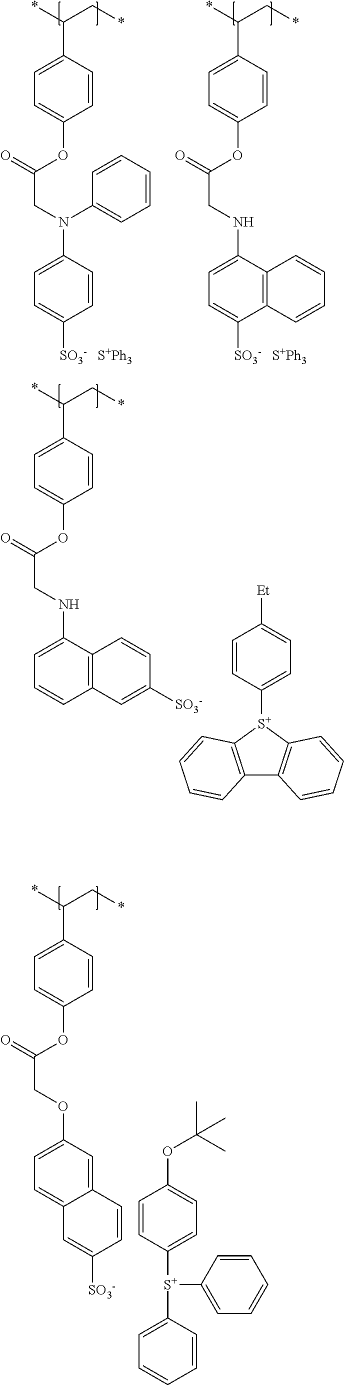

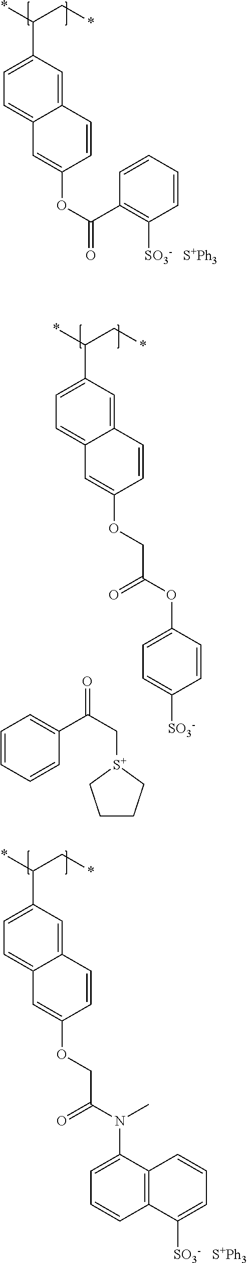

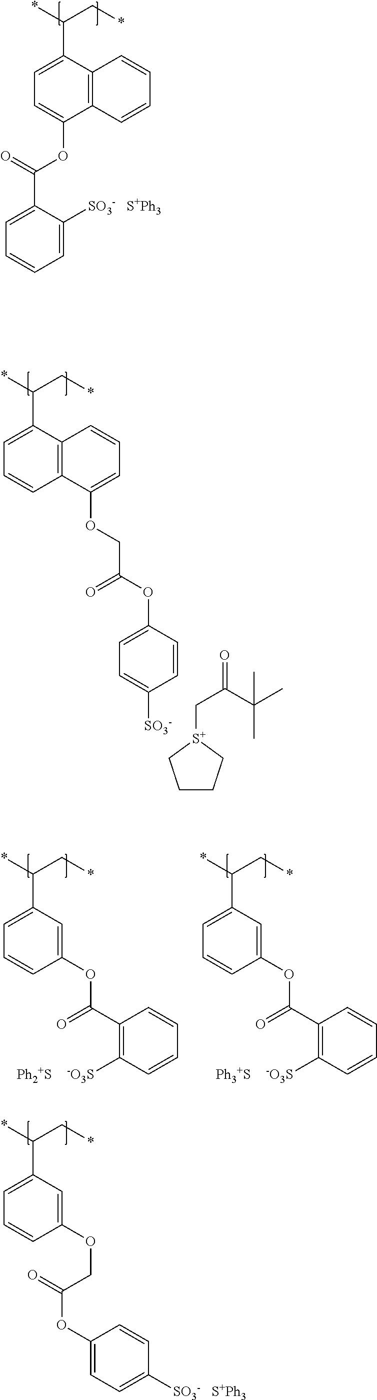

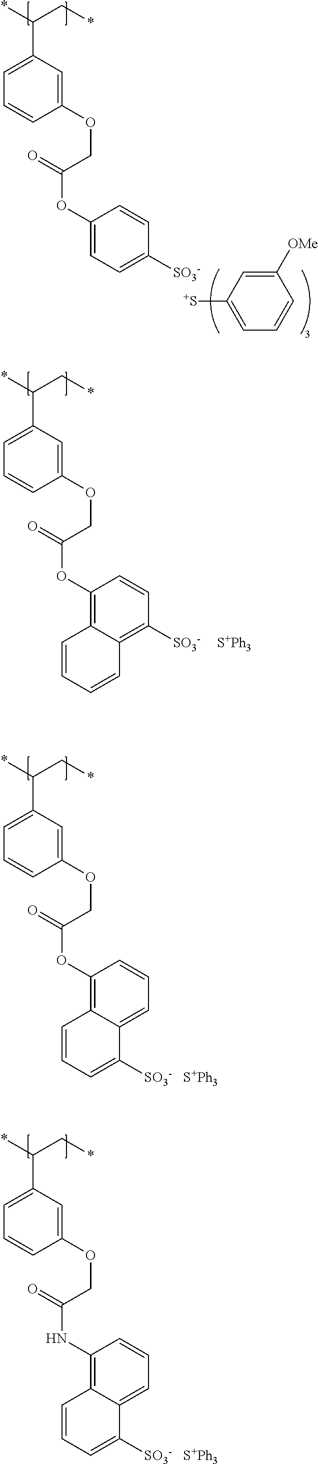

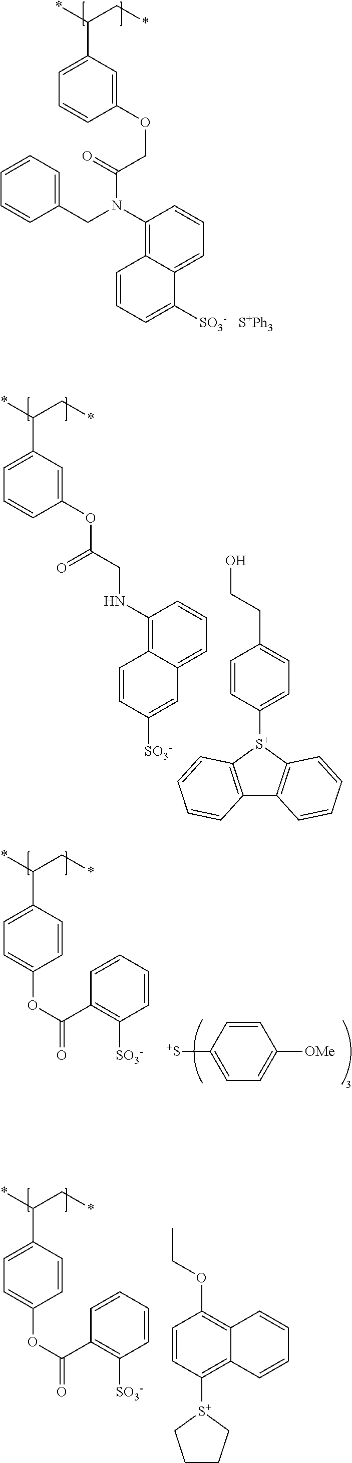

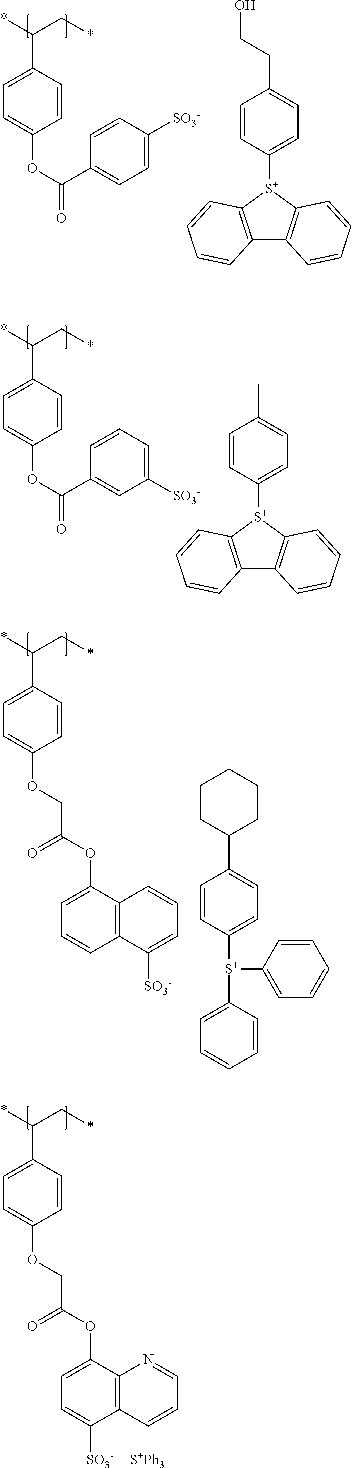

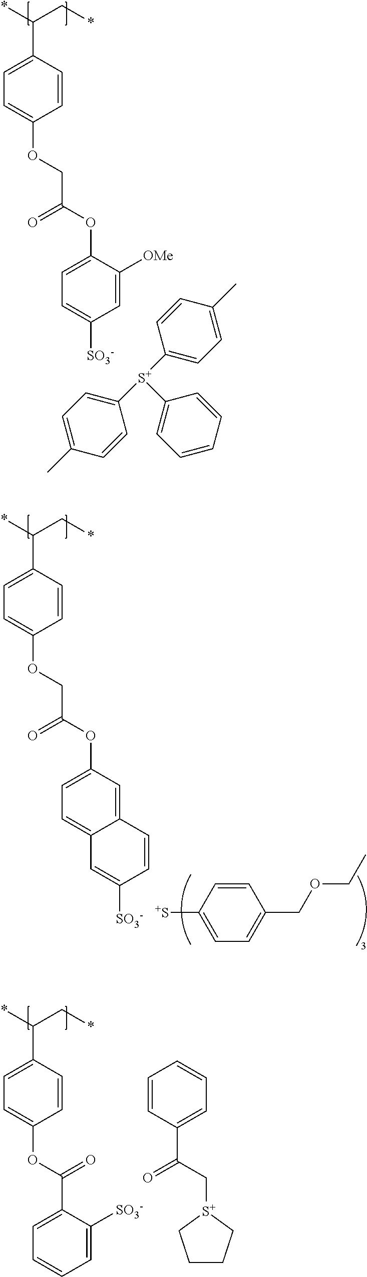

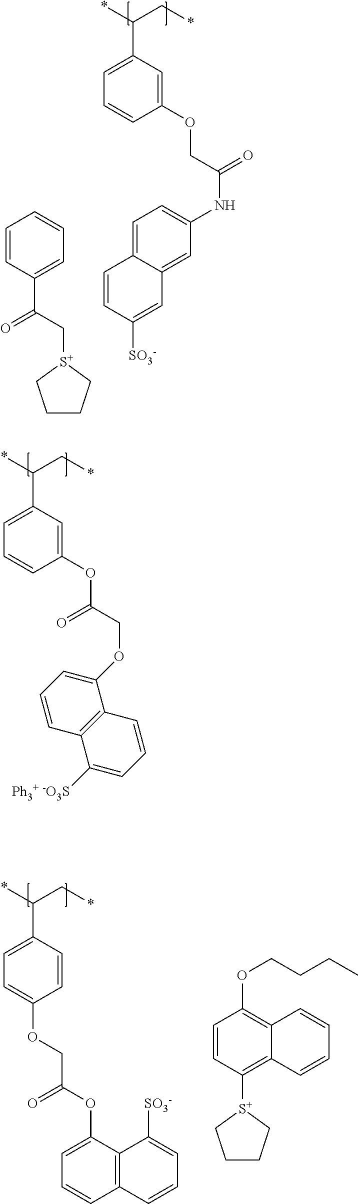

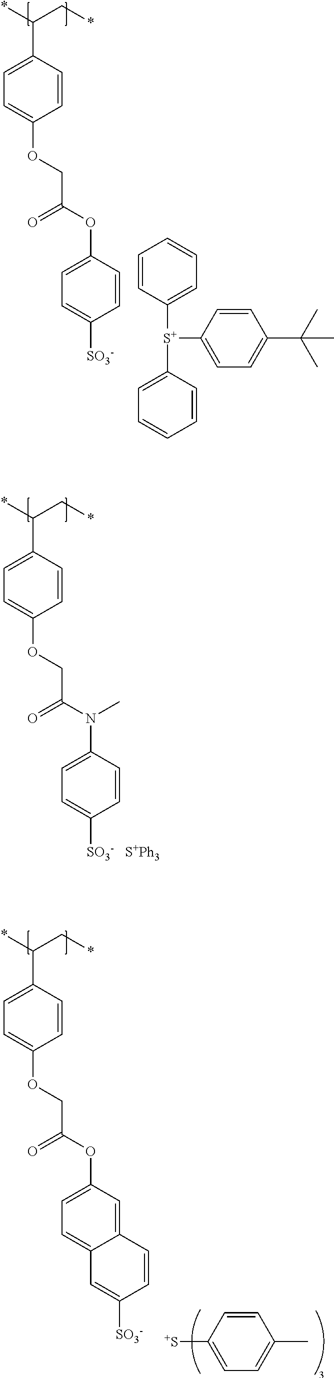

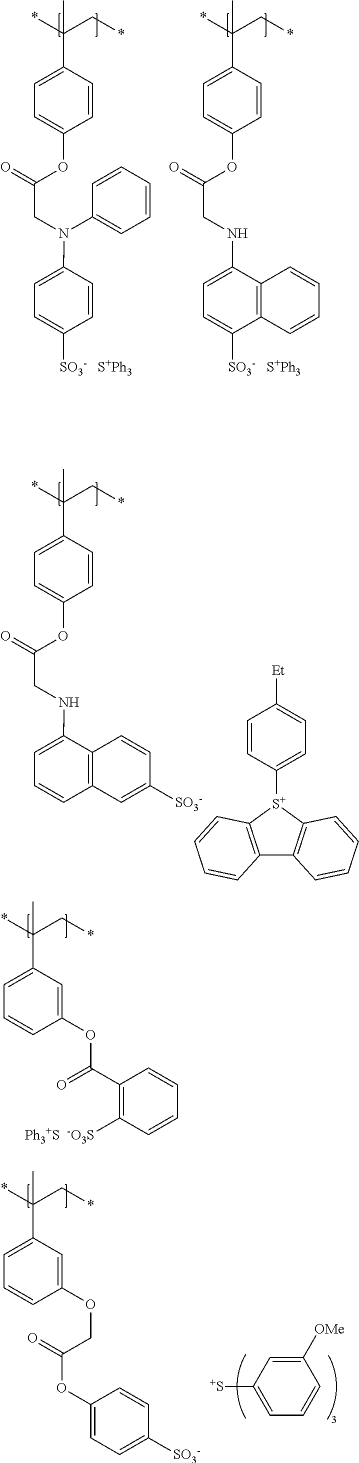

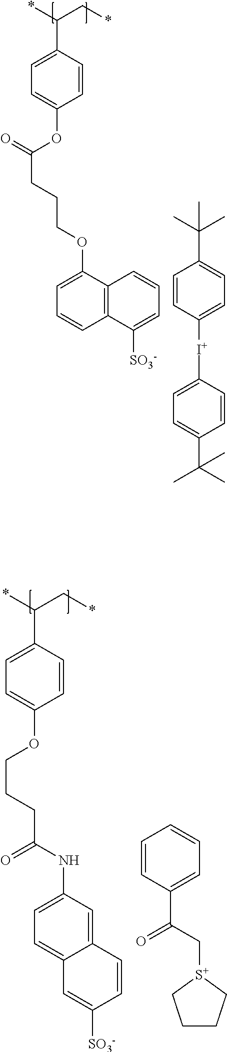

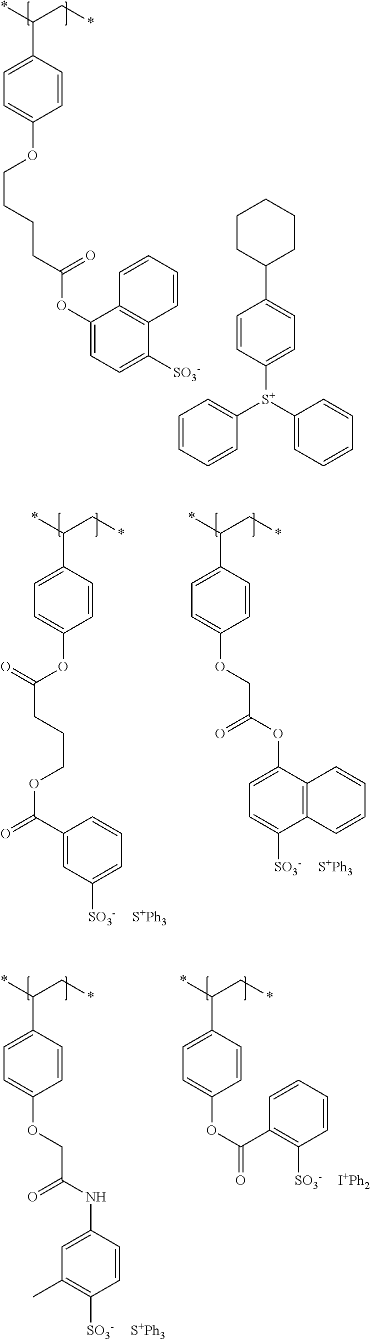

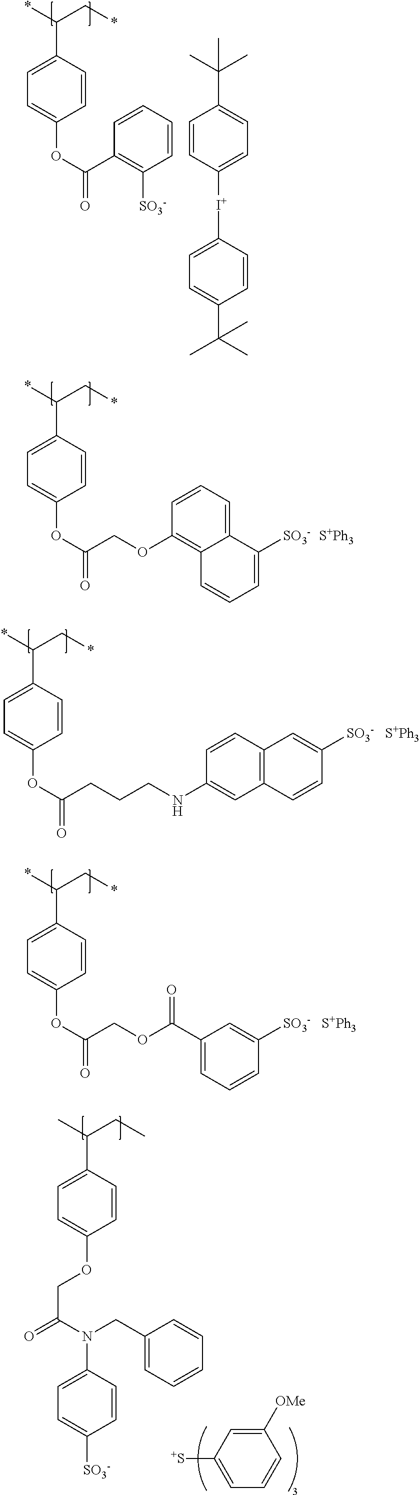

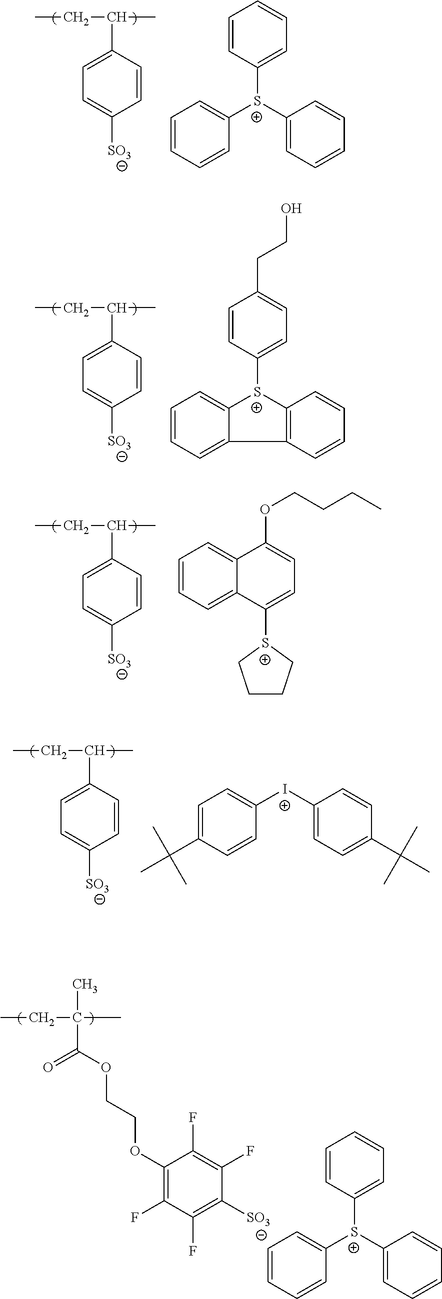

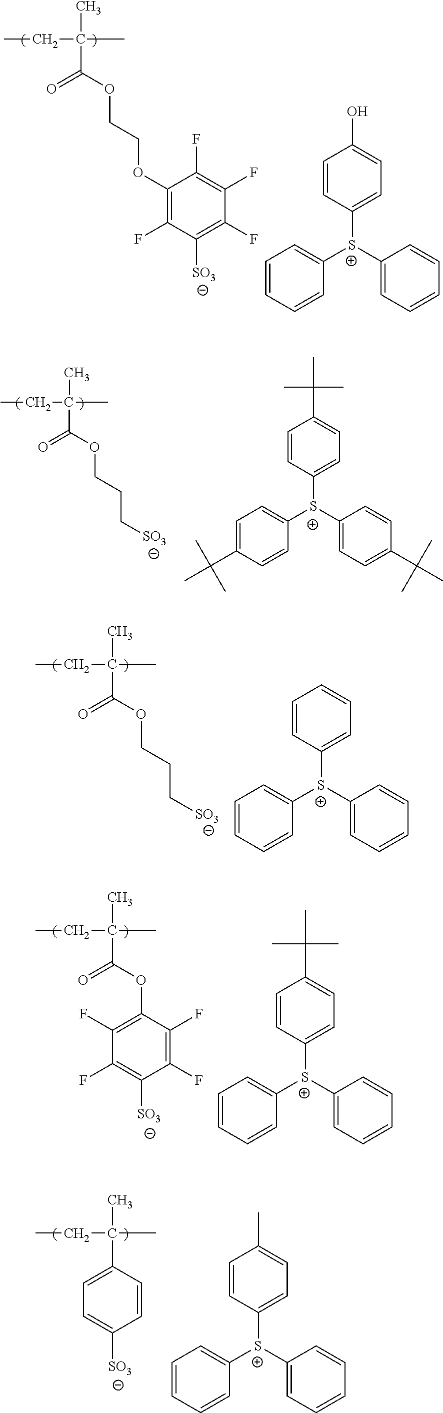

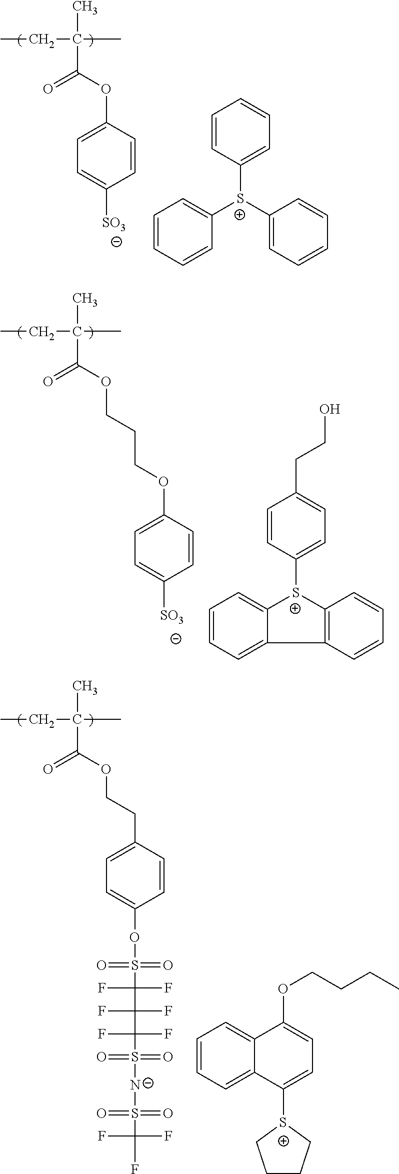

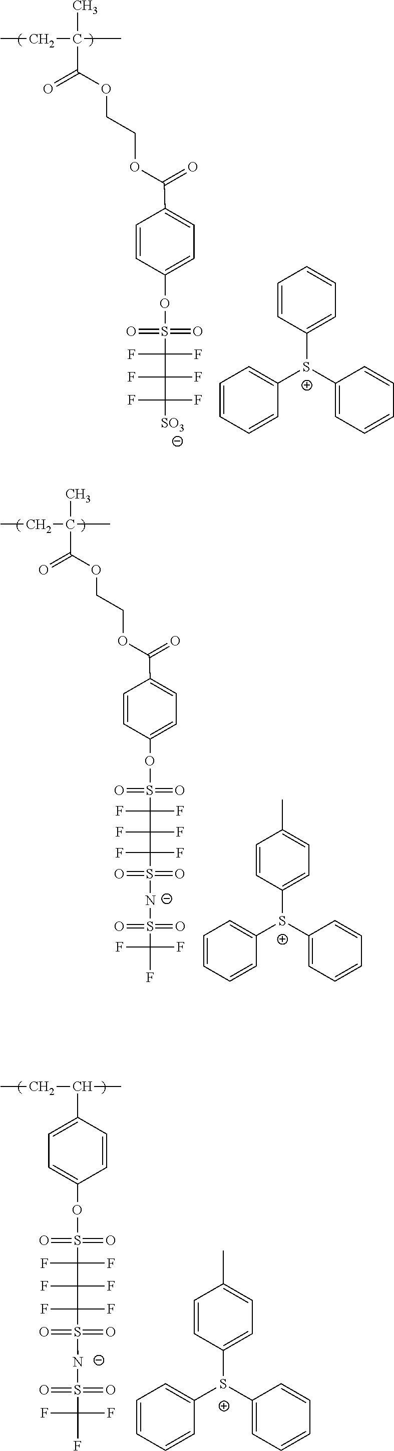

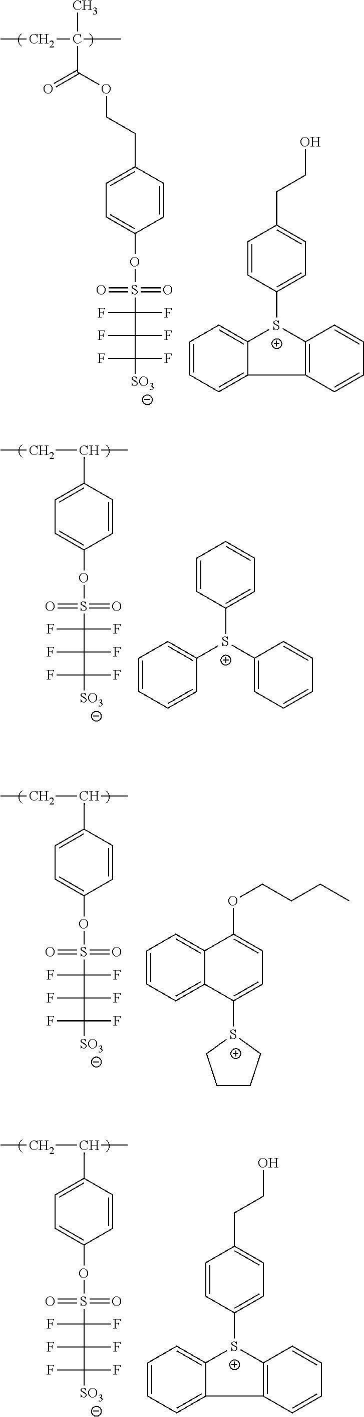

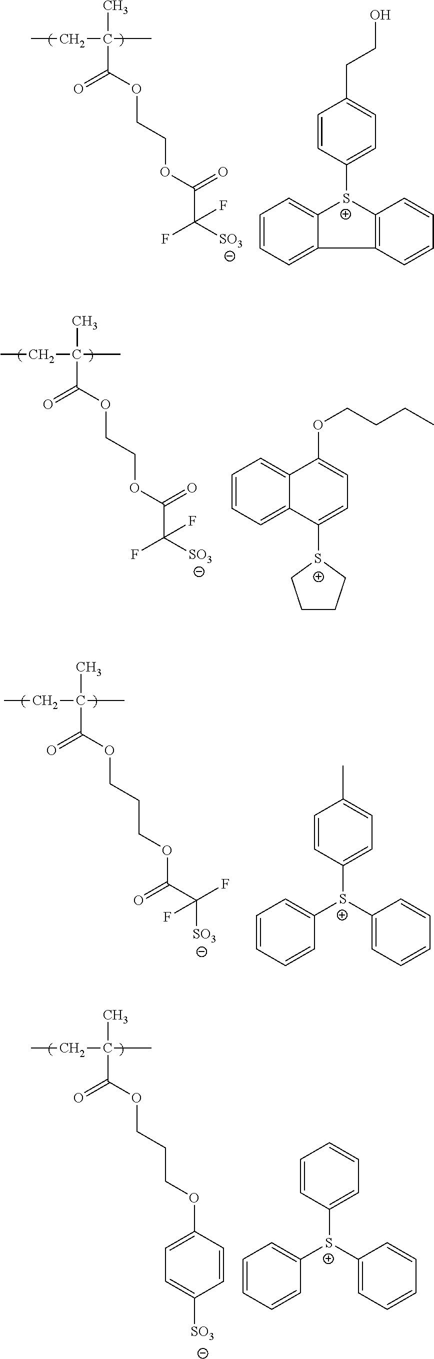

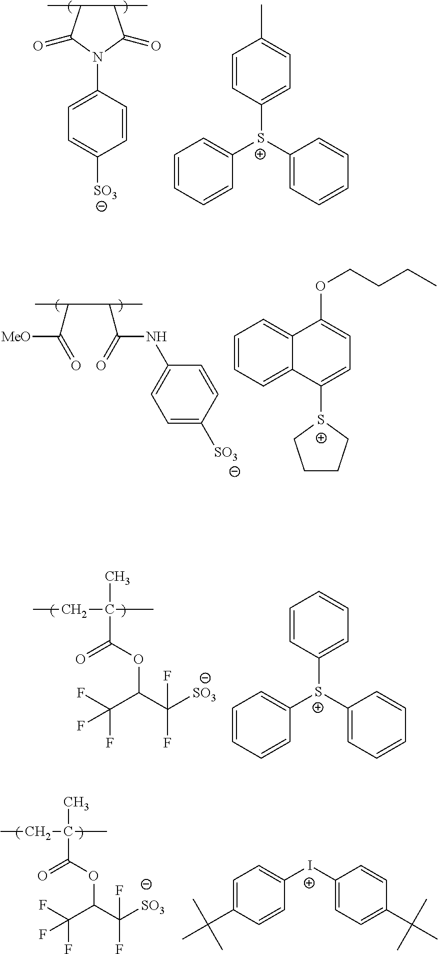

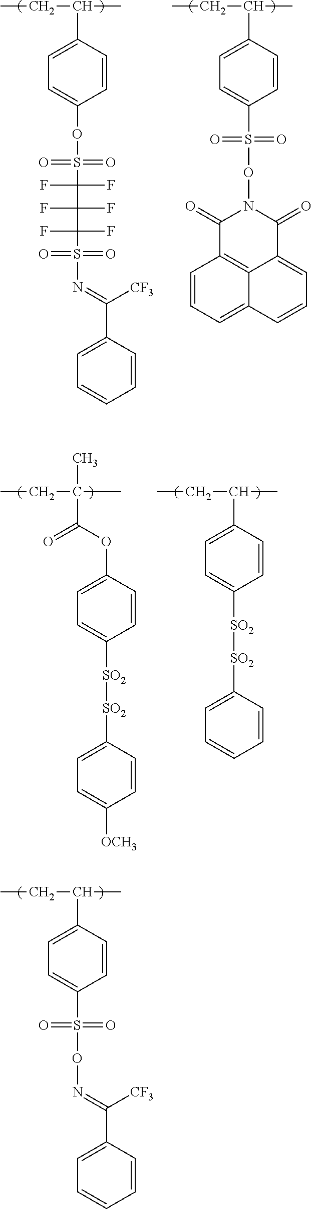

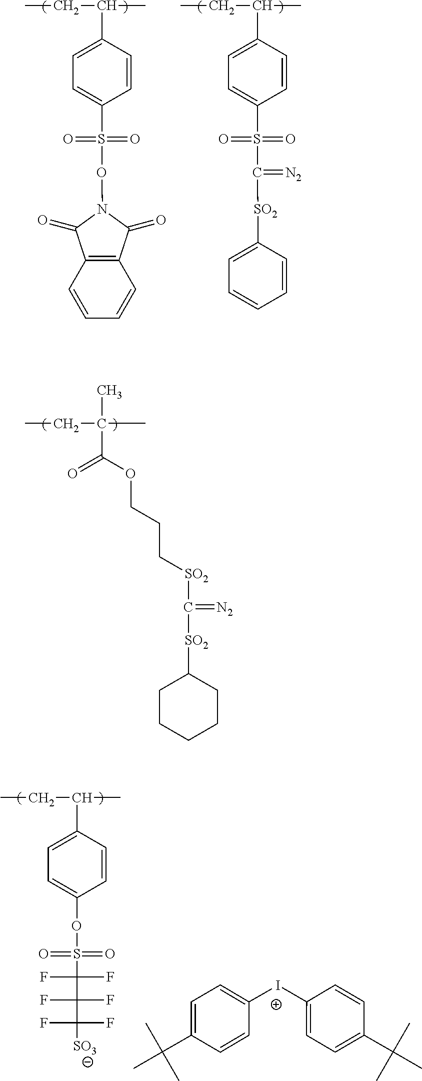

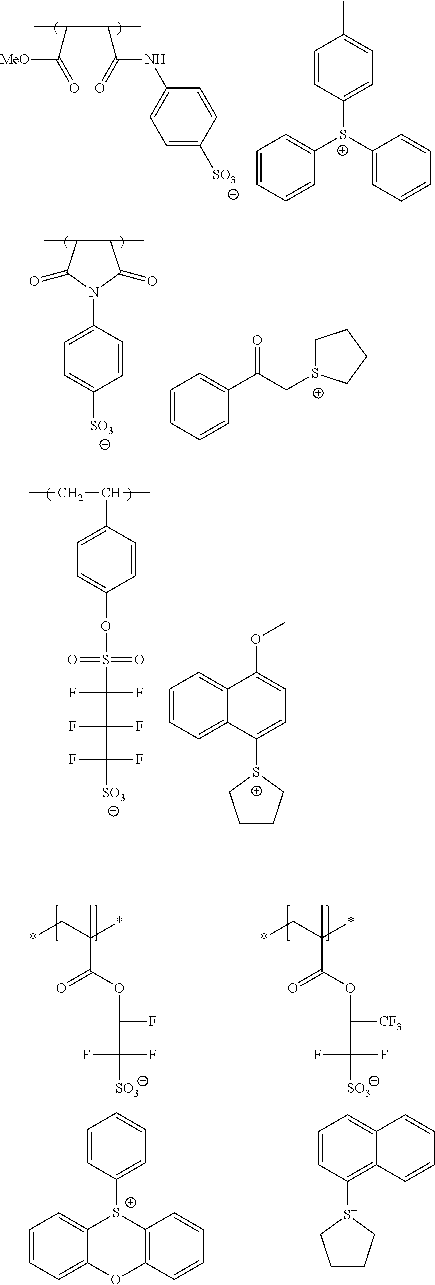

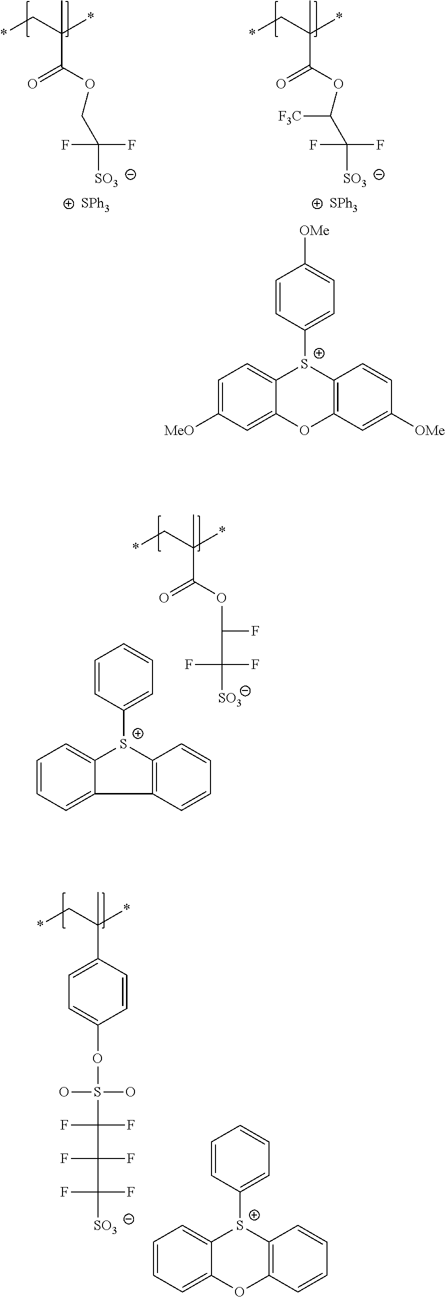

The content of the repeating unit (A1) including the structural part (a) that is decomposed by irradiation with actinic rays or radiation to generate an acid anion on a side chain in the polymer compound (A) is preferably in a range of 1 to 40 mol %, more preferably in a range of 2 to 30 mol %, and particularly preferably in a range of 4 to 25 mol % with respect to all repeating units in the polymer compound (A).

<Repeating Unit (b) Represented by Formula (I)>

The polymer compound (A) contains a repeating unit (b) that is represented by the following Formula (I).

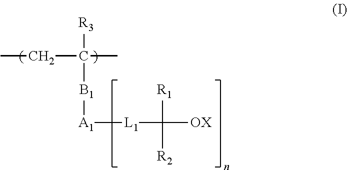

In the formula, R₃ represents a hydrogen atom, an organic group, or a halogen atom.

A₁ represents an aromatic ring group or an alicyclic group.

R₁ and R₂ each independently represent an alkyl group, a cycloalkyl group, or an aryl group.

At least two of A₁, R₁, or R₂ may be bonded to each other to form a ring.

B₁ and L₁ each independently represent a single bond or a divalent linking group.

X represents a hydrogen atom or an organic group.

n represents an integer of 1 or greater.

In a case where n represents an integer of 2 or greater, a plurality of L₁'s, a plurality of R₁'s, a plurality of R₂'s, and a plurality of X's may be the same as or different from each other, respectively.

In a case where R₃ represents an organic group, an alkyl group, a cycloalkyl group, and an aryl group are preferred as the organic group, and a linear or branched alkyl group having 1 to 10 carbon atoms (for example, a methyl group, an ethyl group, a propyl group, a butyl group, and a pentyl group), a cycloalkyl group having 3 to 10 carbon atoms (for example, a cyclopentyl group, a cyclohexyl group, and a norbornyl group), and an aryl group having 6 to 10 carbon atoms (for example, a phenyl group and a naphthyl group) are more preferred.

The organic group may further have a substituent. Examples of the substituent include, but are not limited to, a halogen atom (preferably a fluorine atom), a carboxyl group, a hydroxyl group, an amino group, and a cyano group. As the substituent, a fluorine atom and a hydroxyl group are particularly preferred.

Examples of the organic group in a case where the organic group further has a substituent include a trifluoromethyl group and a hydroxymethyl group.

R₃ is preferably a hydrogen atom or a methyl group, and is more preferably a hydrogen atom.

In a case where A₁ represents an aromatic ring group, the aromatic ring group is preferably a group in which n+1 hydrogen atoms are removed from a monocyclic or polycyclic aromatic ring (n represents an integer of 1 or greater).

Examples of the aromatic ring include aromatic hydrocarbon rings (preferably having 6 to 18 carbon atoms) such as a benzene ring, a naphthalene ring, an anthracene ring, a fluorene ring, and a phenanthrene ring, and aromatic hetero rings including a hetero ring, such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, and a thiazole ring. Among these, a benzene ring and a naphthalene ring are preferred, and a benzene ring is most preferred from the viewpoint of resolution.

In a case where A₁ represents an alicyclic group, the alicyclic group may be monocyclic or polycyclic. Specifically, it is preferably a group in which n+1 hydrogen atoms are removed from a monocyclic or polycyclic alicyclic ring (preferably an alicyclic ring having 3 to 18 carbon atoms) (n represents an integer of 1 or greater), and more preferably a group (a group in which n hydrogen atoms are removed from a monovalent alicyclic group) corresponding to a monocyclic or polycyclic monovalent alicyclic group.

Examples of the monocyclic alicyclic group include a group corresponding to a cycloalkyl group or a cycloalkenyl group such as a cyclopropyl group, a cyclobutyl group, a cycloheptyl group, a cyclohexyl group, a cyclopentyl group, a cyclooctyl group, a cyclononyl group, a cyclodecanyl group, a cycloundecanyl group, a cyclododecanyl group, a cyclohexenyl group, a cyclohexadienyl group, a cyclopentenyl group, and a cyclopentadienyl group, and a group corresponding to a cyclohexyl group or a cyclopentyl group is preferred.

Examples of the polycyclic alicyclic group include a group having a bicyclo, tricyclo, or tetracyclo structure, and examples thereof include a group corresponding to a bicyclobutyl group, a bicyclooctyl group, a bicyclononyl group, a bicycloundecanyl group, a bicyclooctenyl group, a bicyclotridecenyl group, an adamantyl group, an isobornyl group, a norbornyl group, a camphanyl group, an α-pinenyl group, a tricyclodecanyl group, a tetracyclododecyl group, or an androstanyl group. Preferred examples thereof include a group corresponding to an adamantyl group, a decalin group, a norbornyl group, a cedrol group, a cyclohexyl group, a cycloheptyl group, a cyclooctyl group, a cyclodecanyl group, a cyclododecanyl group, or a tricyclodecanyl group, and most preferred examples thereof include a group corresponding to an adamantyl group from the viewpoint of dry etching resistance.

Some carbon atoms in the monocyclic or polycyclic alicyclic group may be substituted with hetero atoms such as oxygen atoms.

A₁ and at least one of R₁ or R₂ may be bonded to each other to form a ring. A₁, R₁, and R₂ are preferably bonded to each other to form a polycyclic alicyclic ring having 5 to 12 carbon atoms, and particularly preferably form an adamantane ring.

The aromatic ring group or the alicyclic group of A₁ may have a substituent, and examples of the substituent include an alkyl group, a halogen atom, a hydroxyl group, an alkoxy group, a carboxyl group, an alkoxycarbonyl group, an alkylcarbonyl group, an alkylcarbonyloxy group, an alkylsulfonyloxy group, and an arylcarbonyl group.

R₁ and R₂ each independently represent an alkyl group, a cycloalkyl group, or an aryl group. R₁ and R₂ may be bonded to each other to form a ring together with carbon atoms to which R₁ and R₂ are bonded.

R₁ and R₂ each independently preferably represent an alkyl group having 1 to 10 carbon atoms or a cycloalkyl group having 3 to 10 carbon atoms, and more preferably represent an alkyl group having 1 to 5 carbon atoms.

R₁ and R₂ each may have a substituent, and examples of the substituent include an alkyl group, a halogen atom, a hydroxyl group, an alkoxy group, a carboxyl group, an alkoxycarbonyl group, an alkylcarbonyl group, an alkylcarbonyloxy group, an alkylsulfonyloxy group, and an arylcarbonyl group.

Examples of R₁ and R₂ in a case where these have a substituent include a benzyl group and a cyclohexylmethyl group.

In a case where X represents an organic group, the organic group is preferably an alkyl group, a cycloalkyl group, an aryl group, or an acyl group, and more preferably an alkyl group or an acyl group.

X is preferably a hydrogen atom, an alkyl group, or an acyl group, and more preferably a hydrogen atom, an alkyl group having 1 to 5 carbon atoms, or an acyl group having 2 to 5 carbon atoms.

B₁ represents a single bond or a divalent linking group.

In a case where B₁ represents a divalent linking group, a group that is preferred as the divalent linking group is a carbonyl group, an alkylene group, an arylene group, a sulfonyl group, —O—, —NH—, or a group obtained by the combination of these (for example, an ester bond).

B₁ preferably represents a divalent linking group that is represented by the following Formula (B).

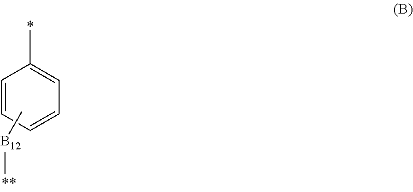

In Formula (B), B₁₂ represents a single bond or a divalent linking group.

* represents a direct bond that is bonded to a main chain.

** represents a direct bond that is bonded to A₁.

In a case where B₁₂ represents a divalent linking group, the divalent linking group is an alkylene group. —O—, or a group obtained by the combination of these.

B₁ preferably represents a divalent linking group that is represented by the following Formula (B-1).

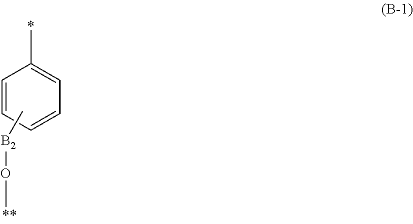

In Formula (B-1), B₂ represents a single bond or a divalent linking group.

* represents a direct bond that is bonded to a main chain.

** represents a direct bond that is bonded to A₁.

In a case where B₂ represents a divalent linking group, an alkylene group and an alkyleneoxy group are preferred as the divalent linking group, and an alkylene group having 1 to 5 carbon atoms and an alkyleneoxy group having 1 to 5 carbon atoms are more preferred. In a case where B₂ represents an alkyleneoxy group, the oxy group of the alkyleneoxy group and any one of carbon atoms constituting the benzene ring that is represented by Formula (B-1) are bonded to each other.

B₁ is particularly preferably a single bond, a carbonyloxy group, a divalent linking group that is represented by Formula (B), or a divalent linking group that is represented by Formula (B-1).

In Formula (I), L₁ represents a single bond or a divalent linking group, preferably represents a single bond or an alkylene group, more preferably represents a single bond or a methylene group, and even more preferably represents a single bond.

In Formula (I), n represents an integer of 1 or greater, preferably represents an integer of 1 to 5, more preferably represents an integer of 1 to 3, even more preferably represents an integer of 1 or 2, and particularly preferably represents 1.

The above Formula (I) is preferably the following Formula (I-2).

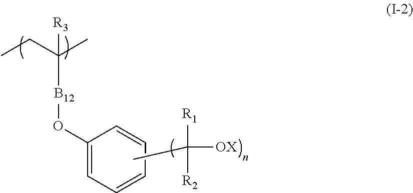

In the formula, R₁ and R₂ each independently represent an alkyl group, a cycloalkyl group, or an aryl group.

R₃ represents a hydrogen atom, an organic group, or a halogen atom.

B₁₂ represents a single bond or a divalent linking group.

X represents a hydrogen atom or an organic group.

n represents an integer of 1 or greater.

In a case where n represents an integer of 2 or greater, a plurality of R₁'s, a plurality of R₂'S, and a plurality of X's may be the same as or different from each other, respectively.

R₁ and R₂ in Formula (I-2) each independently preferably represent an alkyl group having 1 to 10 carbon atoms or a cycloalkyl group having 3 to 10 carbon atoms, and more preferably represent an alkyl group having 1 to 5 carbon atoms.

R₃ and X in Formula (I-2) are synonymous with R₃ and X in Formula (I), respectively. Also, preferred ranges thereof are the same as those of R₃ and X in Formula (I).

B₁₂ in Formula (I-2) is synonymous with B₁₂ in Formula (B). Also, a preferred range thereof is the same as that of B₁₂ in Formula (B).

n in Formula (I-2) preferably represents an integer of 1 to 5, more preferably represents an integer of 1 to 3, and even more preferably represents 1 or 2.

The above Formula (I) is preferably the following Formula (I-3).

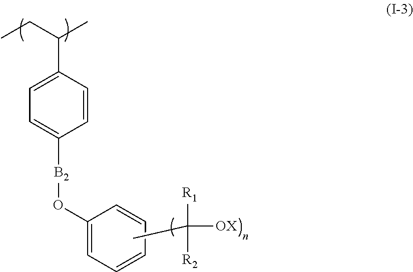

In the formula, R₁ and R₂ each independently represent an alkyl group, a cycloalkyl group, or an aryl group.

B₂ represents a single bond or a divalent linking group.

X represents a hydrogen atom or an organic group.

n represents an integer of 1 or greater.

In a case where n represents an integer of 2 or greater, a plurality of R₁'s, a plurality of R₂'s, and a plurality of X's may be the same as or different from each other, respectively.

R₁ and R₂ in Formula (I-3) each independently preferably represent an alkyl group having 1 to 10 carbon atoms or a cycloalkyl group having 3 to 10 carbon atoms, and more preferably represent an alkyl group having 1 to 5 carbon atoms.

X in Formula (I-3) is synonymous with X in Formula (I). Also, a preferred range thereof is the same as that of X in Formula (I).

B₂ in Formula (I-3) is synonymous with B₂ in Formula (B). Also, a preferred range thereof is the same as that of B₂ in Formula (B).

n in Formula (I-3) preferably represents an integer of 1 to 5, more preferably represents an integer of 1 to 3, and even more preferably represents 1 or 2.

Specific examples of the repeating unit (b) that is represented by Formula (I) will be shown below, but are not limited thereto. Me represents a methyl group, and Ac represents an acetyl group.

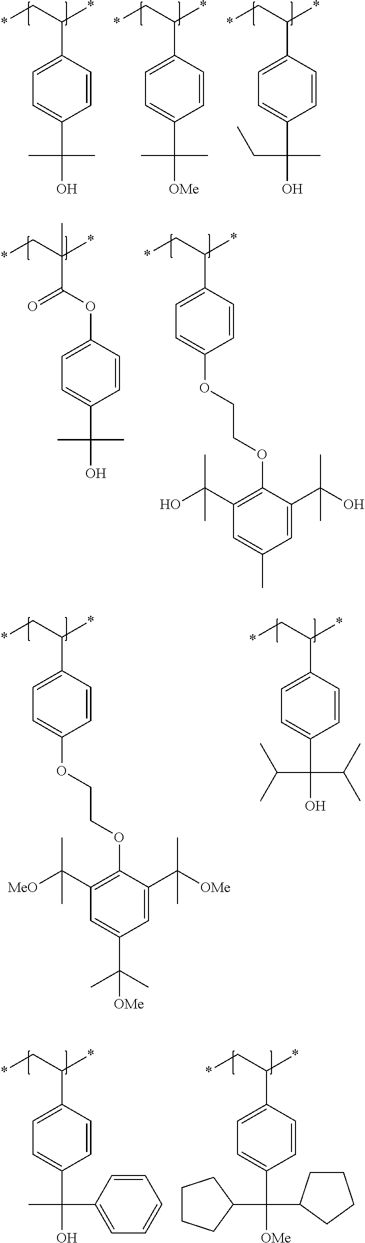

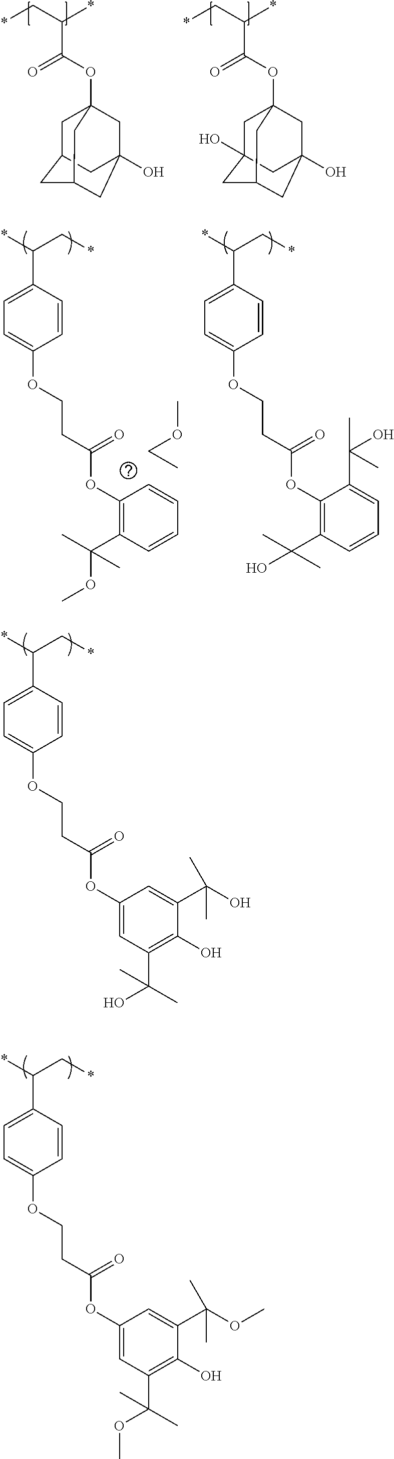

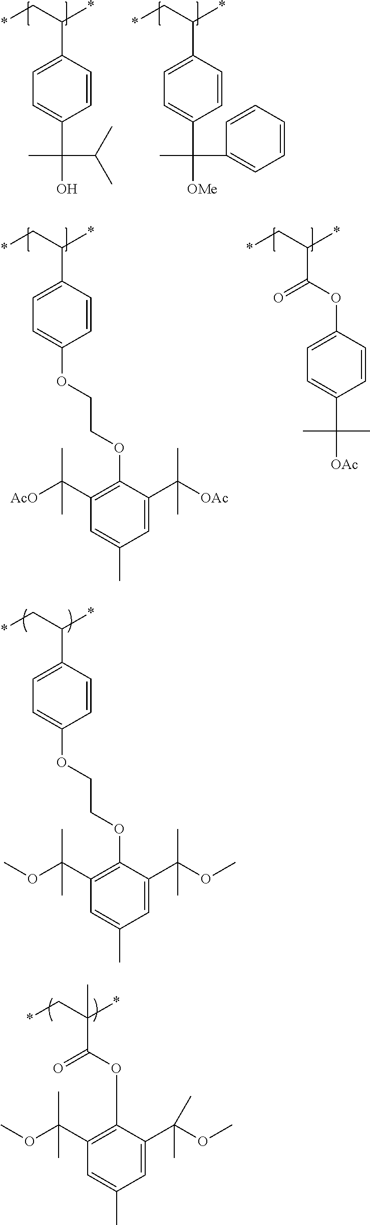

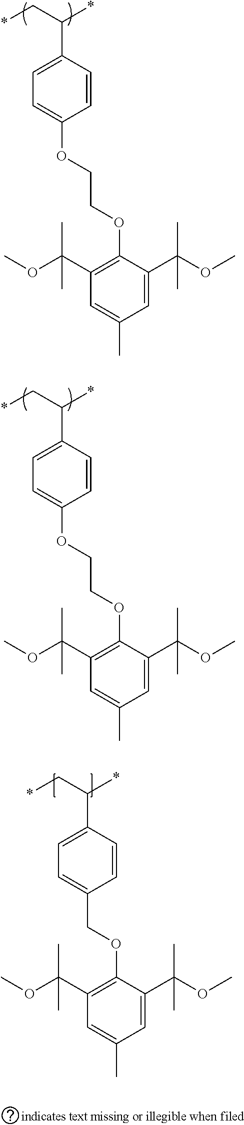

The content of the repeating unit (b) that is represented by Formula (I) is preferably 1 to 60 mol %, more preferably 3 to 50 mol %, and even more preferably 5 to 40 mol % with respect to all repeating units in the polymer compound (A).

<Repeating Unit (c) Represented by Formula (II)>

The polymer compound (A) of the invention preferably further contains a repeating unit (c) that is represented by the following Formula (II), in addition to the structural part (a) that is decomposed by irradiation with actinic rays or radiation to generate an acid anion on a side chain and the repeating unit (b) that is represented by Formula (I).

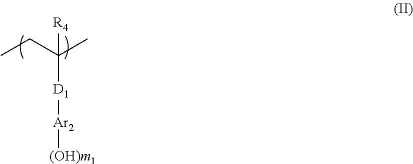

In the formula, R₄ represents a hydrogen atom, an organic group, or a halogen atom.

D₁ represents a single bond or a divalent linking group.

Ar₂ represents an aromatic ring group.

m₁ represents an integer of 1 or greater.

In a case where R₄ in Formula (II) represents an organic group, an alkyl group, a cycloalkyl group, and an aryl group are preferred as the organic group, and a linear or branched alkyl group having 1 to 10 carbon atoms (for example, a methyl group, an ethyl group, a propyl group, a butyl group, and a pentyl group), a cycloalkyl group having 3 to 10 carbon atoms (for example, a cyclopentyl group, a cyclohexyl group, and a norbornyl group), and an aryl group having 6 to 10 carbon atoms (for example, a phenyl group and a naphthyl group) are more preferred.

The organic group may further have a substituent. Examples of the substituent include, but are not limited to, a halogen atom (preferably a fluorine atom), a carboxyl group, a hydroxyl group, an amino group, and a cyano group. As the substituent, a fluorine atom and a hydroxyl group are particularly preferred.

Examples of the organic group in a case where the organic group further has a substituent include a trifluoromethyl group and a hydroxymethyl group.

R₄ is preferably a hydrogen atom or a methyl group, and is more preferably a hydrogen atom.

In a case where D₁ represents a divalent linking group, a carbonyl group, an alkylene group, an arylene group, a sulfonyl group, —O—, —NH—, or a group obtained by the combination of these (for example, an ester bond) is preferred as the divalent linking group.

D₁ is preferably a single bond or a carbonyloxy group, and more preferably a single bond.

The aromatic ring group represented by Ar₂ is preferably a group in which n+1 hydrogen atoms are removed from a monocyclic or polycyclic aromatic ring (n represents an integer of 1 or greater).

Examples of the aromatic ring include aromatic hydrocarbon rings (preferably having 6 to 18 carbon atoms) that may have a substituent, such as a benzene ring, a naphthalene ring, an anthracene ring, a fluorene ring, and a phenanthrene ring, and aromatic hetero rings including a hetero ring, such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, and a thiazole ring. Among these, a benzene ring and a naphthalene ring are preferred, and a benzene ring is most preferred from the viewpoint of resolution.

m₁ is preferably an integer of 1 to 5, more preferably an integer of 1 to 3, even more preferably 1 or 2, and particularly preferably 1.

In a case where m₁ represents 1 and Ar₂ represents a benzene ring, the substitution position of —OH may be a para-position, a meta-position, or an ortho-position with respect to a bonding position of the benzene ring to the polymer main chain. From the viewpoint of alkali developability, the substitution position is preferably a para-position.

The aromatic ring in the aromatic ring group of Ar₂ may have a substituent other than the group represented by —OH. Examples of the substituent include an alkyl group, a halogen atom, a hydroxyl group, an alkoxy group, a carboxyl group, an alkoxycarbonyl group, an alkylcarbonyl group, an alkylcarbonyloxy group, an alkylsulfonyloxy group, and an arylcarbonyl group.

Formula (II) is preferably the following Formula (II-1).

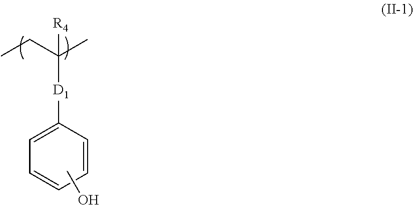

In the formula, R₄ represents a hydrogen atom, an organic group, or a halogen atom.

D₁ represents a single bond or a divalent linking group.

R₄ and D₁ in Formula (II-1) are synonymous with R₄ and D₁ in Formula (II), respectively. Also, preferred ranges thereof are the same as those of R₄ and D₁ in Formula (II).

Formula (II) is more preferably the following Formula (II-2).

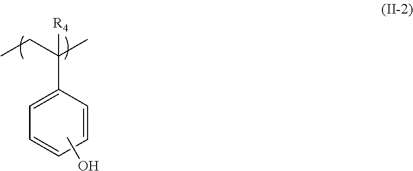

In the formula. R₄ represents a hydrogen atom, an organic group, or a halogen atom.

R₄ in Formula (II-2) is synonymous with R₄ in Formula (II). Also, a preferred range thereof is the same as that of R₄ in Formula (II).

Specific examples of the repeating unit (c) that is represented by Formula (II) will be shown below, but are not limited thereto. Me represents a methyl group.

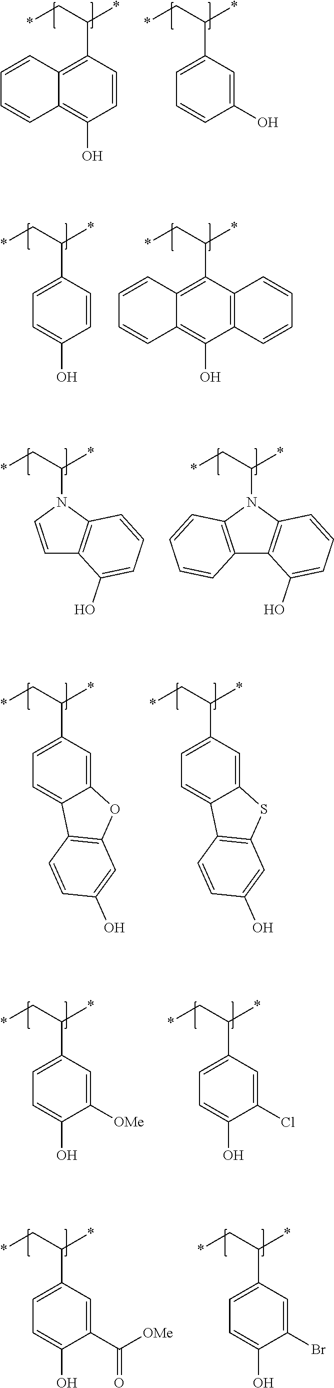

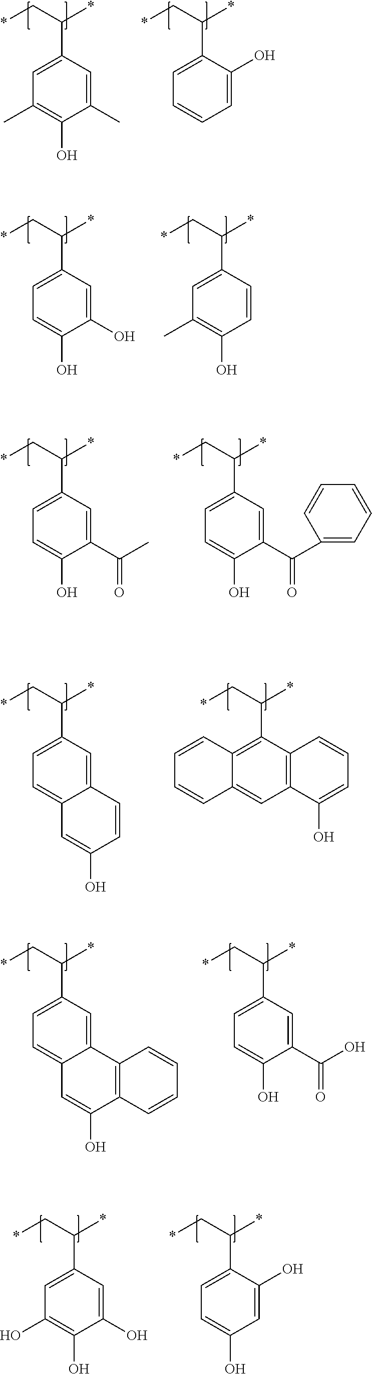

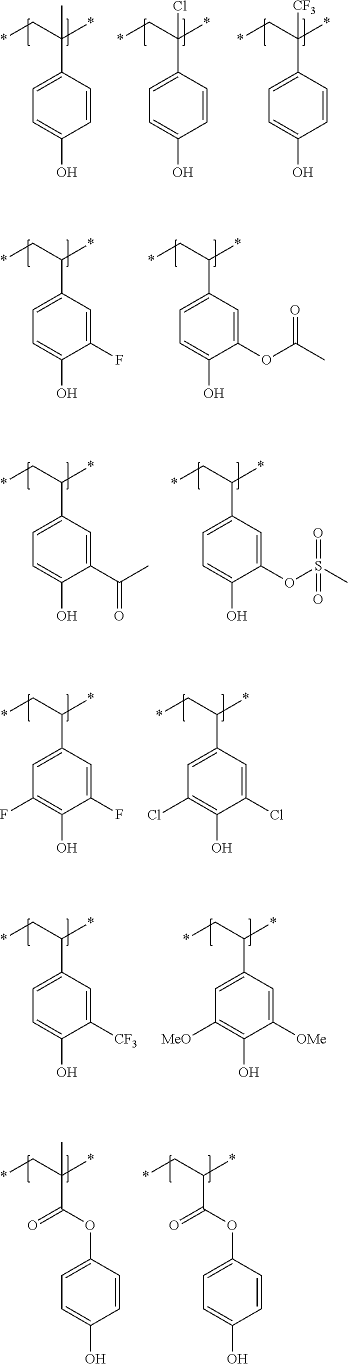

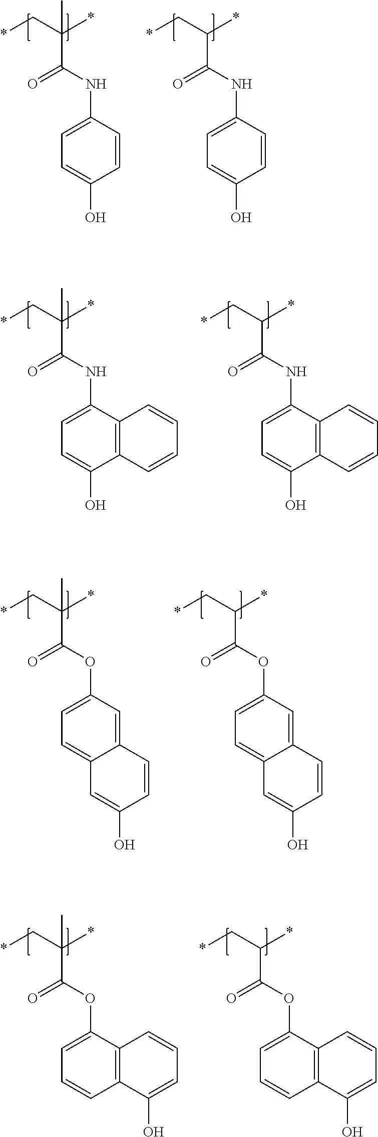

The polymer compound (A) of the invention may not contain the repeating unit (c) that is represented by Formula (II). In a case where the polymer compound (A) contains the repeating unit (c) that represented by Formula (II), the content of the repeating unit (c) that is represented by Formula (II) is preferably 10 to 90 mol %, more preferably 30 to 90 mol %, and even more preferably 40 to 90 mol % with respect to all repeating units in the polymer compound (A). Accordingly, particularly, in a case where the resist film is a thin film (for example, in a case where the resist film has a thickness of 10 to 150 nm), the dissolution rate of an exposed part of the resist film of the invention formed of the polymer compound (A) in an alkaline developer can be more securely reduced (that is, the dissolution rate of the resist film using the polymer compound (A) can be more securely controlled to be optimal). As a result, the sensitivity can be more securely improved.

<Other Repeating Units>

The polymer compound (A) of the invention may contain other repeating units. Hereinafter, other repeating units will be described.

Examples of other repeating units that may be contained in the polymer compound (A) include a repeating unit that is represented by the following Formula (III).

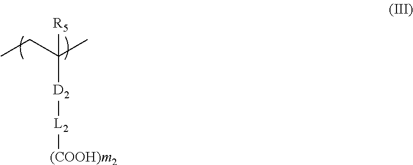

In the formula, R₅ represents a hydrogen atom, an organic group, or a halogen atom.

D₂ represents a single bond or —COR³⁰—.

R³⁰ represents —O— or —NH—.

L₂ represents a single bond, an alkylene group, an arylene group, an amino group, or a group obtained by the combination of two or more of these.

m₂ represents an integer of 1 or greater.

In Formula (III), R₅ and m₂ are synonymous with R₄ and m₁ in Formula (II), respectively. Also, preferred ranges thereof are the same as those of R₄ and m₁ in Formula (II).

In Formula (III). D₂ preferably represents a single bond or —COO— (R³⁰ preferably represents —O—). D₂ more preferably represents a single bond.

In Formula (III), L₂ preferably represents a single bond or an alkylene group having 1 to 5 carbon atoms, and more preferably represents a single bond.

Specific examples of the repeating unit that is represented by Formula (III) will be shown below, but are not limited thereto.

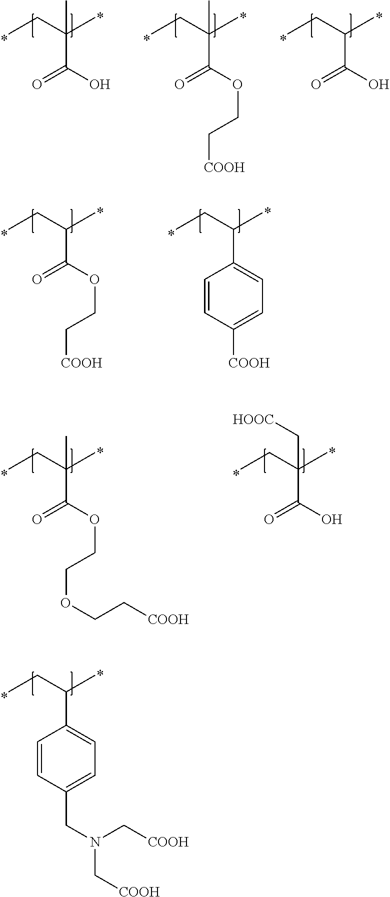

The polymer compound (A) of the invention may not contain the repeating unit that is represented by Formula (III). In a case where the polymer compound (A) contains the repeating unit that is represented by Formula (III), the content of the repeating unit that is represented by Formula (II) is preferably 1 to 30 mol %, more preferably 2 to 20 mol %, and even more preferably 3 to 10 mol % with respect to all repeating units in the polymer compound (A).

Examples of other repeating units that may be contained in the polymer compound (A) of the invention also include a repeating unit that is represented by the following Formula (IV) or the following Formula (V).

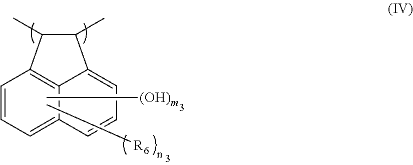

In the formula. R₆ represents a hydrogen atom, an organic group, or a halogen atom.

m₃ represents an integer of 0 to 6.

n₃ represents an integer of 0 to 6.

m₃+n₃ is equal to or less than 6.

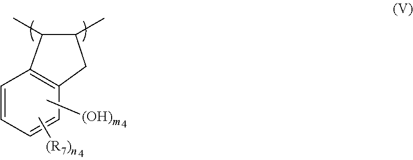

In the formula, R₇ represents a hydrogen atom, an organic group, or a halogen atom.

m₄ represents an integer of 0 to 4.

n₄ represents an integer of 0 to 4.

m₄+n₄ is equal to or less than 4.

In a case where R₆ and R₇ in Formula (IV) and Formula (V) represent an organic group, an alkyl group, a cycloalkyl group, an acyloxy group, and an alkoxy group are preferred as the organic group, and a linear or branched alkyl group having 1 to 6 carbon atoms, a cycloalkyl group having 3 to 10 carbon atoms, a linear, branched, or cyclic acyloxy group having 2 to 8 carbon atoms, and a linear, branched, or cyclic alkoxy group having 1 to 6 carbon atoms are more preferred.

The organic group may further have a substituent. Examples of the substituent include, but are not limited to, a halogen atom (preferably a fluorine atom), a carboxyl group, a hydroxyl group, an amino group, and a cyano group.

m₃ and m₄ in Formula (IV) and Formula (V) preferably represent an integer of 0 to 3, more preferably represent 0 or 1, and even more preferably represent 0.

n₃ and n₄ in Formula (IV) and Formula (V) preferably represent an integer of 0 to 3, more preferably represent 0 or 1, and even more preferably represent 0.

Specific examples of the repeating unit that is represented by Formula (IV) or Formula (V) will be shown below, but are not limited thereto.

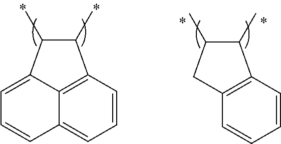

The polymer compound (A) of the invention may not contain the repeating unit that is represented by Formula (IV). In a case % here the polymer compound (A) contains the repeating unit that is represented by Formula (IV), the content of the repeating unit that is represented by Formula (IV) is preferably 1 to 30 mol %, more preferably 2 to 20 mol %, and even more preferably 3 to 15 mol % with respect to all repeating units in the polymer compound (A).

The polymer compound (A) of the invention may not contain the repeating unit that is represented by Formula (V). In a case where the polymer compound (A) contains the repeating unit that is represented by Formula (V), the content of the repeating unit that is represented by Formula (V) is preferably 1 to 30 mol %, more preferably 2 to 20 mol %, and even more preferably 3 to 10 mol % with respect to all repeating units in the polymer compound (A).

Examples of other repeating units that may be contained in the polymer compound (A) of the invention also include a repeating unit having an alcoholic hydroxyl group, that is different from the repeating unit (b) that is represented by the above Formula (I). As the repeating unit having an alcoholic hydroxyl group, that is different from the repeating unit (b) that is represented by the above Formula (I), a repeating unit that is represented by the following Formula (VI) is preferred.

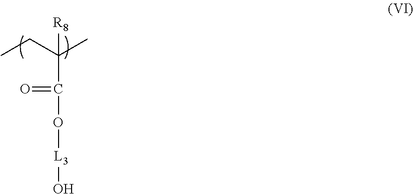

In the formula. R_{R} represents a hydrogen atom, an organic group, or a halogen atom.

L₃ represents a linear or branched alkylene group.

In Formula (VI), R₈ is synonymous with R₄ in Formula (II). Also, a preferred range thereof is the same as that of R₄ in Formula (II).

In Formula (VI), L₃ preferably represents a linear alkylene group having 1 to 5 carbon atoms.

Specific examples of the repeating unit that is represented by Formula (VI) will be shown below, but are not limited thereto.

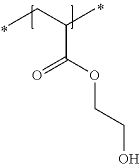

The polymer compound (A) of the invention may not contain the repeating unit that is represented by Formula (VI). In a case where the polymer compound (A) contains the repeating unit that is represented by Formula (VI), the content of the repeating unit that is represented by Formula (VI) is preferably 1 to 30 mol %, more preferably 2 to 20 mol %, and even more preferably 3 to 10 mol % with respect to all repeating units in the polymer compound (A).

Examples of other repeating units that may be contained in the polymer compound (A) of the invention also include a repeating unit having a group having a non-acid decomposable polycyclic alicyclic hydrocarbon structure and a repeating unit having a group having a non-acid decomposable aromatic ring structure.

In the invention, the non-acid decomposable property means a property in which a decomposition reaction is not caused by an acid generated from the structural part (a) that generates an acid anion on a side chain by irradiation with actinic rays or radiation.

More specifically, the group having a non-acid decomposable polycyclic alicyclic hydrocarbon structure is preferably a group stable to an acid and an alkali. The group stable to an acid and an alkali means a group that is not acid-decomposable and alkali-decomposable.

In the invention, the group having a polycyclic alicyclic hydrocarbon structure is not particularly limited as long as it is a monovalent group having a polycyclic alicyclic hydrocarbon structure. The total number of carbon atoms thereof is preferably 5 to 40, and more preferably 7 to 30. The polycyclic alicyclic hydrocarbon structure may have an unsaturated bond in the ring.

In the group having a polycyclic alicyclic hydrocarbon structure, the polycyclic alicyclic hydrocarbon structure means a structure having a plurality of monocyclic alicyclic hydrocarbon groups or a polycyclic alicyclic hydrocarbon structure, and may be a bridged structure. As the monocyclic alicyclic hydrocarbon group, a cycloalkyl group having 3 to 8 carbon atoms is preferred, and examples thereof include a cyclopropyl group, a cyclopentyl group, a cyclohexyl group, a cyclobutyl group, and a cyclooctyl group. The structure having a plurality of monocyclic alicyclic hydrocarbon groups has a plurality of these groups. The structure having a plurality of monocyclic alicyclic hydrocarbon groups preferably has 2 to 4 monocyclic alicyclic hydrocarbon groups, and particularly preferably has 2 monocyclic alicyclic hydrocarbon groups.

As the polycyclic alicyclic hydrocarbon structure, a bicyclo, tricyclo, or tetracyclo structure having 5 or more carbon atoms or the like can be exemplified, and a polycyclic cyclo structure having 6 to 30 carbon atoms is preferred. Examples thereof include an adamantane structure, a decalin structure, a norbornane structure, a norbornene structure, a cedrol structure, an isobornane structure, a bornane structure, a dicyclopentane structure, an α-pinene structure, a tricyclodecane structure, a tetracyclododecane structure, and an androstane structure. Some carbon atoms in the monocyclic or polycyclic cycloalkyl group may be substituted with hetero atoms such as oxygen atoms.

Preferred examples of the polycyclic alicyclic hydrocarbon structure include an adamantane structure, a decalin structure, a norbornane structure, a norbornene structure, a cedrol structure, a structure having a plurality of cyclohexyl groups, a structure having a plurality of cycloheptyl groups, a structure having a plurality of cyclooctyl groups, a structure having a plurality of cyclodecanyl groups, a structure having a plurality of cyclododecanyl groups, and a tricyclodecane structure, and an adamantane structure is most preferred from the viewpoint of dry etching resistance (that is, the group having a non-acid decomposable polycyclic alicyclic hydrocarbon structure is most preferably a group having a non-acid decomposable adamantane structure).

Chemical formulae of these polycyclic alicyclic hydrocarbon structures (regarding the structures having a plurality of monocyclic alicyclic hydrocarbon groups, monocyclic alicyclic hydrocarbon structures (specifically, structures of the following Formulae (47) to (50)) corresponding to the monocyclic alicyclic hydrocarbon groups) will be displayed below.

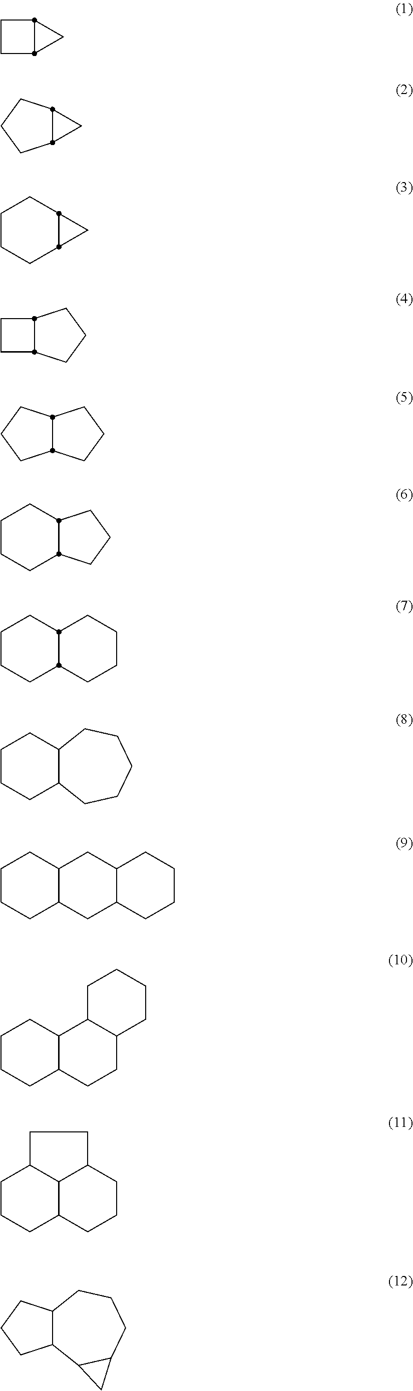

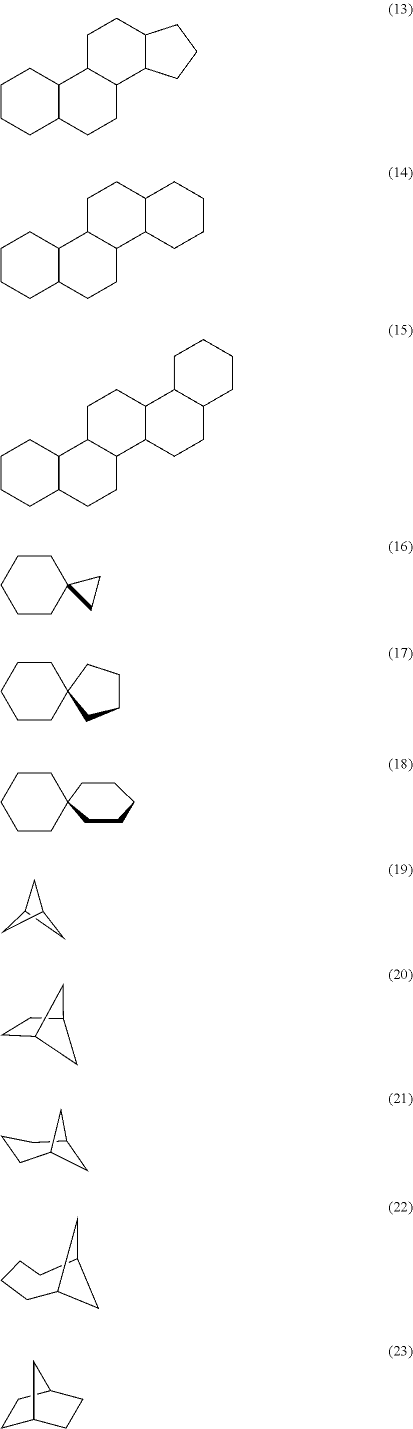

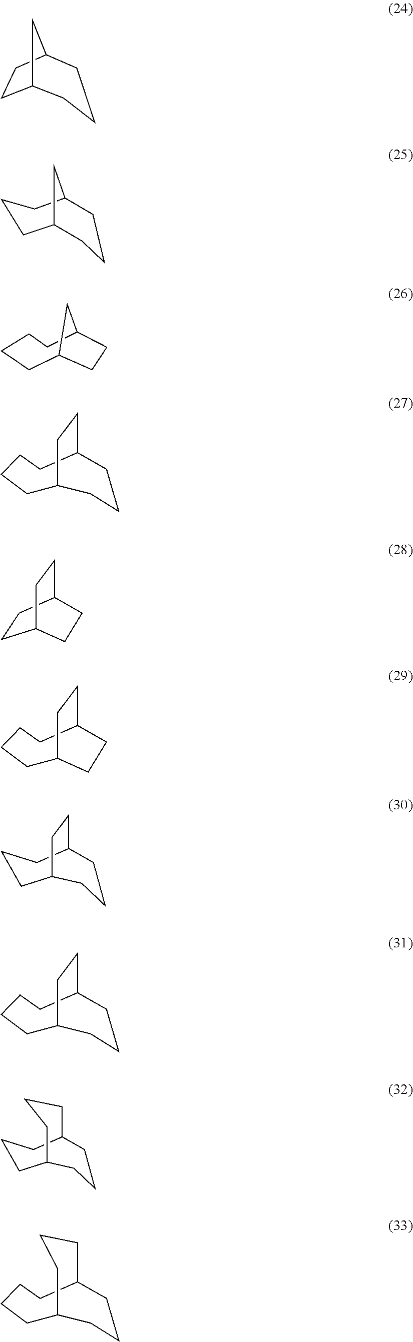

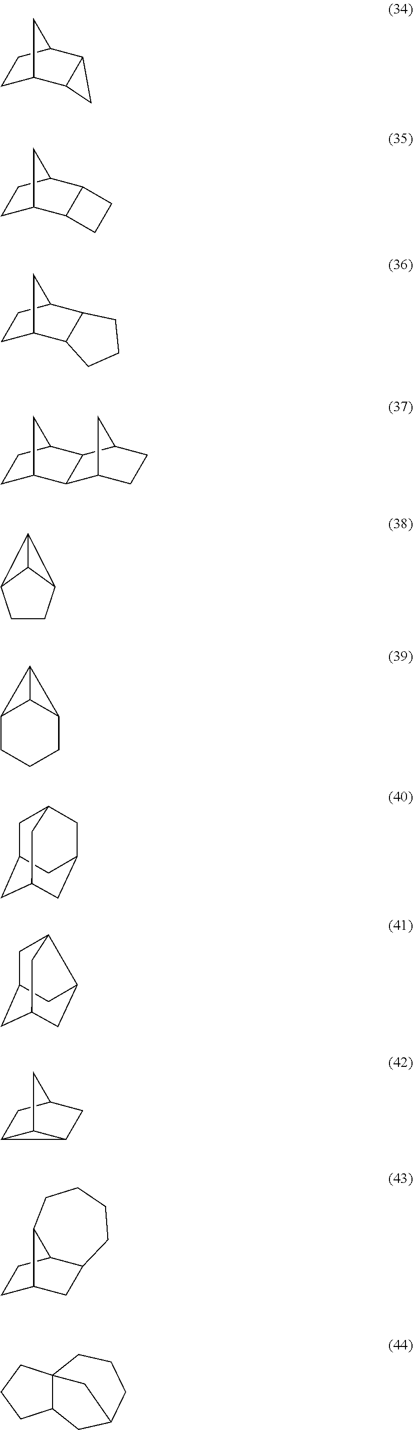

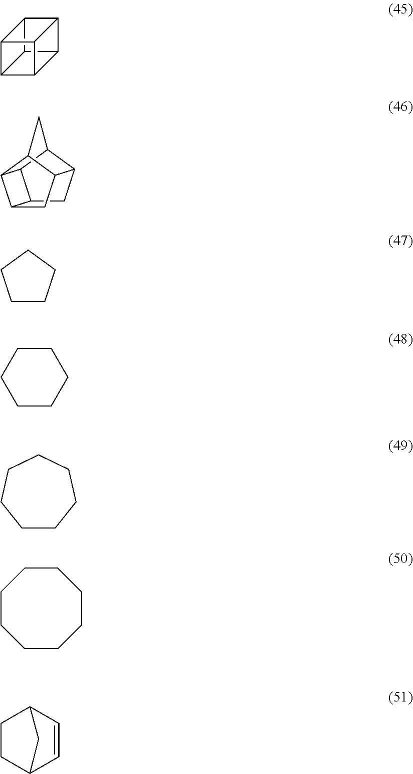

The polycyclic alicyclic hydrocarbon structure may further have a substituent, and examples of the substituent include an alkyl group (preferably having 1 to 6 carbon atoms), a cycloalkyl group (preferably having 3 to 10 carbon atoms), an aryl group (preferably having 6 to 15 carbon atoms), a halogen atom, a hydroxyl group, an alkoxy group (preferably having 1 to 6 carbon atoms), a carboxyl group, a carbonyl group, a thiocarbonyl group, an alkoxycarbonyl group (preferably having 2 to 7 carbon atoms), and a group obtained by the combination of these groups (the total number of carbon atoms is preferably 1 to 30, and more preferably 1 to 15).

As the polycyclic alicyclic hydrocarbon structure, a structure that is represented by any one of the above Formulae (7), (23), (40), (41), and (51) and a structure having two monovalent groups in which one arbitrary hydrogen atom in the structure of the above Formula (48) serves as a direct bond are preferred, a structure that is represented by any one of the above Formulae (23), (40), and (51), and a structure having two monovalent groups in which one arbitrary hydrogen atom in the structure of the above Formula (48) serves as a direct bond are more preferred, and a structure that is represented by the above Formula (40) is most preferred.

As the group having a polycyclic alicyclic hydrocarbon structure, a monovalent group in which one arbitrary hydrogen atom in the polycyclic alicyclic hydrocarbon structure serves as a direct bond is preferred.

The group having an aromatic ring structure is not particularly limited as long as it is a monovalent group having an aromatic ring. The total number of carbon atoms thereof is preferably 6 to 40, and more preferably 6 to 30. Examples of the aromatic ring include aromatic hydrocarbon rings that may have a substituent with 6 to 18 carbon atoms, such as a benzene ring, a naphthalene ring, an anthracene ring, a fluorene ring, and a phenanthrene ring. Among these, a benzene ring and a naphthalene ring are preferred, and a benzene ring is most preferred.

The group having an aromatic ring structure is preferably a monovalent group in which one arbitrary hydrogen atom of the aromatic ring structure serves as a direct bond.

The repeating unit having a non-acid decomposable polycyclic alicyclic hydrocarbon structure or the repeating unit having a non-acid decomposable aromatic ring structure is preferably a repeating unit that is represented by the following Formula (1).

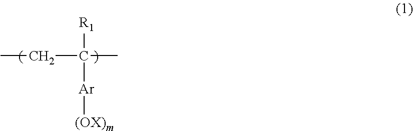

In the formula, R₁ represents a hydrogen atom or a methyl group, and X represents a group having a non-acid decomposable polycyclic alicyclic hydrocarbon structure or a group having a non-acid decomposable aromatic ring structure. Ar represents an aromatic ring, m is an integer of 1 or greater.

R₁ in Formula (1) represents a hydrogen atom or a methyl group, and a hydrogen atom is particularly preferred.

Examples of the aromatic ring of Ar of Formula (1) include aromatic hydrocarbon rings that may have a substituent with 6 to 18 carbon atoms, such as a benzene ring, a naphthalene ring, an anthracene ring, a fluorene ring, and a phenanthrene ring, and aromatic hetero rings including a hetero ring, such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, and a thiazole ring. Among these, a benzene ring and a naphthalene ring are preferred, and a benzene ring is most preferred from the viewpoint of resolution.

The aromatic ring of Ar may have a substituent other than the group represented by —OX. Examples of the substituent include an alkyl group (preferably having 1 to 6 carbon atoms), a cycloalkyl group (preferably having 3 to 10 carbon atoms), an aryl group (preferably having 6 to 15 carbon atoms), a halogen atom, a hydroxyl group, an alkoxy group (preferably having 1 to 6 carbon atoms), a carboxyl group, and an alkoxycarbonyl group (preferably having 2 to 7 carbon atoms). An alkyl group, an alkoxy group, and an alkoxycarbonyl group are preferred, and an alkoxy group is more preferred.

X represents a group having a non-acid decomposable polycyclic alicyclic hydrocarbon structure or a group having a non-acid decomposable aromatic ring structure. Specific examples and preferred ranges of the group having a non-acid decomposable polycyclic alicyclic hydrocarbon structure or the group having a non-acid decomposable aromatic ring structure represented by X are the same as those in the above description. X is more preferably a group represented by —Y—X₂ in Formula (2) to be described later.

m is preferably an integer of 1 to 5, and most preferably 1. In a case where m is 1 and Ar is a benzene ring, the substitution position of —OX may be a para-position, a meta-position, or an ortho-position with respect to a bonding position of the benzene ring to the polymer main chain. The substitution position is preferably a para-position or a meta-position, and more preferably a para-position.

Formula (1) is preferably the following Formula (2).

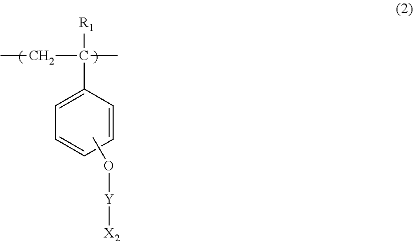

In the formula, R₁ represents a hydrogen atom or a methyl group, Y represents a single bond or a divalent linking group, and X₂ represents a non-acid decomposable polycyclic alicyclic hydrocarbon group or a non-acid decomposable aromatic ring group.

R₁ in Formula (2) represents a hydrogen atom or a methyl group, and is particularly preferably a hydrogen atom.

In Formula (2), Y is preferably a divalent linking group. The divalent linking group of Y is preferably a carbonyl group, a thiocarbonyl group, an alkylene group (preferably having 1 to 10 carbon atoms, and more preferably having 1 to 5 carbon atoms), a sulfonyl group, —COCH₂—, —NH—, or a divalent linking group obtained by the combination of these (the total number of carbon atoms is preferably 1 to 20, and more preferably 1 to 10), more preferably a carbonyl group. —COCH₂—, a sulfonyl group, —CONH—. —CSNH—, or an alkylene group, even more preferably a carbonyl group, —COCH₂—, or an alkylene group, and particularly preferably a carbonyl group or an alkylene group.

X₂ represents a polycyclic alicyclic hydrocarbon group or an aromatic ring group, and is non-acid decomposable.

The total number of carbon atoms of the polycyclic alicyclic hydrocarbon group is preferably 5 to 40, and more preferably 7 to 30. The polycyclic alicyclic hydrocarbon group may have an unsaturated bond in the ring.

Such a polycyclic alicyclic hydrocarbon group is a group having a plurality of monocyclic alicyclic hydrocarbon groups or a polycyclic alicyclic hydrocarbon group, and may be a bridged group. As the monocyclic alicyclic hydrocarbon group, a cycloalkyl group having 3 to 8 carbon atoms is preferred, and examples thereof include a cyclopropyl group, a cyclopentyl group, a cyclohexyl group, a cyclobutyl group, and a cyclooctyl group. A plurality of these groups is included. The group having a plurality of monocyclic alicyclic hydrocarbon groups preferably has two to four monocyclic alicyclic hydrocarbon groups, and particularly preferably has two monocyclic alicyclic hydrocarbon groups.

As the polycyclic alicyclic hydrocarbon group, a group having a bicyclo, tricyclo, or tetracyclo structure with 5 or more carbon atoms can be exemplified, and a group having a polycyclic cyclo structure having 6 to 30 carbon atoms is preferred. Examples thereof include an adamantyl group, a norbornyl group, a norbornenyl group, an isobornyl group, a camphanyl group, a dicyclopentyl group, an α-pinenyl group, a tricyclodecanyl group, a tetracyclododecyl group, and an androstanyl group. Some carbon atoms in the monocyclic or polycyclic cycloalkyl group may be substituted with hetero atoms such as oxygen atoms.

As the polycyclic alicyclic hydrocarbon group of X₂, an adamantyl group, a decalin group, a norbornyl group, a norbornenyl group, a cedrol group, a group having a plurality of cyclohexyl groups, a group having a plurality of cycloheptyl groups, a group having a plurality of cyclooctyl groups, a group having a plurality of cyclodecanyl groups, a group having a plurality of cyclododecanyl groups, and a tricyclodecanyl group are preferred, and an adamantyl group is most preferred.

Furthermore, the alicyclic hydrocarbon group may have a substituent.

The aromatic ring group of X₂ is not particularly limited as long as it is a monovalent group having an aromatic ring. The total number of carbon atoms thereof is preferably 6 to 40, and more preferably 6 to 30. Examples of the aromatic ring include aromatic hydrocarbon rings that may have a substituent with 6 to 18 carbon atoms, such as a benzene ring, a naphthalene ring, an anthracene ring, a fluorene ring, and a phenanthrene ring. Among these, a benzene ring and a naphthalene ring are preferred, and a benzene ring is most preferred.

The group having an aromatic ring structure in Formula (1) is preferably a monovalent group in which one arbitrary hydrogen atom in the aromatic ring structure is removed, more preferably a phenyl group or a naphthyl group, and even more preferably a phenyl group.

The repeating unit that is represented by Formula (1) is most preferably a repeating unit that is represented by the following Formula (2′).

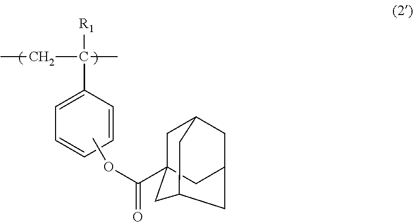

In the formula. R₁ represents a hydrogen atom or a methyl group.

R₁ in Formula (2′) represents a hydrogen atom or a methyl group, and is particularly preferably a hydrogen atom.

The substitution position of the adamantyl ester group in Formula (2′) may be a para-position, a meta-position, or an ortho-position, and is preferably a para-position with respect to a bonding position of the benzene ring to the polymer main chain.

Specific examples of the repeating unit that is represented by Formula (1) or Formula (2) are as follows.

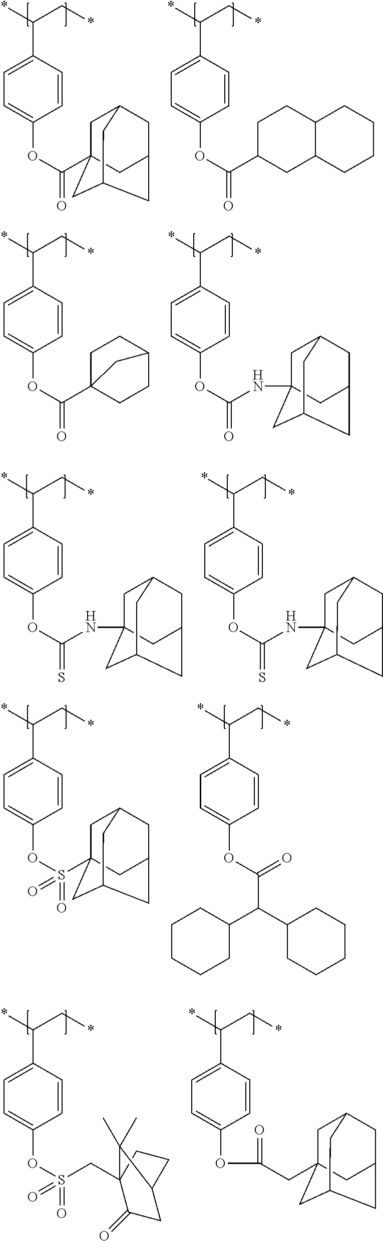

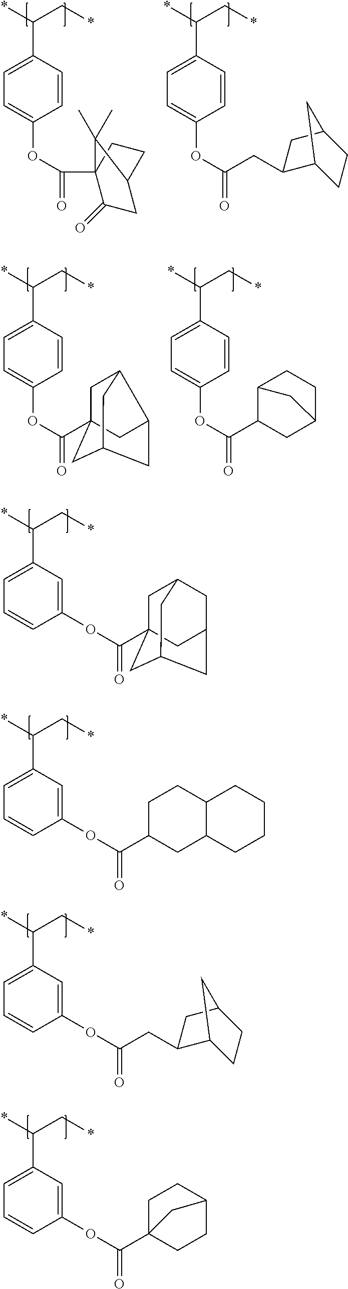

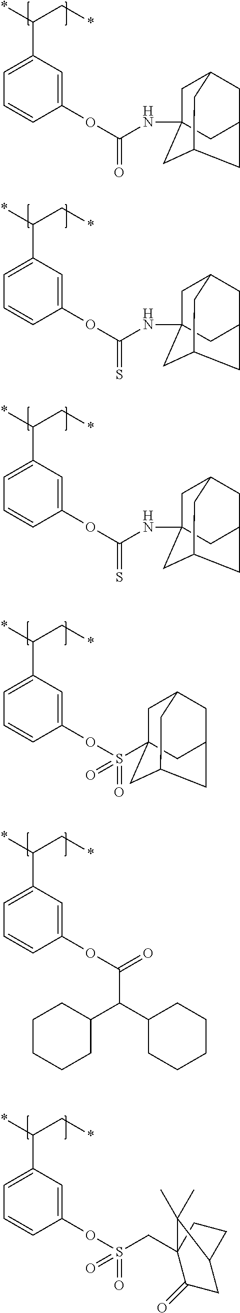

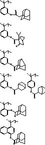

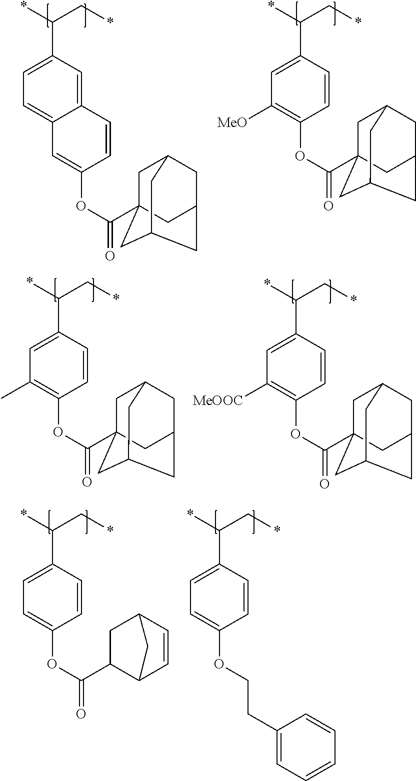

The polymer compound (A) of the invention may not contain the repeating unit that is represented by Formula (1). In a case where the polymer compound (A) contains the repeating unit that is represented by Formula (1), the content of the repeating unit that is represented by Formula (1) is preferably 10 to 90 mol %6, more preferably 20 to 80 mol %, and even more preferably 30 to 70 mol % with respect to all repeating units in the polymer compound (A).

In the invention, the polymer compound (A) is preferably a polymer compound including a repeating unit that is represented by the above Formula (1), a repeating unit that is represented by the above Formula (II), and a repeating unit that is represented by the above Formula (4), or a polymer compound including a repeating unit that is represented by the above Formula (I-2), a repeating unit that is represented by the above Formula (II-1), and a repeating unit that is represented by the above Formula (4). The polymer compound more preferably includes a repeating unit that is represented by the above Formula (I-3), a repeating unit that is represented by the above Formula (II-1), and a repeating unit that is represented by the above Formula (4).

Specific examples of the polymer compound (A) are as follows, but are not limited thereto.

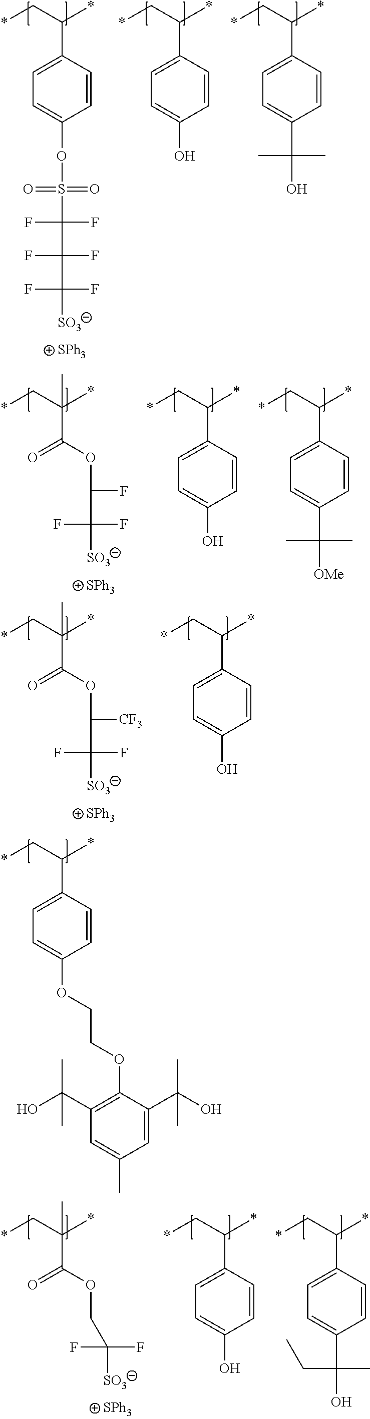

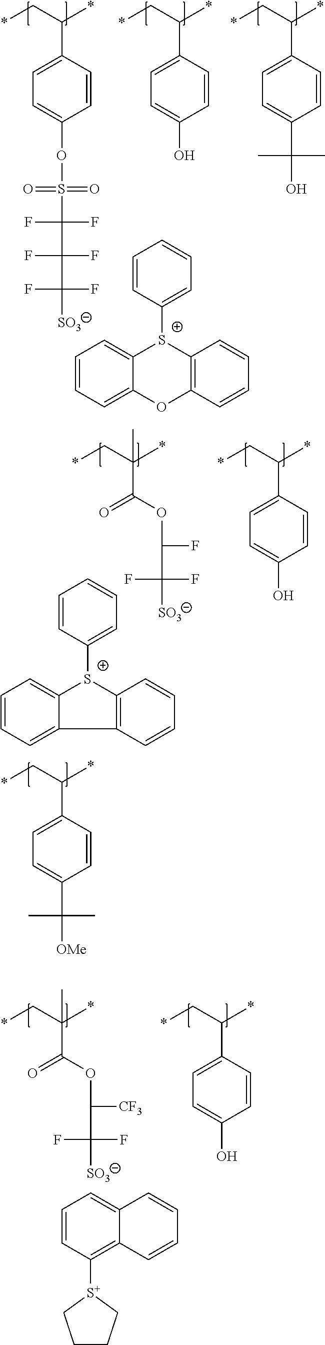

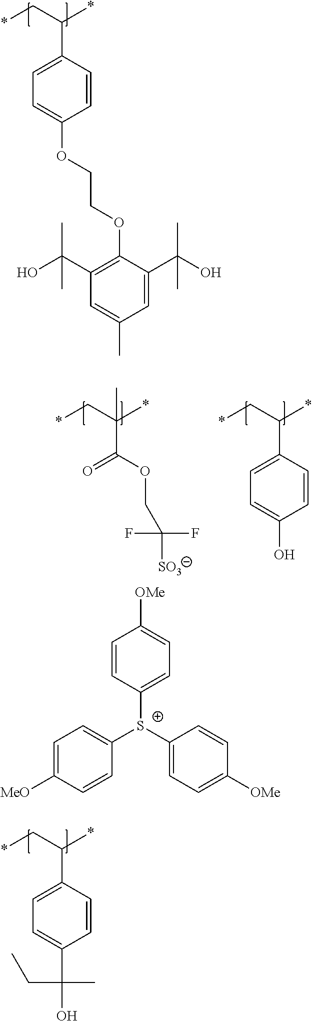

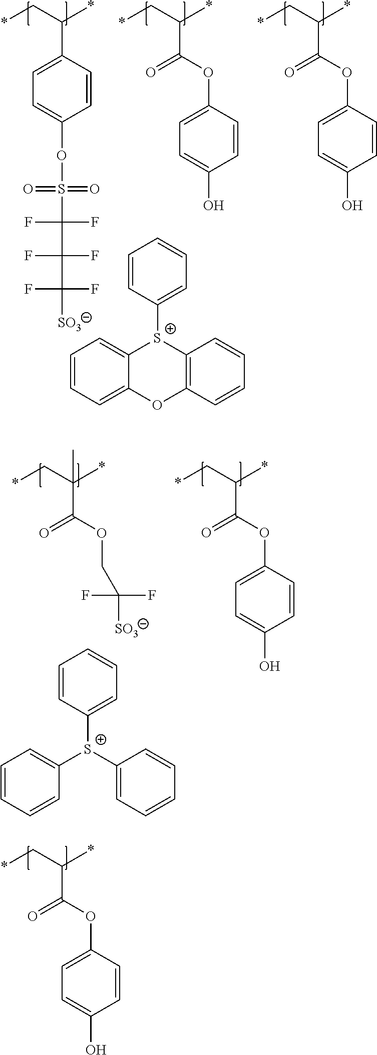

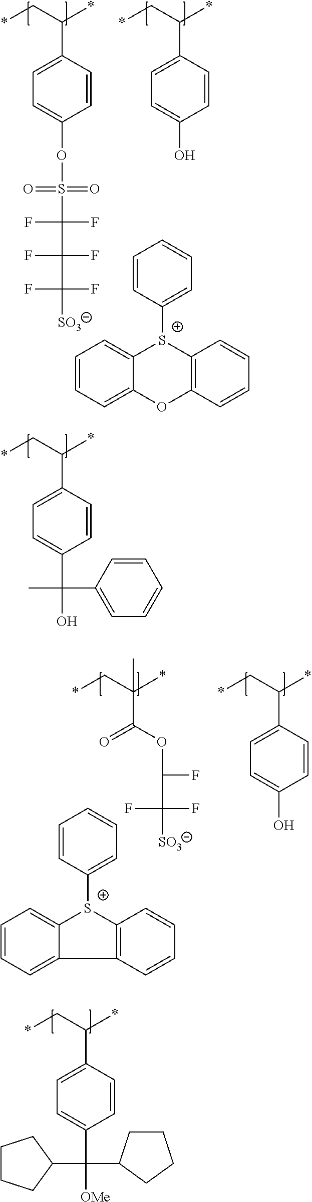

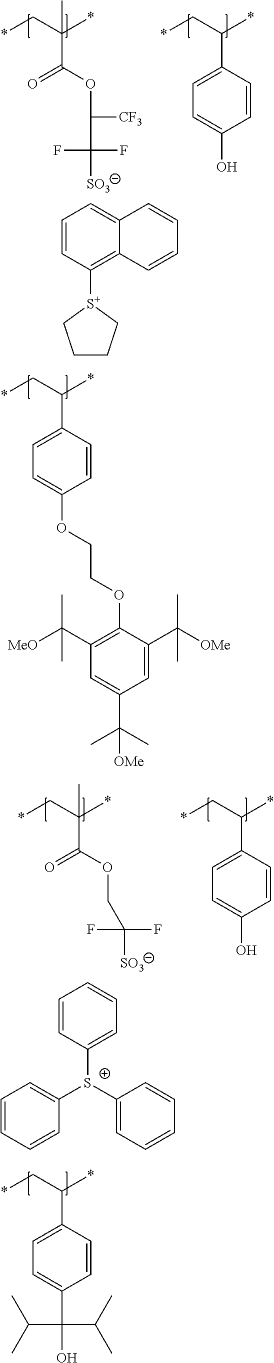

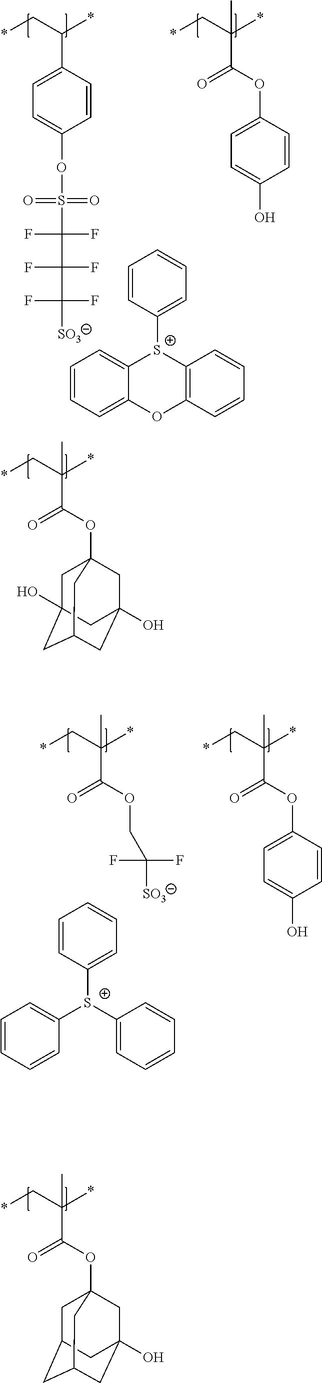

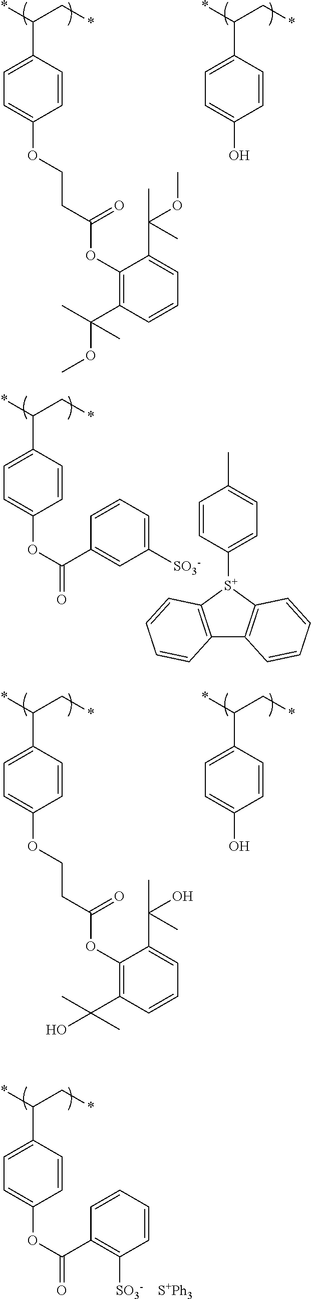

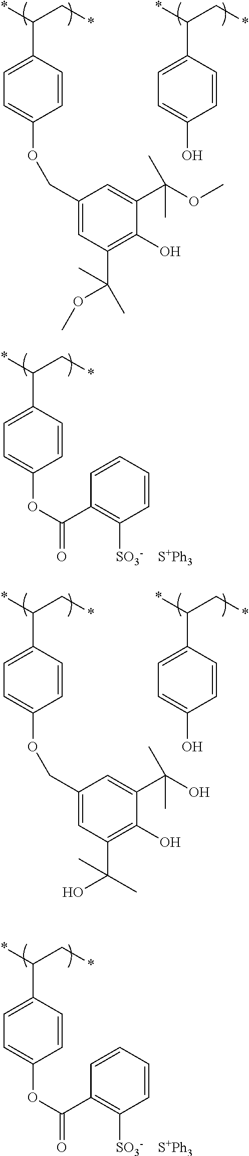

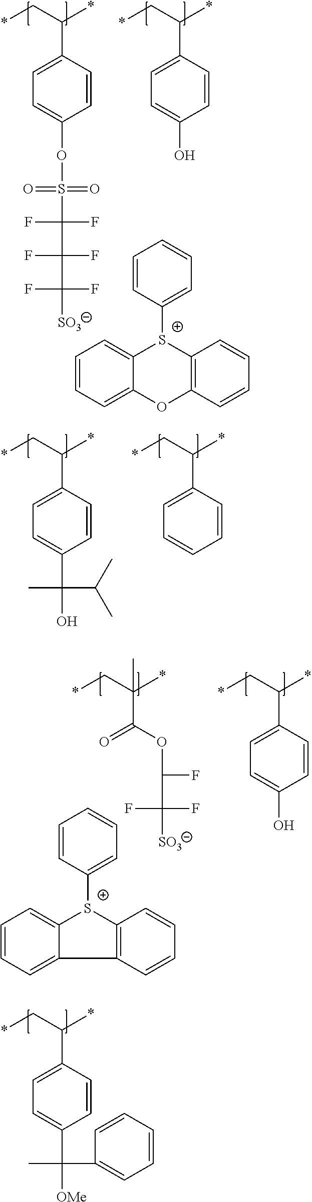

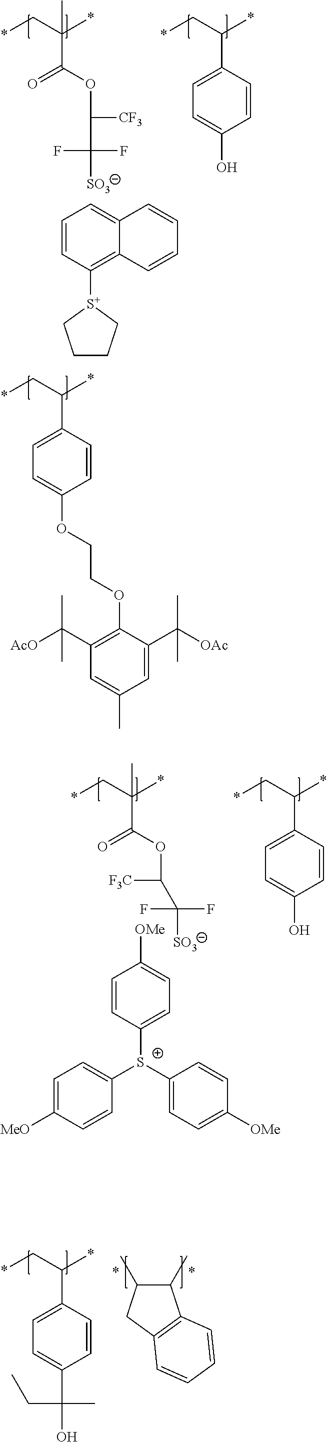

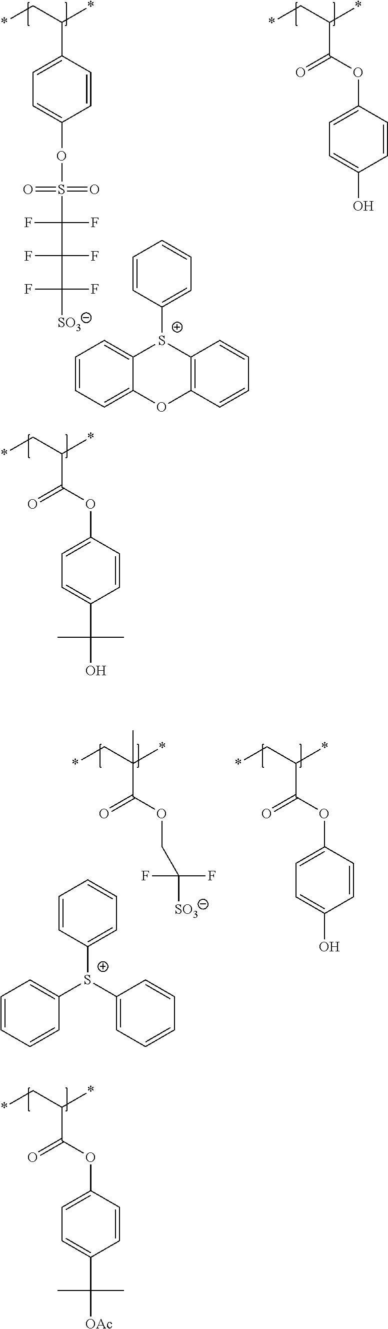

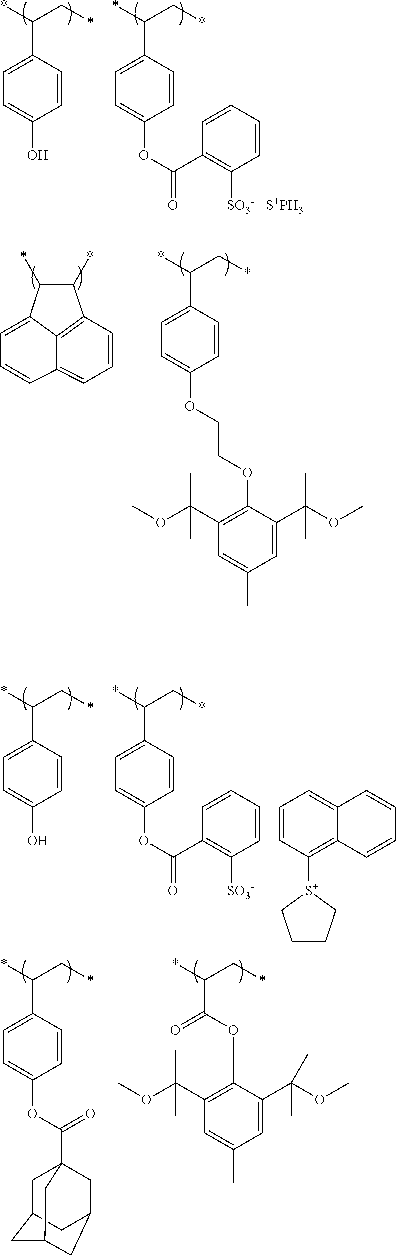

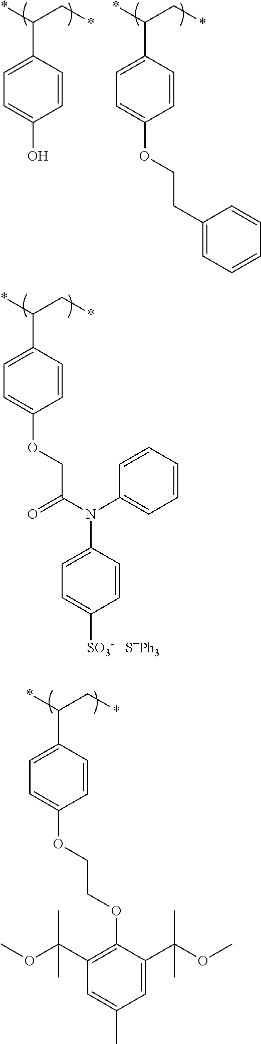

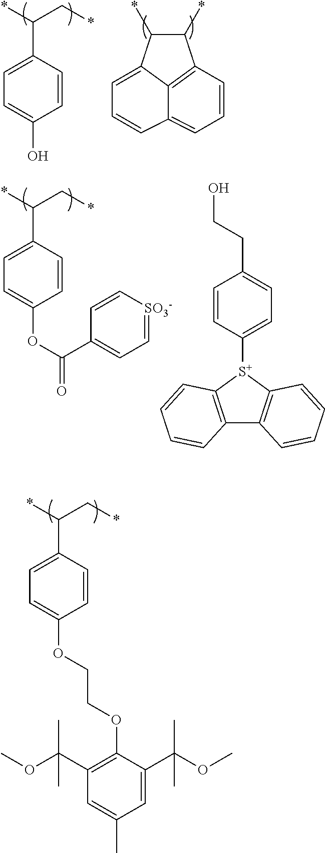

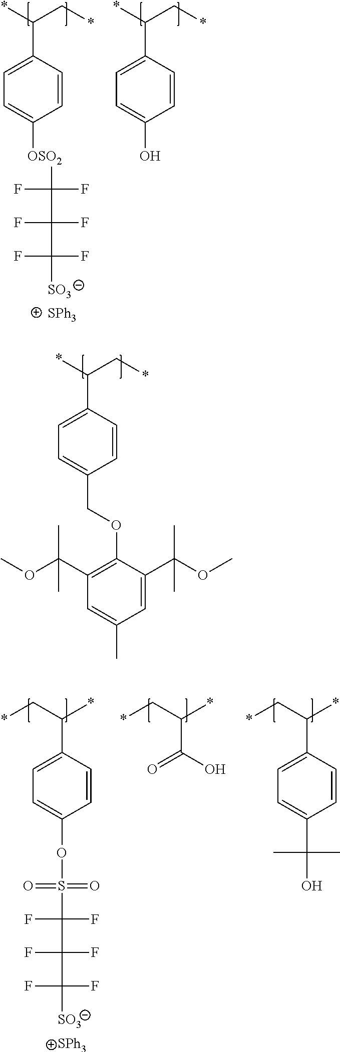

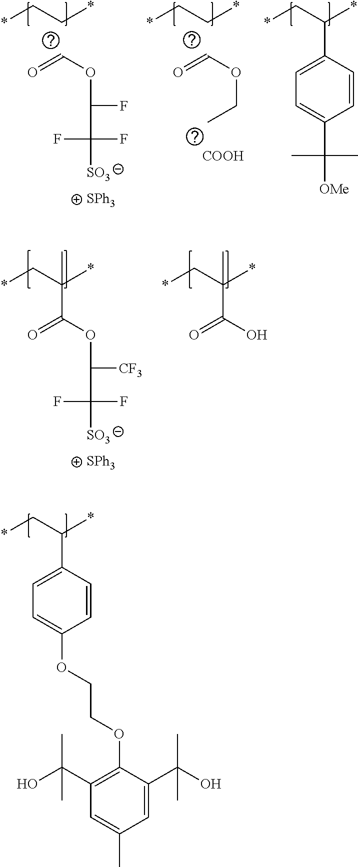

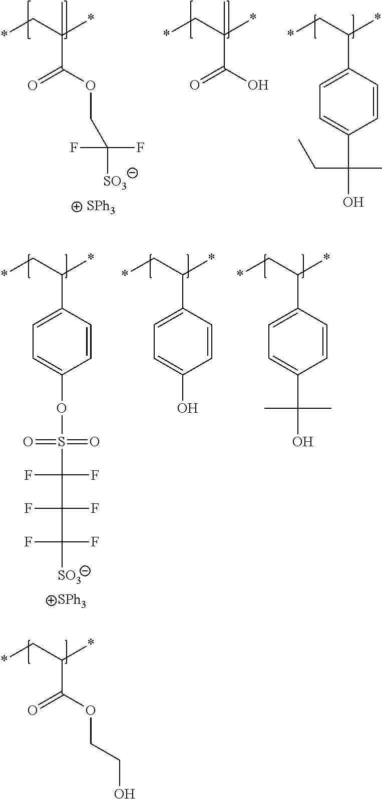

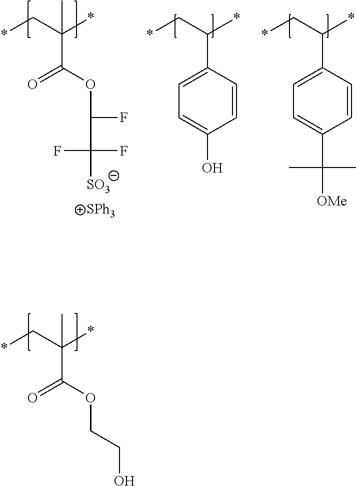

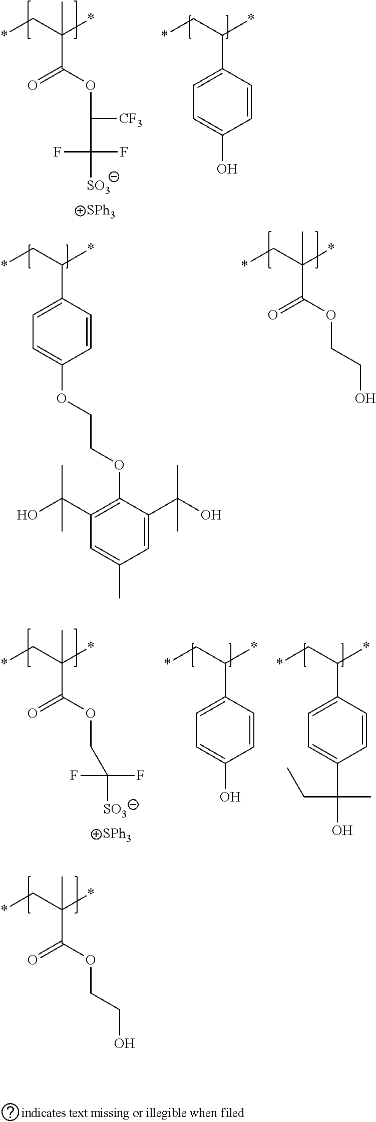

The polymer compound (A) can be synthesized through a known radical polymerization method or living radical polymerization method (an iniferter method or the like) using a monomer having a polycyclic structure group including an acid-crosslinkable group. In addition, the polymer compound (A) can also be synthesized by modifying a polymer synthesized by a radical polymerization method, a living radical polymerization method, or a living anionic polymerization method with a unit having a group including an acid-crosslinkable group through a polymer reaction.

The weight-average molecular weight of the polymer compound (A) is preferably 1,000 to 200,000, more preferably 2,000 to 50,000, and even more preferably 2.000 to 10,000.

The dispersion degree (molecular weight distribution) (Mw/Mn) of the polymer compound (A) is preferably 1.7 or less, more preferably 1.0 to 1.35, and even more preferably 1.0 to 1.20 from the viewpoint of an improvement in sensitivity and resolution. Living polymerization such as living anionic polymerization is preferably used since the polymer compound (A) to be obtained has a uniform dispersion degree (molecular weight distribution). The weight-average molecular weight and the dispersion degree of the polymer compound (A) are defined as values in terms of polystyrene measured by GPC measurement.

The content of the polymer compound (A) in the radiation-sensitive or actinic ray-sensitive resin composition of the invention is preferably 30 to 99.9 mass %, more preferably 40 to 99.9 mass %, and particularly preferably 50 to 99.9 mass % with respect to the total solid content of the radiation-sensitive or actinic ray-sensitive resin composition.

[Low-Molecular Compound (B) that Generates Acid by Irradiation with Actinic Rays or Radiation]

The radiation-sensitive or actinic ray-sensitive resin composition of the invention may further contain a low-molecular compound (B) (hereinafter, these compounds will be appropriately abbreviated as “acid generator (B)”) that generates an acid by irradiation with actinic rays or radiation.

Here, the low-molecular compound (B) means a compound other than a compound in which a part that generates an acid by irradiation with actinic rays or radiation is introduced into a main chain or a side chain of a resin, and is typically a compound in which the part is introduced into a monomolecular compound. The molecular weight of the low-molecular compound (B) is generally 4,000 or less, preferably 2,000 or less, and more preferably 1,000 or less. In addition, the molecular weight of the low-molecular compound (B) is generally 100 or greater, and preferably 200 or greater.

As a preferred embodiment of the acid generator (B), an onium compound can be exemplified. Examples of such an acid generator (B) include a sulfonium salt, an iodonium salt, and a phosphonium salt.

As another preferred embodiment of the acid generator (B), a compound that generates a sulfonic acid, an imido acid, or a methide acid by irradiation with actinic rays or radiation can be exemplified. Examples of the acid generator (B) of the embodiment include a sulfonium salt, an iodonium salt, a phosphonium salt, oxime sulfonate, and imido sulfonate.

The acid generator (B) is preferably a compound that generates an acid by irradiation with electron beams or extreme ultraviolet rays, and more preferably a compound that generates an acid by electron beams.

The radiation-sensitive or actinic ray-sensitive resin composition of the invention may not contain the acid generator (B). However, in a case where the radiation-sensitive or actinic ray-sensitive resin composition contains the acid generator (B), the content of the acid generator (B) is preferably 0.1 to 30 mass %, more preferably 0.5 to 20 mass %, and even more preferably 1.0 to 10 mass % based on the total solid content of the radiation-sensitive or actinic ray-sensitive resin composition.

The acid generators (B) can be used alone or in combination of two or more kinds thereof.

Specific examples of the acid generator (B) of the invention are as follows.

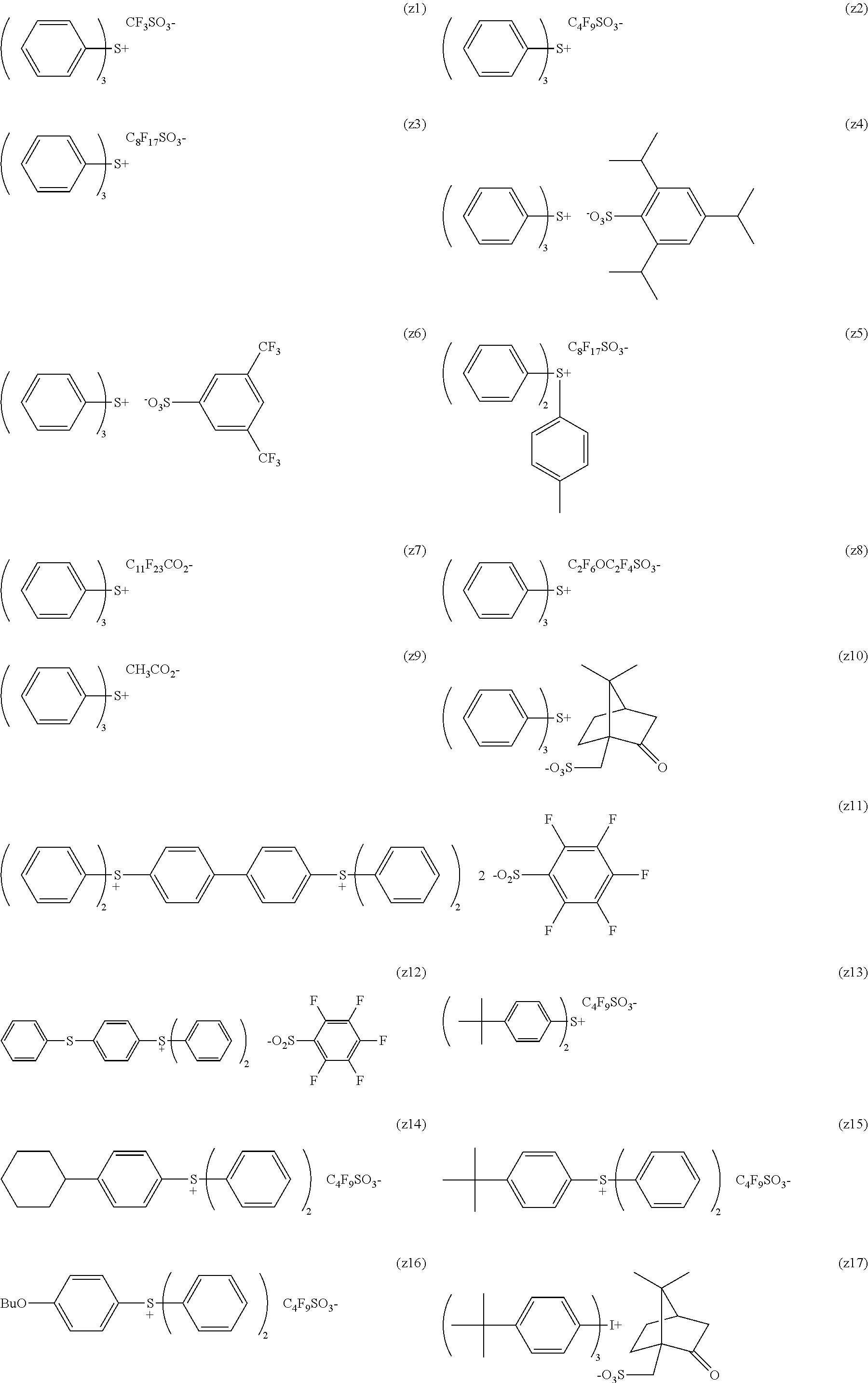

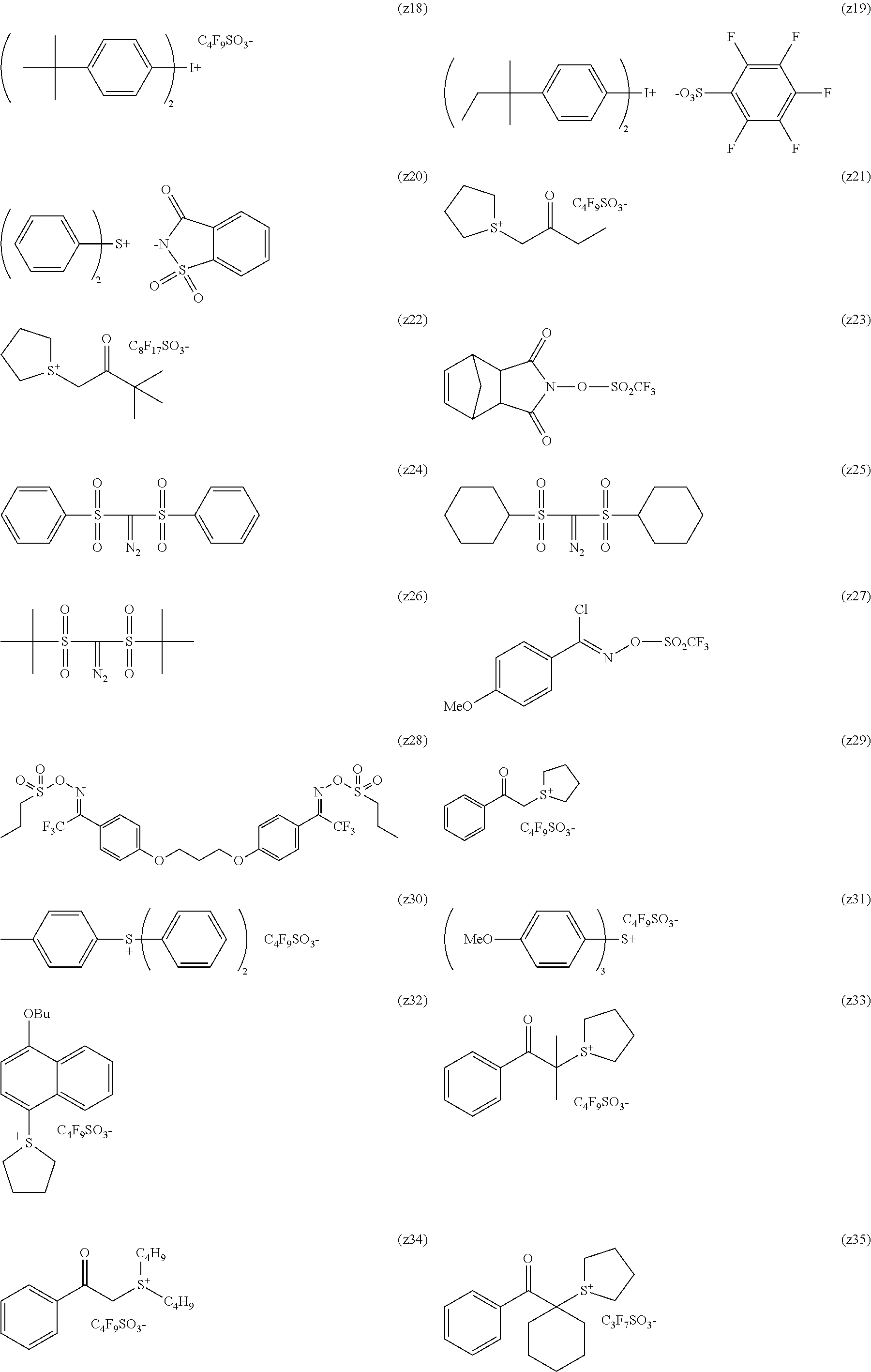

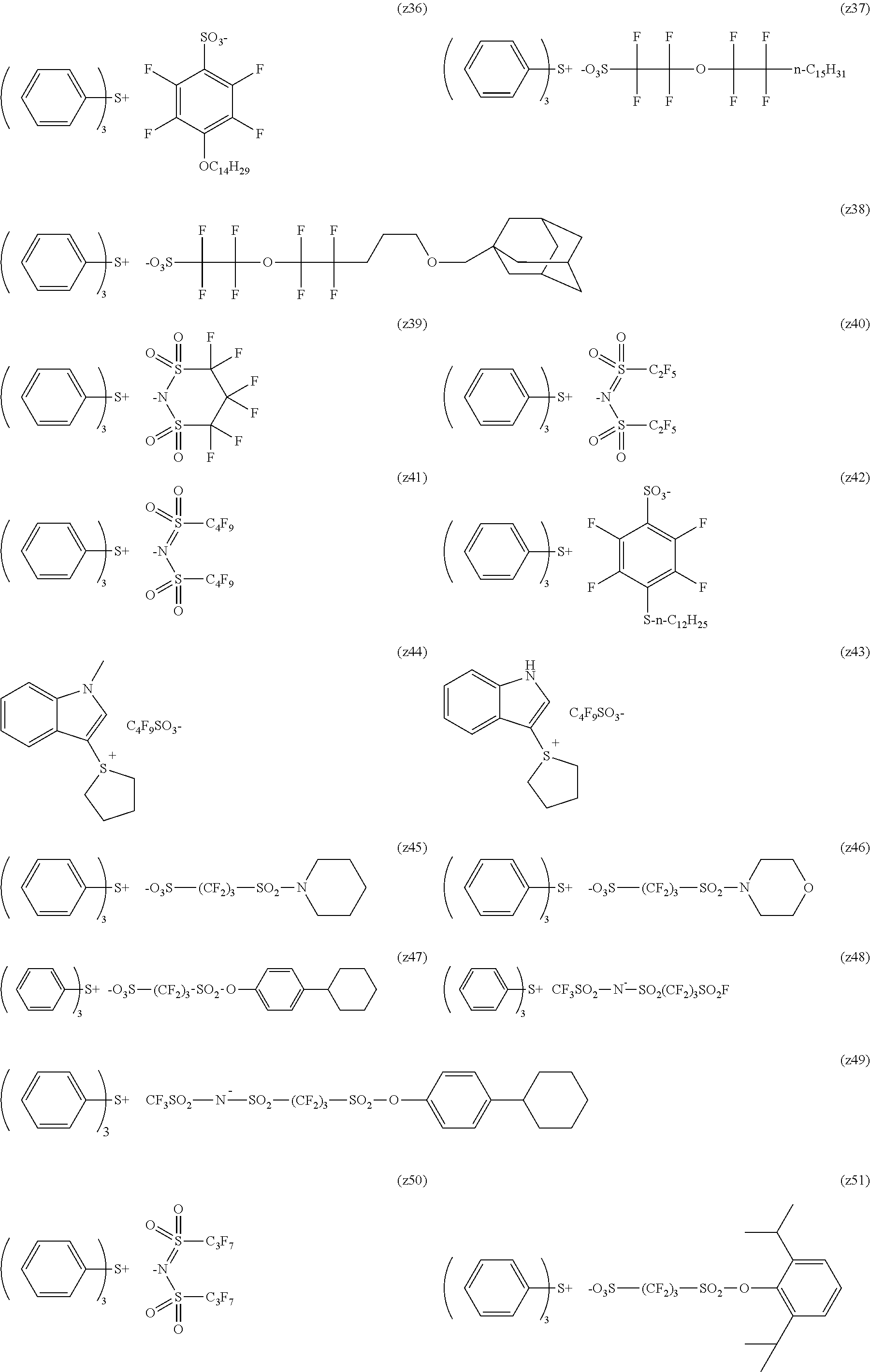

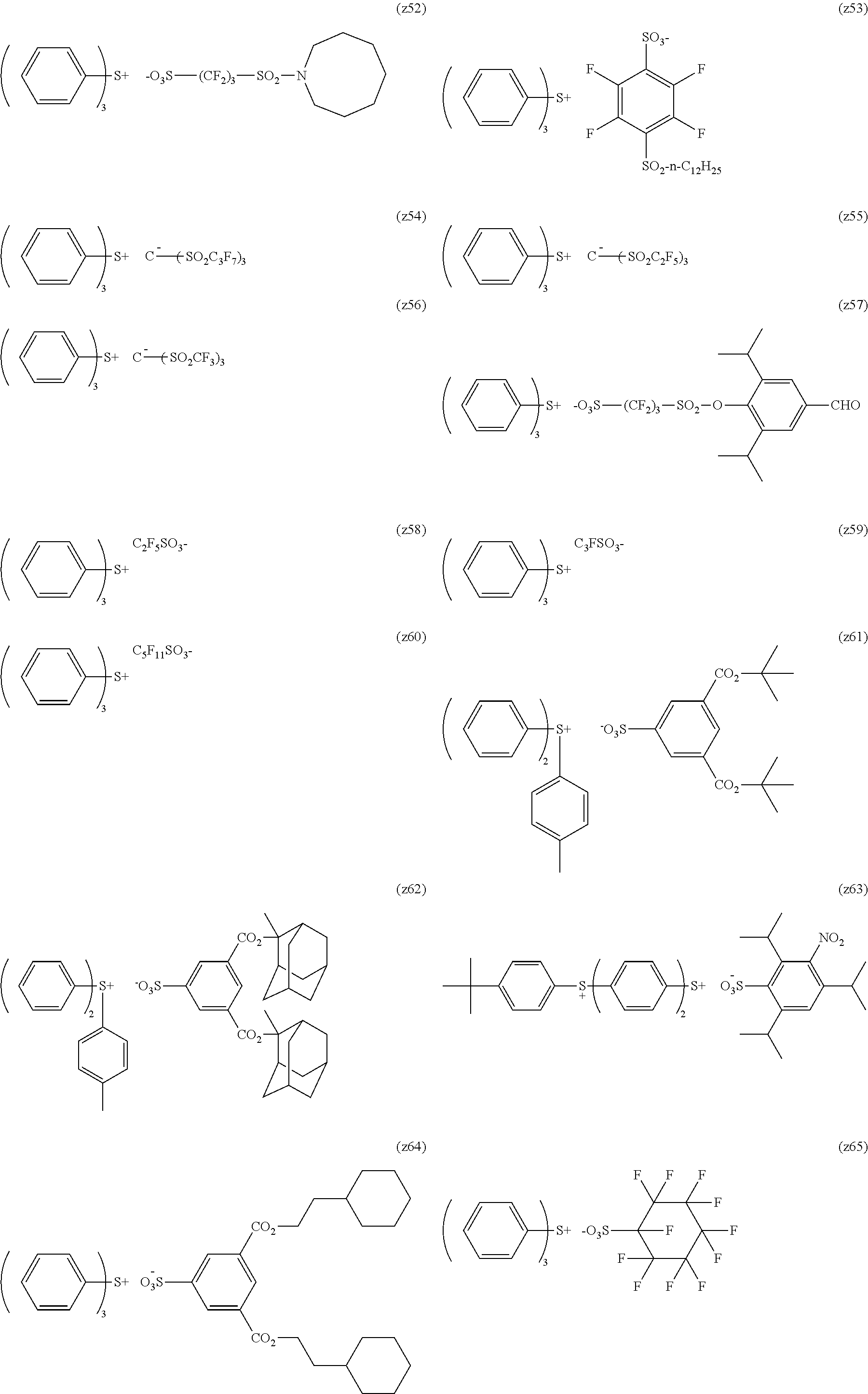

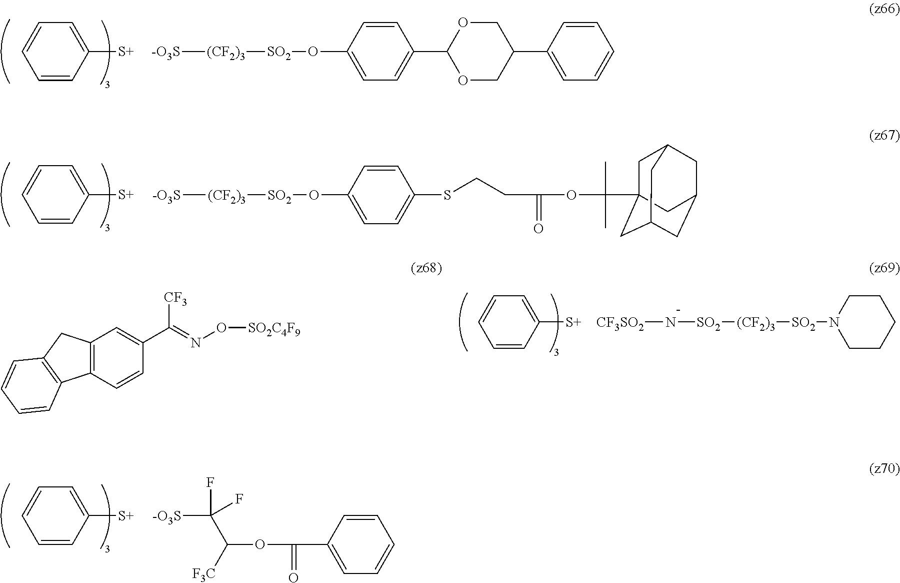

[Compound Having Phenolic Hydroxyl Group]

The radiation-sensitive or actinic ray-sensitive resin composition of the invention may contain one or more kinds of compounds having a phenolic hydroxyl group, that are different from the polymer compound (A) of the invention. The above compound may be a relatively low-molecular compound such as a molecular resist, or a polymer compound. As the molecular resist, for example, the low-molecular-weight cyclic polyphenolic compounds described in JP2009-173623A and JP2009-173625A can be used.

In a case where the compound having a phenolic hydroxyl group, that is different from the polymer compound (A), is a polymer compound, the weight-average molecular weight is preferably 1,000 to 200,000, more preferably 2,000 to 50,000, and even more preferably 2,000) to 15,000. The dispersion degree (molecular weight distribution) (Mw/Mn) is preferably 2.0 or less, more preferably 1.0 to 1.60, and most preferably 1.0 to 1.20.

The radiation-sensitive or actinic ray-sensitive resin composition of the invention may not contain the compound having a phenolic hydroxyl group, that is different from the polymer compound (A). However, in a case where the radiation-sensitive or actinic ray-sensitive resin composition contains the compound, the content of the compound is preferably 1 to 50 mass %, more preferably 2 to 40 mass %, and even more preferably 3 to 30 mass % based on the total solid content of the radiation-sensitive or actinic ray-sensitive resin composition.

Specific examples of the compound having a phenolic hydroxyl group, that is different from the polymer compound (A) of the invention, will be shown below, but the invention is not limited thereto.

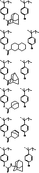

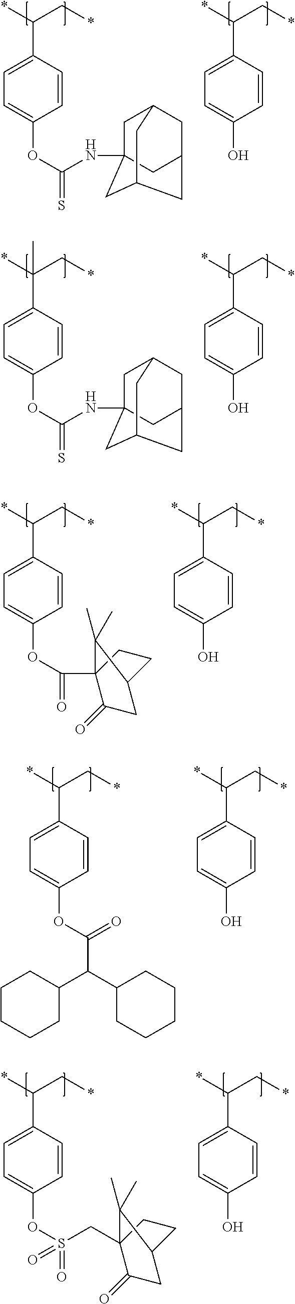

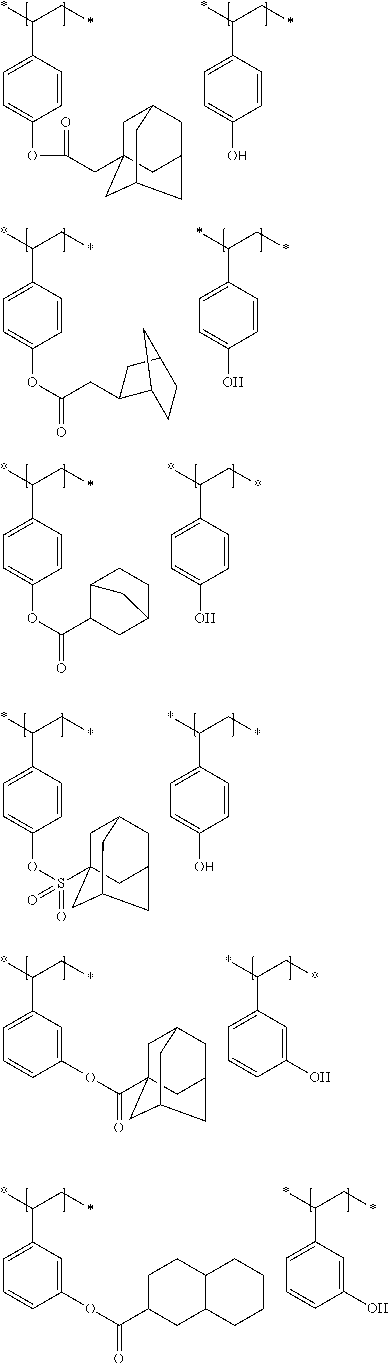

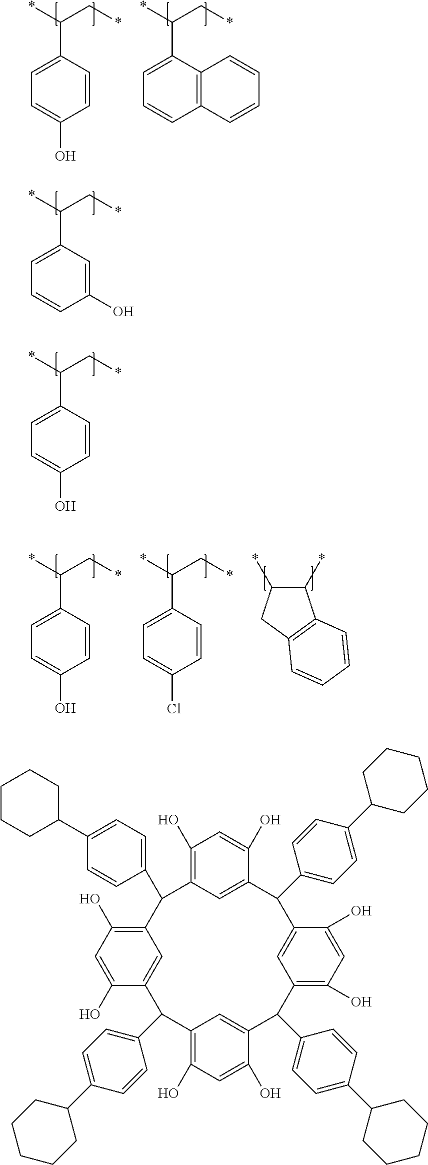

[Crosslinking Agent]

The radiation-sensitive or actinic ray-sensitive resin composition of the invention may further contain a crosslinking agent. Here, the crosslinking agent is different from the polymer compound (A) of the invention. The crosslinking agent is preferably a compound having at least one group selected from the group consisting of a hydroxymethyl group and an alkoxymethyl group in a molecule, and more preferably a compound having two or more groups in a molecule. Specific examples of the crosslinking agent that can be used in the invention will be given below, but are not limited thereto.

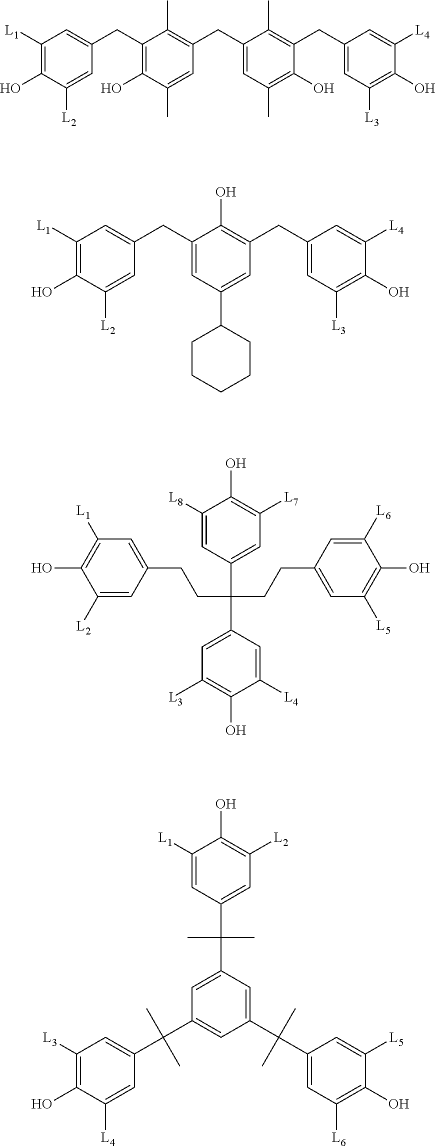

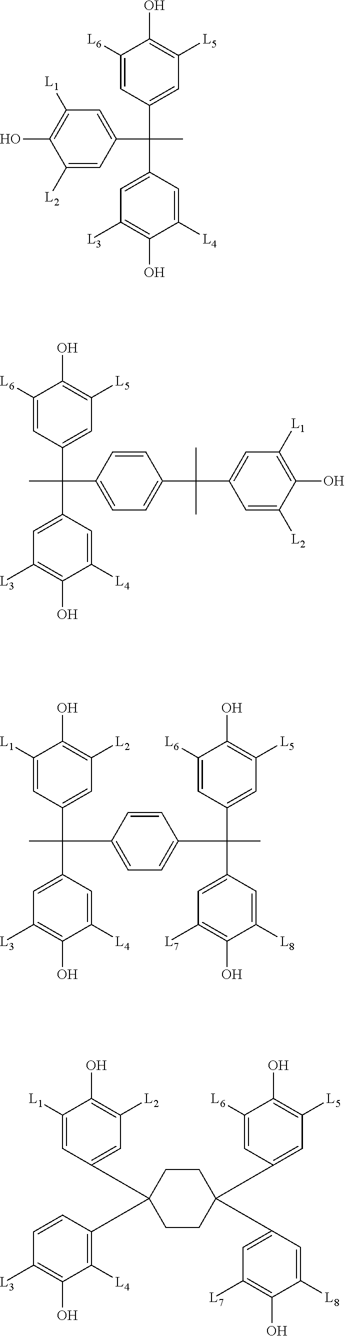

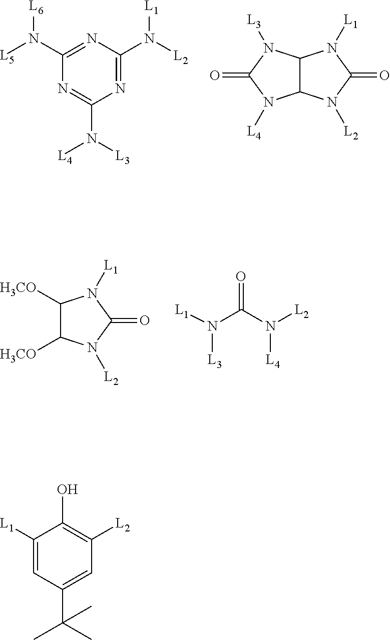

In the formula, L₁ to L₈ each independently represent a hydrogen atom, a hydroxymethyl group, a methoxymethyl group, an ethoxymethyl group, or an alkyl group having 1 to 6 carbon atoms.

In the invention, the crosslinking agents may be used alone or in combination of two or more kinds thereof. From the viewpoint of pattern shape, two or more kinds of crosslinking agents are preferably used in combination.

The radiation-sensitive or actinic ray-sensitive resin composition of the invention may not contain the crosslinking agent. However, in a case where the radiation-sensitive or actinic ray-sensitive resin composition contains the crosslinking agent, the content of the crosslinking agent is preferably 1 to 60 mass %, more preferably 2 to 50 mass %, and even more preferably 3 to 40 mass % based on the total solid content of the radiation-sensitive or actinic ray-sensitive resin composition.

[Compound that is Decomposed by Action of Acid to Generate Acid]

The radiation-sensitive or actinic ray-sensitive resin composition of the invention may further contain one or more kinds of compounds that are decomposed by the action of an acid to generate an acid. The acid generated from the compound that is decomposed by the action of an acid to generate an acid is preferably a sulfonic acid, a methide acid, or an imido acid.

Examples of the compound that is decomposed by the action of an acid to generate an acid and can be used in the invention will be shown below, but are not limited thereto.

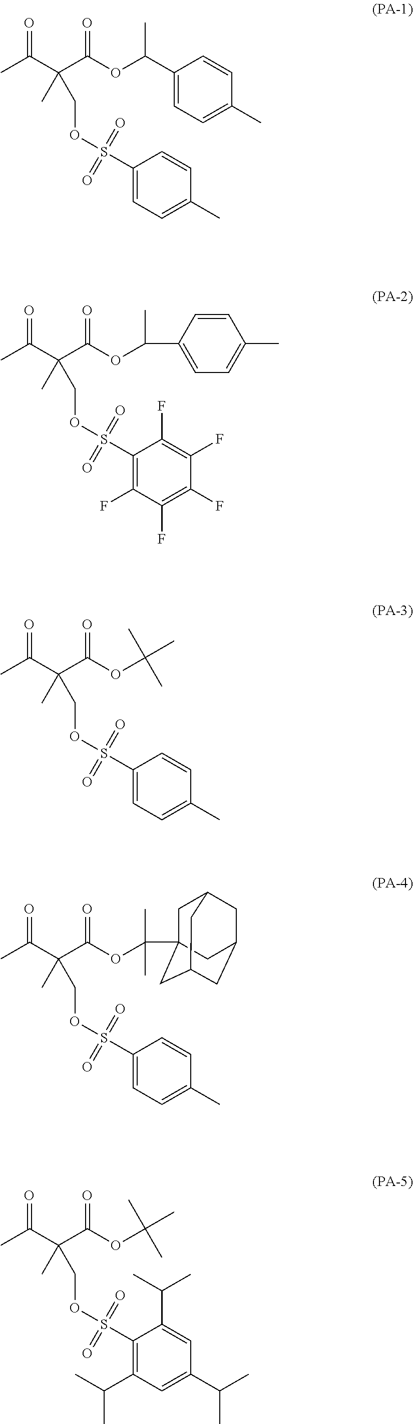

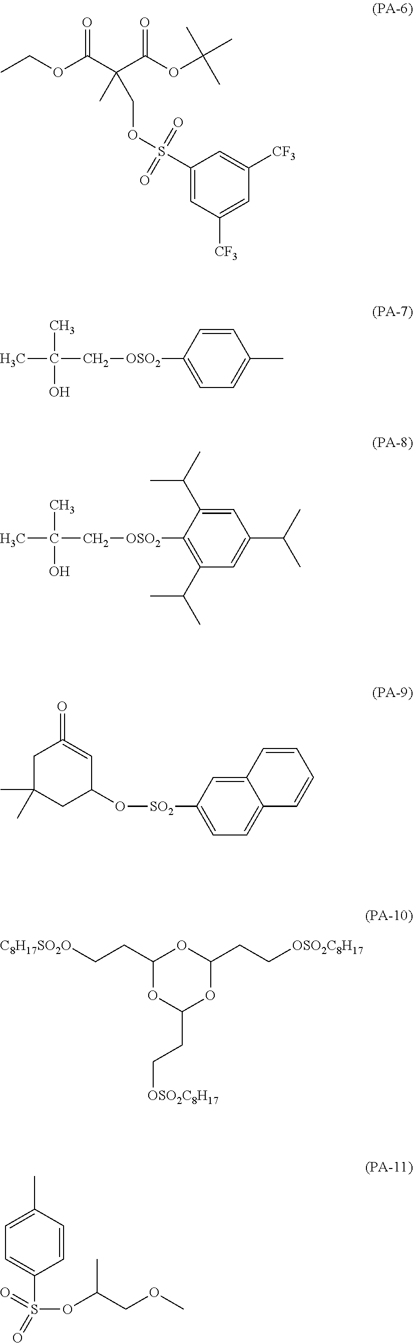

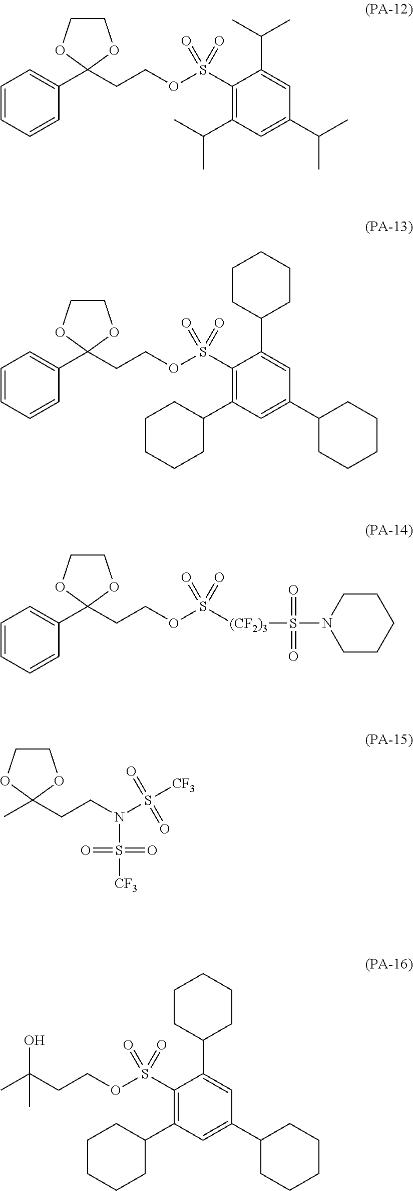

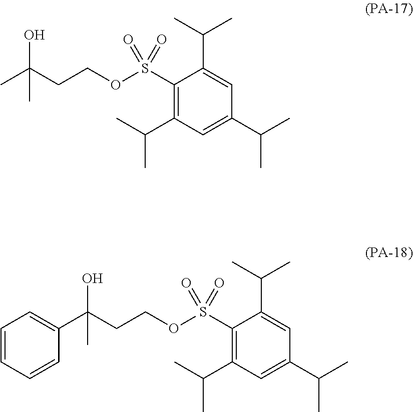 [SMILES: CC(C)c1cc(C(C)C)c(S(=O)(=O)OCCC(C)(C)O)c(C(C)C)c1 ; CC(C)c1cc(C(C)C)c(S(=O)(=O)OCCC(C)(O)c2ccccc2)c(C(C)C)c1]

The radiation-sensitive or actinic ray-sensitive resin composition of the invention may not contains the compound that is decomposed by the action of an acid to generate an acid. However, in a case where the radiation-sensitive or actinic ray-sensitive resin composition contains the compound, the content of the compound that is decomposed by the action of an acid to generate an acid is preferably 1 to 30 mass %, more preferably 2 to 20 mass %, and even more preferably 3 to 10 mass % based on the total solid content of the radiation-sensitive or actinic ray-sensitive resin composition.

[Basic Compound]

The radiation-sensitive or actinic ray-sensitive resin composition of the invention preferably contains a basic compound as an acid scavenger other than the above-described components. Using the basic compound, it is possible to reduce a change in performance with the lapse of time from exposure to heating. As such a basic compound, an organic basic compound is preferred, and specific examples thereof include aliphatic amines, aromatic amines, heterocyclic amines, nitrogen-containing compounds having a carboxyl group, nitrogen-containing compounds having a sulfonyl group, nitrogen-containing compounds having a hydroxy group, nitrogen-containing compounds having a hydroxyphenyl group, alcoholic nitrogen-containing compounds, amido derivatives, and imido derivatives. An amine oxide compound (described in JP2008-102383A) or an ammonium salt (preferably a hydroxide or a carboxylate, and more specifically, a tetraalkylammonium hydroxide typified by a tetrabutylammonium hydroxide is preferred from the viewpoint of LER) is also appropriately used.

A compound having basicity that increases by the action of an acid can also be used as a kind of basic compound.

Specific examples of the amines include tri-n-butylamine, tri-n-pentylamine, tri-n-octylamine, tri-n-decylamine, triisodecylamine, dicyclohexylmethylamine, tetradecylamine, pentadecylamine, hexadecylamine, octadecylamine, didecylamine, methyloctadecylamine, dimethylundecylamine, N,N-dimethyldodecylamine, methyldioctadecylamine, N,N-dibutylaniline, N,N-dihexylaniline, 2,6-diisopropylaniline, 2,4,6-tri(t-butyl)aniline, triethanolamine, N,N-dihydroxyethylaniline, tris(methoxyethoxyethyl)amine, compounds exemplified in U.S. Pat. No. 6,040,112A, column 3, line 60 et seq., 2-[2-{2-(2,2-dimethoxy-phenoxyethoxy)ethyl}-bis-(2-methoxyethyl)]-amine, and compounds (C1-1) to (C3-3) exemplified in US2007/0224539A1, paragraph <0066>. Examples of the compound having a nitrogen-containing heterocyclic structure include 2-phenylbenzimidazole, 2,4,5-triphenylimidazole, N-hydroxyethylpiperidine, bis(1,2,2,6,6-pentamethyl-4-piperidyl)sebacate, 4-dimethylaminopyridine, antipyrine, hydroxyantipyrine, 1,5-diazabicyclo[4.3.0]nona-5-ene, 1,8-diazabicyclo[5.4.0]undeca-7-ene, and tetrabutylammonium hydroxide.

Furthermore, a photodegradable basic compound (a compound in which a basic nitrogen atom initially acts as a base to exhibit basicity, but as the compound is decomposed by irradiation with actinic rays or radiation and generates a zwitterionic compound having a basic nitrogen atom and an organic acid part, these moieties are neutralized in the molecule, and basicity is decreased or lost. For example, the onium salts described in JP3577743B, JP2001-215689A, JP2001-166476A, and JP2008-102383A), or a photobase generator (for example, the compounds described in JP2010-243773A) is also appropriately used.

Among these basic compounds, an ammonium salt is preferred from the viewpoint of an improvement in resolution.

In addition, as the basic compound, an amine compound or an amine oxide compound having a carboxyl group and containing no hydrogen atoms covalently bonded to a nitrogen atom as a basic center may be contained. As such a basic compound, compounds represented by the following Formulae (12) to (14) are preferred.

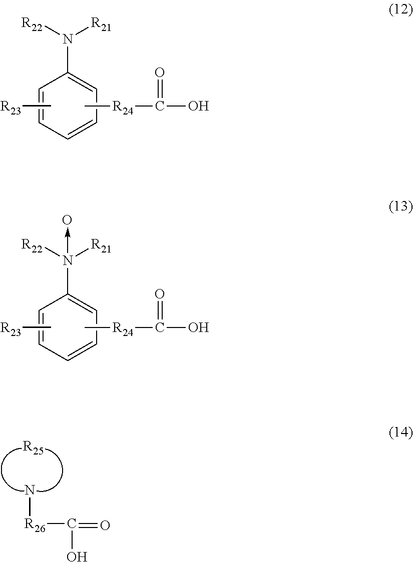

In Formula (12) and Formula (13), R₂₁ and R₂₂ each independently represent an alkyl group, a cycloalkyl group, or an aryl group.

R₂₁ and R₂₂ may be bonded to each other to form a ring structure together with a nitrogen atom to which R₂₁ and R₂₂ are bonded.

R₂₃ represents a hydrogen atom, an alkyl group, a cycloalkyl group, an aryl group, or a halogen atom.

R₂₄ represents a single bond, an alkylene group, a cycloalkylene group, or an arylene group.

In Formula (14), R₂₅ represents an alkylene group, and one or more of a carbonyl group (—CO—), an ether group (—O—), an ester group (—COO—), and a sulfide (—S) may be included between carbon atoms of the alkylene group.

R₂₆ represents an alkylene group, a cycloalkylene group, or an arylene group.

R₂₁ and R₂₂ may further have a substituent, and examples of the substituent include an alkyl group, an aryl group, a hydroxyl group, an alkoxy group, an acyloxy group, and an alkylthio group.

Each of R₂₁ and R₂₂ is preferably any one of a linear or branched alkyl group having 1 to 20 carbon atoms, a cycloalkyl group having 3 to 20 carbon atoms, an aryl group having 6 to 20 carbon atoms, an aralkyl group having 7 to 20 carbon atoms, a hydroxyalkyl group having 2 to 10 carbon atoms, an alkoxyalkyl group having 2 to 10 carbon atoms, an acyloxyalkyl group having 2 to 10 carbon atoms, and an alkylthioalkyl group having 1 to 10 carbon atoms.

R₂₃ may further have a substituent, and examples of the substituent include an alkyl group, an aryl group, a hydroxyl group, an alkoxy group, an acyloxy group, and an alkylthio group.

R₂₃ is preferably a hydrogen atom, a linear or branched alkyl group having 1 to 20 carbon atoms, a cycloalkyl group having 3 to 20 carbon atoms, an aryl group having 6 to 20 carbon atoms, an aralkyl group having 7 to 20 carbon atoms, a hydroxyalkyl group having 2 to 10 carbon atoms, an alkoxyalkyl group having 2 to 10 carbon atoms, an acyloxyalkyl group having 2 to 10 carbon atoms, an alkylthioalkyl group having 1 to 10 carbon atoms, or a halogen atom.

R₂₄ is preferably a single bond, a linear, branched, or cyclic alkylene group having 1 to 20 carbon atoms, or an arylene group having 6 to 20 carbon atoms.

R₂₅ is preferably a linear or branched alkylene group that may have a substituent with 2 to 20 carbon atoms.

R₂₆ is preferably a linear or branched alkylene group having 1 to 20 carbon atoms, a cycloalkylene group having 3 to 20 carbon atoms, or an arylene group having 6 to 20 carbon atoms.

Specific examples of the amine compound that is represented by Formula (12), having a carboxyl group and containing no hydrogen atoms covalently bonded to a nitrogen atom as a basic center, will be shown below, but are not limited thereto.

That is, specific examples of the amine compound include o-dimethylaminobenzoic acid, p-dimethylaminobenzoic acid, m-dimethylaminobenzoic acid, p-diethylaminobenzoic acid, p-dipropylaminobenzoic acid, p-dibutylaminobenzoic acid, p-dipentylaminobenzoic acid, p-dihexylaminobenzoic acid, p-diethanolaminobenzoic acid, p-diisopropanolaminobenzoic acid, p-dimethanolaminobenzoic acid, 2-methyl-4-diethylaminobenzoic acid, 2-methoxy-4-diethylaminobenzoic acid, 3-dimethylamino-2-naphthalenic acid, 3-diethylamino-2-naphthalenic acid, 2-dimethylamino-5-bromobenzoic acid, 2-dimethylamino-5-chlorobenzoic acid, 2-dimethylamino-5-iodobenzoic acid, 2-dimethylamino-5-hydroxybenzoic acid, 4-dimethylaminophenylacetic acid, 4-dimethylaminophenylpropionic acid, 4-dimethylaminophenylbutyric acid, 4-dimethylaminophenylmalic acid, 4-dimethylaminophenylpyruvic acid, 4-dimethylaminophenyllactic acid, 2-(4-dimethylaminophenyl)benzoic acid, and 2-(4-(dibutylamino)-2-hydroxybenzoyl)benzoic acid.

The amine compound that is represented by Formula (13), having a carboxyl group and containing no hydrogen atoms covalently bonded to a nitrogen atom as a basic center, is a compound obtained by oxidizing the amine compound specifically exemplified in the above description, but is not limited thereto.

Specific examples of the amine compound that is represented by Formula (14), having a carboxyl group and containing no hydrogen atoms covalently bonded to a nitrogen atom as a basic center, will be shown below, but are not limited thereto.

That is, specific examples of the amine compound include 1-piperidinepropionic acid, 1-piperidinebutyric acid, 1-piperidinemalic acid, 1-piperidinepyruvic acid, and 1-piperidinelactic acid.

The radiation-sensitive or actinic ray-sensitive resin composition of the invention may not contain the basic compound. However, in a case where the radiation-sensitive or actinic ray-sensitive resin composition contains the basic compound, the content of the basic compound is preferably 0.01 to 10 mass %, more preferably 0.03 to 5 mass %, and even more preferably 0.05 to 3 mass % with respect to the total solid content of the radiation-sensitive or actinic ray-sensitive resin composition.

[Surfactant]

The radiation-sensitive or actinic ray-sensitive resin composition of the invention may further contain a surfactant in order to improve coatability. Examples of the surfactant include, but are not limited to, nonionic surfactants such as polyoxyethylene alkyl ethers, polyoxyethylene alkylaryl ethers, polyoxyethylene polyoxypropylene block copolymers, sorbitan fatty acid esters, and polyoxyethylene sorbitan fatty acid ester, fluorine surfactants such as MEGAFACE F171 (manufactured by DIC Corporation), FLUORAD FC 430 (manufactured by Sumitomo 3M Limited), SURFYNOL E1004 (manufactured by ASAHI GLASS CO., LTD.), and PF656 and PF6320 (manufactured by OMNOVA Solutions Inc.), and organosiloxane polymers.

The radiation-sensitive or actinic ray-sensitive resin composition of the invention may not contain the surfactant. However, in a case where the radiation-sensitive or actinic ray-sensitive resin composition contains the surfactant, the content of the surfactant is preferably 0.0001 to 2 mass %, and more preferably 0.0005 to 1 mass % with respect to the total amount (excluding the solvent) of the composition.

[Organic Carboxylic Acid]

The radiation-sensitive or actinic ray-sensitive resin composition of the invention preferably contains an organic carboxylic acid other than the above-described components. Examples of such an organic carboxylic acid compound include an aliphatic carboxylic acid, an alicyclic carboxylic acid, an unsaturated aliphatic carboxylic acid, an oxycarboxylic acid, an alkoxycarboxylic acid, a ketocarboxylic acid, a benzoic acid derivative, a phthalic acid, a terephthalic acid, an isophthalic acid, a 2-naphthoic acid, a 1-hydroxy-2-naphthoic acid, and a 2-hydroxy-3-naphthoic acid. In a case where electron beam exposure is performed under vacuum, aromatic organic carboxylic acids are preferred since there is a concern that the organic carboxylic acid is volatilized from a surface of a resist film and contaminates the inside of a drawing chamber. Among these, for example, a benzoic acid, a 1-hydroxy-2-naphthoic acid, and a 2-hydroxy-3-naphthoic acid are preferred.

The radiation-sensitive or actinic ray-sensitive resin composition of the invention may not contain the organic carboxylic acid. However, in a case where the radiation-sensitive or actinic ray-sensitive resin composition contains the organic carboxylic acid, the content of the organic carboxylic acid is preferably in a range of 0.01 to 10 parts by mass, more preferably 0.01 to 5 parts by mass, and even more preferably 0.01 to 3 parts by mass with respect to 100 parts by mass of the polymer compound (A).

If necessary, the radiation-sensitive or actinic ray-sensitive resin composition of the invention may further contain a dye, a plasticizer, an acid proliferator and the like (described in WO95/29968A, WO98/24000A, JP1996-305262A (JP-H08-305262A), JP1997-34106A (JP-H09-34106A), JP1996-248561A (JP-H08-248561 A), JP1996-503082A (JP-H08-503082A). U.S. Pat. No. 5,445,917A, JP1996-503081A (JP-H08-503081A), U.S. Pat. No. 5,534,393A, U.S. Pat. No. 5,395,736A, U.S. Pat. No. 5,741,630A, U.S. Pat. No. 5,334,489A. U.S. Pat. No. 5,582,956A. U.S. Pat. No. 5,578,424A. U.S. Pat. No. 5,453,345A, EP665960B, EP757628B, EP665961B, U.S. Pat. No. 5,667,943A, JP1998-1508A (JP-H10-1508A). JP1998-282642A (JP-H10-282642A), JP1997-512498A (JP-H09-512498A), JP2000-62337A, JP2005-17730A, JP2008-209889A, and the like). With respect to these compounds, respective compounds described in JP2008-268935A can be exemplified.

[Carboxylic Acid Onium Salt]

The radiation-sensitive or actinic ray-sensitive resin composition of the invention may contain a carboxylic acid onium salt. Examples of the carboxylic acid onium salt include a carboxylic acid sulfonium salt, a carboxylic acid iodonium salt, and a carboxylic acid ammonium salt. Particularly, as the carboxylic acid onium salt, a carboxylic acid sulfonium salt and a carboxylic acid iodonium salt are preferred. Furthermore, in the invention, a carboxylate residue of the carboxylic acid onium salt preferably does not contain an aromatic group and a carbon-carbon double bond. As a particularly preferred anion part, a linear, branched, monocyclic or polycyclic cyclic alkylcarboxylate anion having 1 to 30 carbon atoms is preferred. An anion of a carboxylic acid in which some or all of alkyl groups are substituted with fluorine is more preferred. An oxygen atom may be included in an alkyl chain. Accordingly, transparency with respect to light of 220 nm or less is secured, and thus sensitivity and resolving power are improved, such that density dependence and exposure margins are improved.

The radiation-sensitive or actinic ray-sensitive resin composition of the invention may not contain the carboxylic acid onium salt. However, in a case where the radiation-sensitive or actinic ray-sensitive resin composition contains the carboxylic acid onium salt, the content of the carboxylic acid onium salt is preferably 0.5 to 20 mass %, more preferably 0.7 to 15 mass %, and even more preferably 1.0 to 10 mass % based on the total solid content of the radiation-sensitive or actinic ray-sensitive resin composition.

[Solvent]

The radiation-sensitive or actinic ray-sensitive resin composition usually contains a solvent.

Examples of the solvent that can be used in the preparation of the radiation-sensitive or actinic ray-sensitive resin composition include organic solvents such as an alkylene glycol monoalkyl ether carboxylate, an alkylene glycol monoalkyl ether, an alkyl lactate ester, an alkyl alkoxypropionate, a cyclic lactone (preferably having 4 to 10 carbon atoms), a monoketone compound (preferably having 4 to 10 carbon atoms) that may have a ring, an alkylene carbonate, an alkyl alkoxyacetate, and an alkyl pyruvate.

Specific examples of these solvents include the examples described in paragraphs <0441> to <0455> of US2008/0187860A.

In the invention, a mixed solvent obtained by mixing a solvent containing a hydroxyl group in the structure and a solvent containing no hydroxyl group may be used as an organic solvent.

As the solvent containing a hydroxyl group and the solvent containing no hydroxyl group, the compounds exemplified in the above description can be appropriately selected. As the solvent containing a hydroxyl group, an alkylene glycol monoalkyl ether, an alkyl lactate, and the like are preferred, and a propylene glycol monomethyl ether (PGME, also referred to as 1-methoxy-2-propanol) and an ethyl lactate are more preferred. In addition, as the solvent containing no hydroxyl group, an alkylene glycol monoalkyl ether acetate, an alkyl alkoxy propionate, a monoketone compound that may have a ring, a cyclic lactone, an alkyl acetate, and the like are preferred. Among these, a propylene glycol monomethyl ether acetate (PGMEA, also referred to as 1-methoxy-2-acetoxypropane), an ethyl ethoxy propionate, a 2-heptanone, a γ-butyrolactone, a cyclohexanone, and a butyl acetate are particularly preferred, and a propylene glycol monomethyl ether acetate, an ethyl ethoxy propionate, and a 2-heptanone are most preferred.

The mixing ratio (mass) between the solvent containing a hydroxyl group and the solvent containing no hydroxyl group is 1/99 to 99/1, preferably 10/90 to 90/10, and more preferably 20/80 to 60/40. A mixed solvent containing the solvent containing no hydroxyl group in a proportion of 50 mass % or greater is particularly preferred from the viewpoint of uniform coating.

The solvent preferably contains a propylene glycol monomethyl ether acetate, and is preferably a single solvent of a propylene glycol monomethyl ether acetate or a mixed solvent of two or more kinds containing a propylene glycol monomethyl ether acetate.

The solid content concentration of the radiation-sensitive or actinic ray-sensitive resin composition of the invention is preferably 1 to 40 mass %, more preferably 1 to 30 mass %, and even more preferably 3 to 20 mass %.

The invention relates to a resist film formed of the radiation-sensitive or actinic ray-sensitive resin composition of the invention, and such a film is formed by, for example, coating a support such as a substrate with the composition of the invention. The thickness of this film is preferably 0.02 to 0.1 μm. As a method for coating on the substrate, an appropriate coating method such as spin coating, roll coating, flow coating, dip coating, spray coating, and doctor coating is used to coat the substrate, and spin coating is preferred. In addition, the rotation speed thereof is preferably 1,000 to 3,000 rpm. As the coating film, a thin film is formed by performing prebaking at 60° C. to 150° C. for 1 to 20 minutes, and preferably at 80° C. to 120° C. for 1 to 10 minutes.

As a material constituting a substrate to be processed and the outermost layer thereof, for example, a silicon wafer can be used, in the case of a semiconductor wafer, and examples of the material that becomes the outermost layer include Si, SiO₂, SiN, SiON, TiN, WSi, BPSG, SOG, and an organic antireflection film.

The invention also relates to a mask blank on which the resist film obtained as described above is coated. In order to obtain such a mask blank having the resist film, as a transparent substrate to be used in a case where a pattern is formed on a photo mask blank for producing a photo mask, a transparent substrate such as quartz or calcium fluoride can be exemplified. Generally, a necessary functional film such as a light shielding film an antireflection film, and further a phase shift film, and additionally, an etching stopper film and an etching mask film are laminated on the substrate. As a material of the functional film, a film containing a transition metal such as silicon, chromium, molybdenum, zirconium, tantalum, tungsten, titanium, and niobium is laminated. In addition, as a material used in the outermost layer, a silicon compound material that contains, as a main constituent material, a material containing silicon or a material containing oxygen and/or nitrogen in silicon, or contains, as a main constituent material, a material containing a transition metal in the above material, and a transition metal compound material that contains, as a main constituent material, a material containing one or more selected from transition metals, particularly, chromium, molybdenum, zirconium, tantalum, tungsten, titanium, and niobium, or a material containing one or more selected from oxygen, nitrogen, and carbon in the above material are exemplified.

The light shielding film may be a single layer, but a multilayer structure in which a plurality of materials is coated in an overlapped manner is more preferred. In a case of the multilayer structure, a thickness of the film per one layer is not particularly limited, but is preferably 5 to 100 nm, and more preferably 10 to 80 nm. The total thickness of the light shielding film is not particularly limited, but is preferably 5 to 200 nm, and more preferably 10 to 150 nm.

Generally, in a case where a pattern is formed of the composition of the invention on a photo mask blank that contains, in the outermost layer thereof, a material containing oxygen or nitrogen in chromium among the above materials, a so-called undercut shape in which a constricted shape is formed near the substrate is easily formed. However, in a case where the invention is used, the undercut problem can be solved compared to a case of a composition in the related art.

The resist film is irradiated with actinic rays or radiation (electron beams or the like). Baking (usually at 80° C. to 150° C., and preferably at 90° C. to 130° C.) is preferably performed, and then development is performed. Accordingly, a good pattern can be obtained. In addition, using this pattern as a mask, etching and ion injection are appropriately performed to form a semiconductor fine circuit, an imprint mold structure, and the like.

Processes for a case of producing an imprint mold using the radiation-sensitive or actinic ray-sensitive resin composition of the invention are described in, for example, JP4109085B, JP2008-162101A, and “Science and New Technology in Nanoimprint—Substrate technology of nanoimprint and latest technology development—edited by HIRAI YOSIHIKO (Frontier Publishing)”.

A usage form of the chemically amplified resist composition of the invention and a pattern forming method will be described below.

The invention also relates to a pattern forming method including exposing the resist film or a mask blank having the film formed thereon and developing the exposed resist film or the exposed mask blank having the film. In the invention, the exposure is preferably performed using electron beams or extreme ultraviolet rays.

For the exposure (pattern forming step) of the resist film in the manufacturing of a precisely integrated circuit element and the like, first, the resist film of the invention is preferably irradiated with electron beams or extreme ultraviolet rays (EUV) in a pattern shape. The exposure is performed such that in a case of electron beams, the exposure amount is about 0.1 to 20 μC/cm², and preferably about 3 to 10 μC/cm², and in a case of extreme ultraviolet rays, the exposure amount is about 0.1 to 20 mJ/cm², and preferably about 3 to 15 mJ/cm². Next, post exposure baking is performed on a hot plate at 60° C. to 150° C. for 1 to 20 minutes, and preferably at 80° C. to 120° C. for 1 to 10 minutes, and subsequently, a pattern is formed by performing developing, rinsing, and drying. The developer is appropriately selected, and an alkaline developer (typified by an alkaline aqueous solution) or a developer containing an organic solvent (also referred to as an organic developer) is preferably used. In a case where the developer is an alkaline aqueous solution, using an alkaline aqueous solution of 0.1 to 5 mass %6, and preferably 2 to 3 mass %, such as tetramethylammonium hydroxide (TMAH) or tetrabutylammonium hydroxide (TBAH), development is performed through a usual method such as a dipping method, a puddling method, or a spraying method for 0.1 to 3 minutes, and preferably for 0.5 to 2 minutes. Alcohols and/or a surfactant may be added in an appropriate amount to the alkaline developer. In this manner, the film of the unexposed part is dissolved, the exposed part is difficult to dissolve in the developer due to the crosslinking of the polymer compound (A), whereby a target pattern is formed on the substrate.

As the alkaline developer, alkaline aqueous solutions of inorganic alkalis such as sodium hydroxide, potassium hydroxide, sodium carbonate, sodium silicate, sodium metasilicate, and ammonia water, primary amines such as ethylamine and n-propylamine, secondary amines such as diethylamine and di-n-butylamine, tertiary amines such as triethylamine and methyldiethylamine, alcohol amines such as dimethylethanolamine and triethanolamine, tetraalkylammonium hydroxides such as tetramethylammonium hydroxide, tetraethylammonium hydroxide, tetrapropylammonium hydroxide, tetrabutylammonium hydroxide, tetrapentylammonium hydroxide, tetrahexylammonium hydroxide, tetraoctylammonium hydroxide, ethyltrimethylammonium hydroxide, butyltrimethylammonium hydroxide, methyltriamylammonium hydroxide, and dibutyldipentylammonium hydroxide, quaternary ammonium salts such as trimethylphenylammonium hydroxide, trimethylbenzylammonium hydroxide, and triethylbenzylammonium hydroxide, and cyclic amines such as pyrrole and piperidine. Furthermore, the alkaline aqueous solution can also be used with the addition of alcohols and a surfactant in an appropriate amount. The alkali concentration of the alkaline aqueous solution is usually 0.1 to 20 mass %. The pH of the alkaline developer is usually 10.0 to 15.0. The alkaline developer can be used by appropriately adjusting the alkali concentration and the pH thereof. The alkaline developer may also be used with the addition of a surfactant and an organic solvent.

As the organic developer, a polar solvent such as an ester solvent (butyl acetate, ethyl acetate, or the like), a ketone solvent (2-heptanone, cyclohexanone, or the like), an alcohol solvent, an amido solvent, and an ether solvent, and a hydrocarbon solvent can be used. The moisture content with respect to the total organic developer is preferably less than 10 mass %, and it is more preferable for the developer not to substantially contain moisture. In addition, the organic developer may contain a basic compound, and specific examples thereof include the compounds exemplified as the basic compound that can be contained in the resist composition of the invention. A process in which alkali development and development with an organic developer are combined may also be performed.

The invention also relates to a photo mask obtained by exposing and developing a resist-coated mask blank. As the exposure and the development, the steps described above are applied. The photo mask is preferably used for manufacturing a semiconductor.

The photo mask of the invention may be a light transmission-type mask that is used in ArF excimer laser and the like, or a light reflective-type mask that is used in a reflection system lithography using EUV light as a light source.

The invention also relates to an electronic device manufacturing method including the above-described resist pattern forming method of the invention and an electronic device manufactured by the manufacturing method.

The electronic device of the invention is preferably mounted on an electric and electronic apparatus (home electric appliances. OA media related-apparatuses, optical apparatuses, communication apparatuses, and the like).

### EXAMPLES

Hereinafter, the invention will be described in further detail with reference to examples, but the invention is not limited thereto.

### Synthesis Example

### Synthesis of Polymer Compound (A1)

12.9 parts by mass of a propylene glycol monomethyl ether was heated at 85° C. in a nitrogen stream. While this liquid was stirred, a mixed solution of 12.6 parts by mass of p-hydroxystyrene, 4.87 parts by mass of a monomer (X3) with the following structure, 10.15 parts by mass of a monomer (X4) with the following structure, 51.6 parts by mass of a propylene glycol monomethyl ether, and 2.42 parts by mass of 2,2′-azobisisodimethyl butyrate (V-601, manufactured by Wako Pure Chemical Industries, Ltd.) was added dropwise thereto over 2 hours. After the dropwise addition was completed, the mixture was further stirred for 4 hours at 85° C. The reaction liquid was allowed to cool, and then reprecipitation was performed with a large amount of heptane/ethyl acetate (=90/10 (volume ratio)). The obtained solid was dissolved again in acetone to perform reprecipitation and vacuum drying with a large amount of water/methanol (=90/10 (volume ratio)), whereby 35.5 parts by mass of a polymer compound (A1) of the invention was obtained.

The weight-average molecular weight (Mw: in terms of polystyrene) of the obtained polymer compound (A1) obtained by GPC (carrier: N-methyl-2-pyrrolidone (NMP)) was 6.500, and the dispersion degree (Mw/Mn) was 1.45.

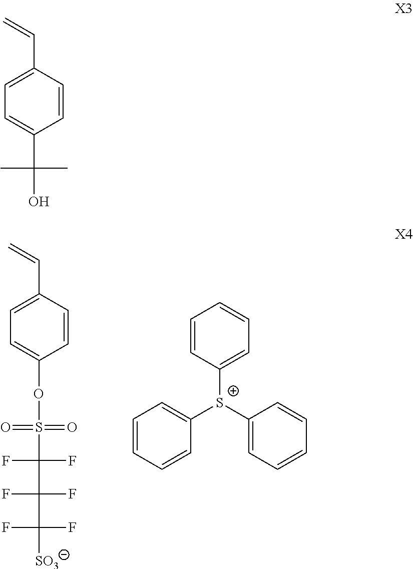

Polymer compounds (A2) to (A10) were synthesized in the same manner.

The structural formulae, composition ratios (molar ratios), weight-average molecular weights, and dispersion degrees of the polymer compounds (A1) to (A10) are shown in the following Table 1 and Table 2, and the structural formulae, composition ratios (molar ratios), weight-average molecular weights, and dispersion degrees of comparative polymer compounds (R₁) to (R₄) used in comparative examples are shown in the following Table 3.

TABLE 1

| | | Composition | Weight-Average | |
|---|---|---|---|---|
| Polymer | | Ratio | Molecular | Dispersion |
| Compound | Chemical Formula | (molar ratio) | Weight | Degree |
| Polymer Compound (A1) | 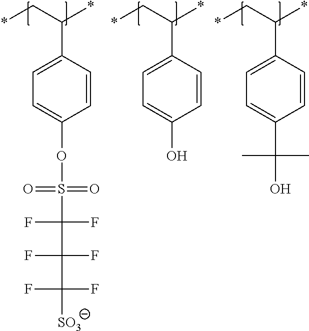 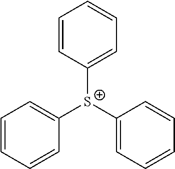 [SMILES: c1ccc([S+](c2ccccc2)c2ccccc2)cc1] | 10/70/20 | 6500 | 1.45 |
| Polymer Compound (A2) | 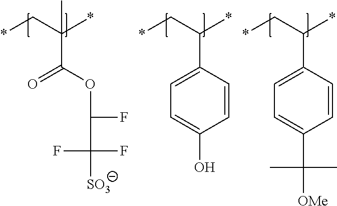 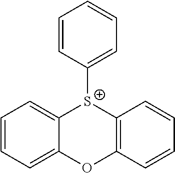 [SMILES: c1ccc([S+]2c3ccccc3Oc3ccccc32)cc1] | 10/70/20 | 4800 | 1.52 |
| Polymer Compound (A3) | 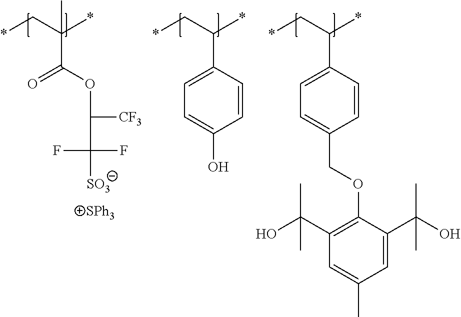 | 5/70/25 | 3900 | 1.67 |
| Polymer Compound (A4) | 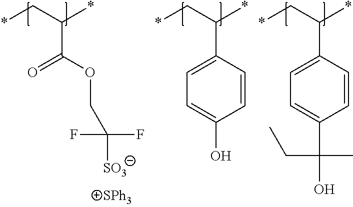 | 10/65/25 | 5400 | 1.53 |
| Polymer Compound (A5) | 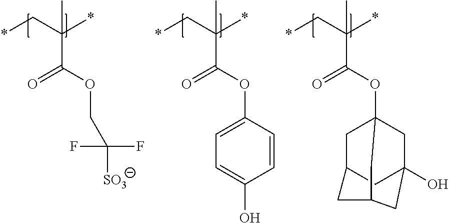 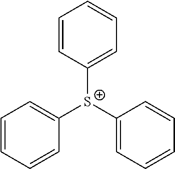 [SMILES: c1ccc([S+](c2ccccc2)c2ccccc2)cc1] | 20/50/30 | 9500 | 1.62 |

TABLE 2

| | | | Weight- | |
|---|---|---|---|---|
| | | Composition | Average | Dis- |
| Polymer | | Ratio | Molecular | persion |
| Compound | Chemical Formula | (molar ratio) | Weight | Degree |
| Polymer Compound (A6) | 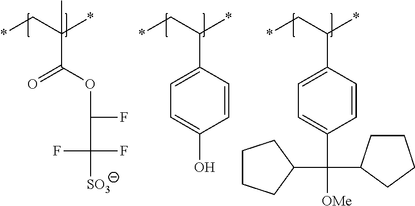 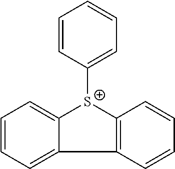 [SMILES: c1ccc(-[s+]2c3ccccc3c3ccccc32)cc1] | 15/50/35 | 8800 | 1.45 |
| Polymer Compound (A7) | 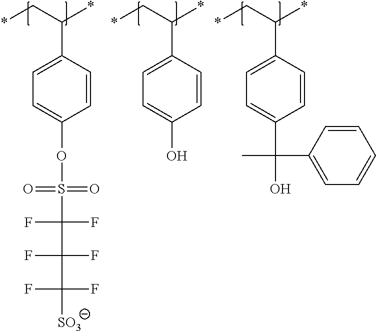 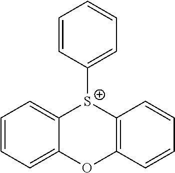 [SMILES: c1ccc([S+]2c3ccccc3Oc3ccccc32)cc1] | 15/50/35 | 12000 | 1.13 |
| Polymer Compound (A8) | 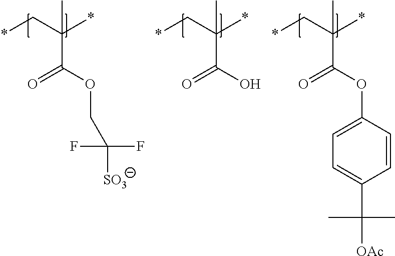 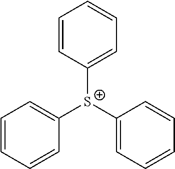 [SMILES: c1ccc([S+](c2ccccc2)c2ccccc2)cc1] | 10/50/40 | 5600 | 1.32 |
| Polymer Compound (A9) | 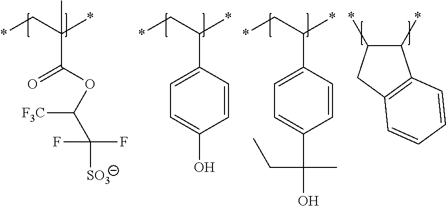 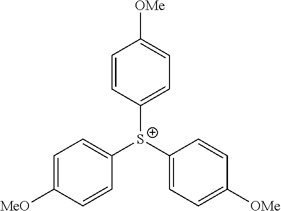 [SMILES: COc1ccc([S+](c2ccc(OC)cc2)c2ccc(OC)cc2)cc1] | 10/50/30/10 | 6600 | 1.83 |
| Polymer Compound (A10) | 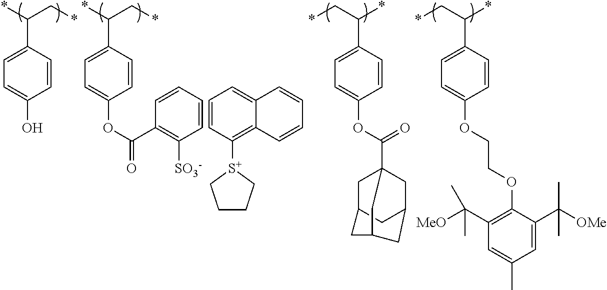 | 50/10/10/30 | 7700 | 1.53 |

TABLE 3

| | | Composition | Weight-Average | |
|---|---|---|---|---|
| Polymer | | Ratio | Molecular | Dispersion |
| Compound | Chemical Formula | (molar ratio) | Weight | Degree |
| Comparative Polymer Compound (R1) | 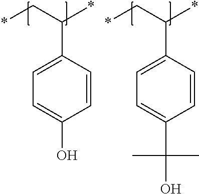 | 70/30 | 4500 | 1.52 |
| Comparative Polymer Compound (R2) | 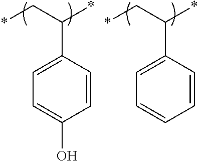 | 90/10 | 8000 | 1.51 |
| Comparative Polymer Compound (R3) | 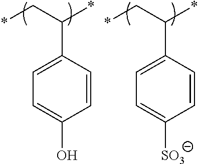 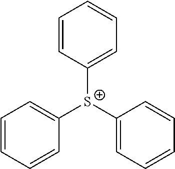 [SMILES: c1ccc([S+](c2ccccc2)c2ccccc2)cc1] | 85/15 | 7000 | 1.45 |
| Comparative Polymer Compound (R4) | 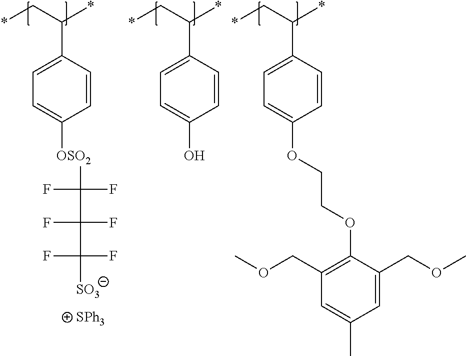 | 10/65/25 | 7000 | 1.45 |

### Example 1E

### (1) Preparation of Support

A chromium oxide-deposited 6-inch silicon wafer (a wafer subjected to a shielding film treatment for use in a usual photo mask blank) was prepared.

### (2) Preparation of Resist Coating Liquid

(Coating Liquid Composition of Negative
Tone Resist Composition N1)

| | |
|---|---|
| Polymer Compound (A1) | 6.04 g |
| Tetrabutylammonium Hydroxide (basic compound) | 0.04 g |
| 2-Hydroxy-3-Naphthoic Acid (organic carboxylic acid) | 0.11 g |
| Surfactant PF6320 (manufactured by OMNOVA Solutions | 0.005 g |
| Inc.) | |
| Propylene Glycol Monomethyl Ether Acetate (solvent) | 75.0 g |
| Propylene Glycol Monomethyl Ether (solvent) | 18.8 g |

The composition solution was subjected to microfiltration with a polytetrafluoroethylene filter having a hole diameter of 0.04 m to obtain a resist coating liquid.

### (3) Formation of Resist Film

The 6-inch silicon wafer was coated with the resist coating liquid using a spin coater Mark 8 manufactured by Tokyo Electron Limited, and dried on a hot plate for 90 seconds at 110° C. to obtain a resist film having a thickness of 50 nm. That is, a resist-coated mask blank was obtained.

### (4) Production of Negative Tone Resist Pattern

Pattern irradiation was performed on the resist film using an electron beam drawing apparatus (ELS-7500 manufactured by ELIONIX INC., acceleration voltage: 50 KeV). After the irradiation, heating was performed on a hot plate for 90 seconds at 120° C., dipping was performed for 60 seconds using a 2.38 mass % tetramethylammonium hydroxide (TMAH) aqueous solution. Then, rinsing was performed with water for 30 seconds, and drying was performed.

### (5) Evaluation of Resist Pattern

The obtained pattern was evaluated through the following method, with respect to sensitivity, resolving power, pattern shape, line edge roughness (LER) performance, scum reducing property, PEB time dependence. PED stability, in-plane uniformity of line width (CDU), and dry etching resistance.

[Sensitivity]

A cross-sectional shape of the obtained pattern was observed using a scanning electron microscope (S-4300 manufactured by Hitachi, Ltd.). An exposure amount (electron beam irradiation amount) when a resist pattern (line:space=1:1) having a line width of 50 nm was resolved was set as sensitivity. The smaller the value thereof, the higher the sensitivity.

[Resolving Power]

Marginal resolving power (minimum line width in which a line and a space were separately resolved) in the exposure amount (electron beam irradiation amount) indicating the sensitivity was set as LS resolving power (nm).

[Pattern Shape]

A cross-sectional shape of a line and space pattern (1:1) having a line width of 50 nm in the exposure amount (electron beam irradiation amount) indicating the sensitivity was observed using a scanning electron microscope (S-4300 manufactured by Hitachi, Ltd.). In the cross-sectional shape of the line pattern, a shape of which a ratio expressed by [a line width in a top portion (surface portion) of the line pattern/a line width in a middle portion (a position in a half height of a height of the line pattern) of the line pattern] was 1.2 or greater was evaluated as a “reversed taper”, a shape of which the ratio was equal to or greater than 1.05 and less than 1.2 was evaluated as a “slightly reversed taper”, and a shape of which the ratio was less than 1.05 was evaluated as a “rectangular shape”.

[Line Edge Roughness (LER)]

A line and space pattern (1:1) having a line width of 50 nm was formed with the irradiation amount (electron beam irradiation amount) indicating the sensitivity. With respect to arbitrary 30 points included in 10 μm in a length direction thereof, a distance from a reference line that had to have an edge to the edge was measured using a scanning electron microscope (S-9220 manufactured by Hitachi, Ltd.). Also, standard deviation of the distance was obtained so as to calculate 3σ. The smaller the value, the better the performance.

[Dry Etching Resistance]

A resist film formed by performing full irradiation with the irradiation amount (electron beam irradiation amount) indicating the sensitivity was subjected to dry etching for 30 seconds using an Ar/C₄F6/O₂ gas (a mixed gas having a volume ratio of 100/4/2) with HITACHI U-621. Then, a residual resist film rate was measured and used as an indicator of dry etching resistance.

Very Good: The residual film rate was 95% or greater.

Good: The residual film rate was equal to or greater than 90% and less than 95%.

Poor: The residual film rate was less than 90%

[Scum Evaluation]

A line pattern was formed in the same manner as in the formation of a line pattern in the evaluation of the above-described [Pattern Shape]. Then, a cross-sectional SEM image was acquired using a scanning electron microscope (S-4800 manufactured by Hitachi High-Technologies Corporation) to observe residues in a space part and perform evaluation as follows.

A: No scum is shown.

B: Scum is shown, but the patterns are not connected to each other.

C: Scum is shown, and the patterns are partially connected to each other.

[PEB Time Dependence]

An exposure amount in which lines and spaces of 50 nm (1:1) were reproduced during post exposure baking (PEB) for 90 seconds at 120° C. was set as an optimum exposure amount. Lines and spaces obtained in cases where post exposure baking after exposure with the optimum exposure amount was performed for +10 seconds (100 seconds) and for −10 seconds (80 seconds), respectively, were measured to obtain line widths L1 and L2 thereof. PEB time dependence (PEBS) was defined as a variation in the line width per second of PEB time change, and calculated through the following expression.

PEB Time Dependence (nm/sec)=|L1−L2|/20

The smaller the value, the better due to a reduced change in performance with respect to a time change.

[Post Exposure Time Delay (PED) Stability Evaluation]

With an exposure amount in which the line width dimension of a line and space pattern (1:1) was 50 nm, a line width dimension (1h) on a wafer rapidly subjected to a PEB treatment after exposure and a line width dimension (5.0h) on a wafer subjected to a PEB treatment after 5 hours from exposure were measured to calculate a rate of the change of the line width through the following expression.

Rate of Change of Line Width (%)=|ΔCD(5.0h−0h)| nm/50 nm

The smaller the value, the better the performance, and this was used as an indicator of PED stability.

[In-Plane Uniformity of Line Width (CDU)]

With an exposure amount in which the line width of a line and space pattern (1:1) was 50 nm, line widths of 100 line patterns among the line patterns were measured to obtain a value (3σ) three times the standard deviation (a) of an average value calculated from the measurement results to thus evaluate in-plane uniformity of line width (CDU) (nm). The smaller the value of 30 obtained as described above, the higher the in-plane uniformity (CDU) of each line CD formed on the resist film.

### Examples 2E to 17E and Comparative Examples 1E to 4E

Resist coating liquids (negative tone resist compositions N2 to N17 and comparative negative tone resist compositions NR1 to NR4) were prepared in the same manner as in the preparation of Example 1E, except that the prescription of the resist coating liquid was changed to prescriptions described in the following Table 4 and Table 5 in the preparation of Example 1E, negative tone resist patterns were produced in the same manner as in Example 1E, and the obtained patterns were evaluated (Examples 2E to 17E and Comparative Examples 1E to 4E).

TABLE 4

| | Polymer | Basic | | |
|---|---|---|---|---|
| Compo- | Com- | Com- | Surfac- | |
| sition | pound | pound | tant | Solvent |
| N1 | A1 | B1 | W-1 | S1/S2 |
| | (6.04 g) | (0.04 g) | (0.005 g) | (75.0 g/18.8 g) |
| N2 | A2 | B1 | W-1 | S1/S3 |
| | (6.04 g) | (0.04 g) | (0.005 g) | (75.0 g/18.8 g) |
| N3 | A3 | B1 | W-1 | S2/S3 |
| | (6.04 g) | (0.04 g) | (0.005 g) | (75.0 g/18.8 g) |
| N4 | A4 | B1 | W-1 | S2/S7 |
| | (6.04 g) | (0.04 g) | (0.005 g) | (75.0 g/18.8 g) |
| N5 | A5 | B1 | W-1 | S2/S1 |
| | (6.04 g) | (0.04 g) | (0.005 g) | (75.0 g/18.8 g) |
| N6 | A6 | B1 | W-1 | S2/S1 |
| | (6.04 g) | (0.04 g) | (0.005 g) | (75.0 g/18.8 g) |
| N7 | A7 | B1 | W-1 | S2/S1 |
| | (6.04 g) | (0.04 g) | (0.005 g) | (75.0 g/18.8 g) |
| N8 | A8 | B1 | W-1 | S2/S1 |
| | (6.04 g) | (0.04 g) | (0.005 g) | (75.0 g/18.8 g) |
| N9 | A9 | B1 | W-1 | S2/S1 |
| | (6.04 g) | (0.04 g) | (0.005 g) | (75.0 g/18.8 g) |
| N10 | A10 | B1 | W-1 | S2/S1 |
| | (6.04 g) | (0.04 g) | (0.005 g) | (75.0 g/18.8 g) |
| N11 | A1/R2 | B2 | None | S2/S1 |
| | (5.04 g/1.0 g) | (0.04 g) | | (75.0 g/18.8 g) |
| N12 | A1 | B3 | W-2 | S1/S2/S6 |
| | (6.04 g) | (0.04 g) | (0.005 g) | (50.0 g/25.0 g/18.8 g) |
| N13 | A1 | B4 | W-2 | S1/S2/S5 |
| | (6.04 g) | (0.04 g) | (0.005 g) | (50.0 g/25.0 g/18.8 g) |
| N14 | A1 | B5 | W-3 | S1/S2/S4 |
| | (6.04 g) | (0.04 g) | (0.005 g) | (50.0 g/25.0 g/18.8 g) |
| N15 | A1 | B6 | None | S2/S1 |
| | (6.04 g) | (0.04 g) | | (75.0 g/18.8 g) |
| N16 | A1 | B7 | W-1 | S2/S1 |
| | (5.15 g) + | (0.04 g) | (0.005 g) | (75.0 g/18.8 g) |
| | CL-3 (0.89 g) | | | |
| N17 | A1(5.57 g) + | B8 | W-1 | S2/S1 |
| | A1′ (0.47 g) | (0.04 g) | (0.005 g) | (75.0 g/18.8 g) |

TABLE 5

| | Photoacid | Polymer | Basic | | Crosslinking | |
|---|---|---|---|---|---|---|
| Composition | Generator | Compound | Compound | Surfactant | Agent | Solvent |
| Comparative | A1′ | R1 | B1 | W-1 | None | S2/S1 |
| Composition | (0.47 g) | (5.1 g) | (0.04 g) | (0.005 g) | | (75.0 g/18.8 g) |
| NR1 | | | | | | |
| Comparative | A1′ | R2 | B1 | W-1 | CL-3 | S1/S3 |
| Composition | (0.47 g) | (4.21 g) | (0.04 g) | (0.005 g) | (0.89 g) | (75.0 g/18.8 g) |
| NR2 | | | | | | |
| Comparative | None | R3 | B1 | W-1 | CL-3 | S2/S3 |
| Composition | | (4.68 g) | (0.04 g) | (0.005 g) | (0.89 g) | (75.0 g/18.8 g) |
| NR3 | | | | | | |
| Comparative | None | R4 | B1 | W-1 | None | S2/S3 |
| Composition | | (6.04 g) | (0.04 g) | (0.005 g) | | (75.0 g/18.8 g) |
| NR4 | | | | | | |

Abbreviated material names other than the names described above, used in the examples or comparative examples, will be described below.

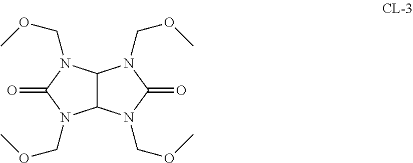

[Basic Compound]

B1: Tetrabutylammonium Hydroxide

B2: Tri(n-octyl)amine

B3: 2,4,5-triphenylimidazole

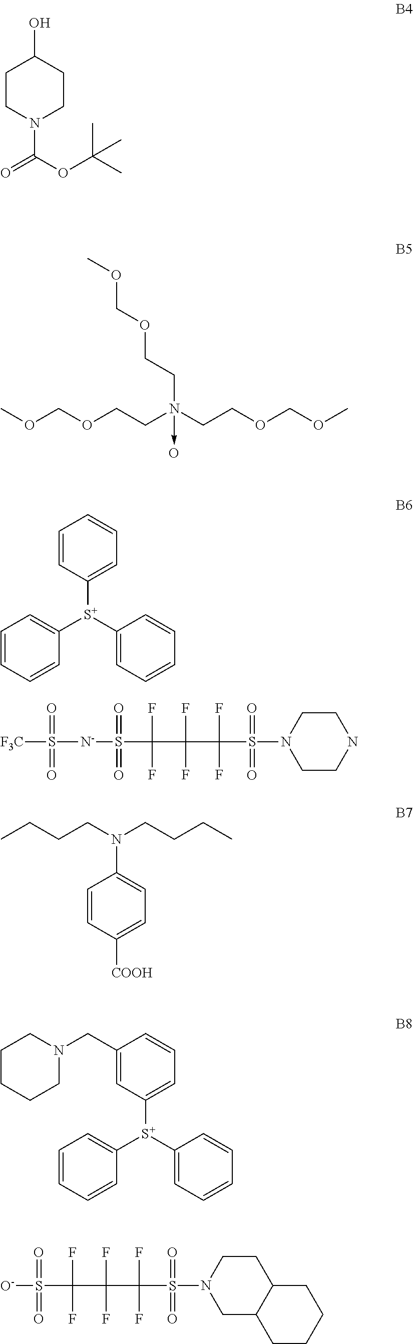

[Surfactant]

W-1: PF6320 (manufactured by OMNOVA Solutions Inc.)

W-2: MEGAFACE F176 (manufactured by DIC Corporation; fluorine-based)

W-3: Polysiloxane Polymer KP-341 (manufactured by Shin-Etsu Chemical Co., Ltd.; silicon-based)

[Solvent]

S1: Propylene Glycol Monomethyl Ether Acetate (1-methoxy-2-acetoxypropane)

S2: Propylene Glycol Monomethyl Ether (1-methoxy-2-propanol)

S3: 2-Heptanone

S4: Ethyl Lactate

S5: Cyclohexanone

S6: γ-Butyrolactone

S7: Propylene Carbonate

[Photoacid Generator]

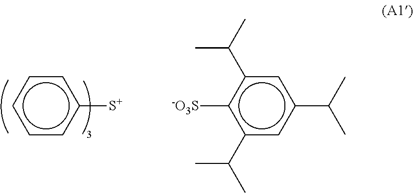

The evaluation results are shown in Table 6.

TABLE 6

| | | | Resolving | | | | Dry | PEB Time | PED | |
|---|---|---|---|---|---|---|---|---|---|---|
| | | Sensitivity | Power | Pattern | LER | | Etching | Dependence | Stability | CDU |
| Example | Composition | (μC/cm²) | (nm) | Shape | (nm) | Scum | Resistance | (nm/sec) | (%) | (nm) |
| 1E | N1 | 10.2 | 25 | Rectangular | 4.0 | A | Very Good | 0.2 | 0.2 | 3.5 |
| | | | | Shape | | | | | | |
| 2E | N2 | 10.0 | 25 | Rectangular | 4.0 | A | Very Good | 0.4 | 0.4 | 3.6 |
| | | | | Shape | | | | | | |
| 3E | N3 | 10.2 | 23 | Rectangular | 4.0 | A | Very Good | 0.4 | 0.4 | 3.5 |
| | | | | Shape | | | | | | |
| 4E | N4 | 10.2 | 25 | Rectangular | 4.0 | A | Very Good | 0.4 | 0.4 | 3.5 |
| | | | | Shape | | | | | | |
| 5E | N5 | 10.3 | 30 | Rectangular | 4.0 | A | Very Good | 0.4 | 0.4 | 3.7 |
| | | | | Shape | | | | | | |
| 6E | N6 | 10.3 | 25 | Rectangular | 4.0 | A | Very Good | 0.4 | 0.4 | 3.6 |
| | | | | Shape | | | | | | |
| 7E | N7 | 11.3 | 25 | Rectangular | 4.0 | A | Very Good | 0.2 | 0.2 | 3.5 |
| | | | | Shape | | | | | | |
| 8E | N8 | 11.2 | 25 | Rectangular | 4.0 | A | Very Good | 0.4 | 0.4 | 3.7 |
| | | | | Shape | | | | | | |
| 9E | N9 | 12.8 | 25 | Rectangular | 4.0 | A | Very Good | 0.4 | 0.4 | 3.5 |
| | | | | Shape | | | | | | |
| 10E | N10 | 10.2 | 23 | Rectangular | 4.0 | A | Very Good | 0.4 | 0.4 | 3.6 |
| | | | | Shape | | | | | | |
| 11E | N11 | 10.3 | 25 | Rectangular | 4.0 | A | Very Good | 0.3 | 0.3 | 3.5 |
| | | | | Shape | | | | | | |
| 12E | N12 | 10.2 | 25 | Rectangular | 4.0 | A | Very Good | 0.2 | 0.2 | 3.5 |
| | | | | Shape | | | | | | |
| 13E | N13 | 10.3 | 25 | Rectangular | 4.0 | A | Very Good | 0.2 | 0.2 | 3.5 |
| | | | | Shape | | | | | | |
| 14E | N14 | 10.3 | 25 | Rectangular | 4.0 | A | Very Good | 0.2 | 0.2 | 3.6 |
| | | | | Shape | | | | | | |
| 15E | N15 | 10.3 | 25 | Rectangular | 4.0 | A | Very Good | 0.2 | 0.2 | 3.5 |
| | | | | Shape | | | | | | |
| 16E | N16 | 12.3 | 25 | Rectangular | 4.0 | A | Very Good | 0.3 | 0.3 | 3.6 |
| | | | | Shape | | | | | | |
| 17E | N17 | 12.3 | 25 | Rectangular | 4.0 | A | Very Good | 0.3 | 0.3 | 3.5 |
| | | | | Shape | | | | | | |
| Comparative | Comparative | 14.8 | 50 | Slightly | 5.0 | C | Good | 0.8 | 0.8 | 4.3 |
| Example 1E | Composition | | | Reversed | | | | | | |
| | NR1 | | | taper | | | | | | |
| Comparative | Comparative | 14.8 | 50 | Slightly | 5.0 | C | Poor | 2.0 | 1.9 | 4.3 |
| Example 2E | Composition | | | Reversed | | | | | | |
| | NR2 | | | taper | | | | | | |
| Comparative | Comparative | 13.8 | 40 | Reversed | 5.0 | B | Poor | 1.1 | 1.2 | 4.2 |
| Example 3E | Composition | | | taper | | | | | | |
| | NR3 | | | | | | | | | |
| Comparative | Comparative | 13.8 | 30 | Rectangular | 5.0 | A | Good | 0.6 | 0.6 | 4.5 |
| Example 4E | Composition | | | Shape | | | | | | |
| | NR4 | | | | | | | | | |

From the results shown in Table 6, it is found that the radiation-sensitive or actinic ray-sensitive resin compositions of Examples 1E to 17E containing the polymer compound (A) are more excellent in all of sensitivity, resolving power, pattern shape, LER performance, and dry etching resistance in electron beam exposure with less generation of scum, have lower PEB time dependence, and are more excellent in PED stability, than the radiation-sensitive or actinic ray-sensitive resin compositions of Comparative Examples 1E to 4E not containing the polymer compound (A).

### Examples 1F to 6F and Comparative Examples 1F to 4F

A negative tone resist composition shown in Table 7 to be described below was subjected to microfiltration with a polytetrafluoroethylene filter having a hole diameter of 0.04 μm to obtain a resist coating liquid.

(Formation of Resist Film)

The above-described 6-inch silicon wafer was coated with the resist coating liquid using a spin coater Mark 8 manufactured by Tokyo Electron Limited, and dried on a hot plate for 90 seconds at 110° C. to obtain a resist film having a thickness of 50 nm. That is, a resist-coated mask blank was obtained.

(Resist Evaluation)

The obtained resist film was evaluated through the following method, with respect to sensitivity, resolving power, pattern shape, line edge roughness (LER) performance, scum reducing property, PED stability, in-plane uniformity of line width (CDU), and dry etching resistance.

[Sensitivity]

The obtained resist film was exposed via a reflective-type mask with a line and space pattern (1:1) having a line width of 50 nm using EUV light (wavelength: 13 nm) while the exposure amount was changed by 0.1 mJ/cm² in a range of 0 to 20.0 mJ/cm². Then, the film was baked for 90 seconds at 110° C. Thereafter, development was performed using a 2.38 mass % tetramethylammonium hydroxide (TMAH) aqueous solution.

An exposure amount (extreme ultraviolet exposure amount) in which a line-and-space (1:1) mask pattern having a line width of 50 nm was reproduced was set as sensitivity. The smaller the value thereof, the higher the sensitivity.

[Resolving Power]

Marginal resolving power (minimum line width in which a line and a space (line:space=1:1) were separately resolved) in the exposure amount indicating the sensitivity was set as resolving power (nm).

[Pattern Shape]

A cross-sectional shape of a line and space pattern (1:1) having a line width of 50 nm in the exposure amount indicating the sensitivity was observed using a scanning electron microscope (S-4300 manufactured by Hitachi, Ltd.). In the cross-sectional shape of the line pattern, a shape of which a ratio expressed by [a line width in a top portion (surface portion) of the line pattern/a line width in a middle portion (a position in a half height of a height of the line pattern) of the line pattern] was 1.5 or greater was evaluated as a “reversed taper”, a shape of which the ratio was equal to or greater than 1.2 and less than 1.5 was evaluated as a “slightly reversed taper”, and a shape of which the ratio was less than 1.2 was evaluated as a “rectangular shape”.

[Line Edge Roughness (LER)]

A line and space pattern (1:1) having a line width of 50 nm was formed with the exposure amount indicating the sensitivity. With respect to arbitrary 30 points in 50 μm in a length direction thereof, a distance from a reference line that had to have an edge was measured using a scanning electron microscope (S-9220 manufactured by Hitachi, Ltd.). Also, standard deviation of the distance was obtained so as to calculate 3σ. The smaller the value, the better the performance.

[Scum Evaluation]

A line pattern was formed in the same manner as in the formation of a line pattern in the evaluation of the above-described [Pattern Shape]. Then, a cross-sectional SEM image was acquired using a scanning electron microscope (S-4800 manufactured by Hitachi High-Technologies Corporation) to observe residues in a space part and perform evaluation as follows.

A: No scum is shown.

B: Scum is shown, but the patterns are not connected to each other.

C: Scum is shown, and the patterns are partially connected to each other.

[Post Exposure Time Delay (PED) Evaluation]

With an exposure amount in which the line width dimension of a line and space pattern (1:1) was 50 nm, a line width dimension (0h) on a wafer rapidly subjected to a PEB treatment after exposure and a line width dimension (5.0h) on a wafer subjected to a PEB treatment after 5 hours from exposure were measured to calculate a rate of the change of the line width through the following expression.

Rate of Change of Line Width (%)=|ΔCD(5.0h−0h)| nm/50 nm

The smaller the value, the better the performance, and this was used as an indicator of PED stability.

[Dry Etching Resistance]

A resist film formed by performing full irradiation with the exposure amount (extreme ultraviolet exposure amount) indicating the sensitivity was subjected to dry etching for 30 seconds using an Ar/C₄F1′O₂ gas (a mixed gas having a volume ratio of 100/4/2) with HITACHI U-621. Then, a residual resist film rate was measured and used as an indicator of dry etching resistance.

Very Good: The residual film rate was 95% or greater.

Good: The residual film rate was equal to or greater than 90% and less than 95%.

Poor: The residual film rate was less than 90%.

[In-Plane Uniformity of Line Width (CDU)]

With an exposure amount in which the line width of a line and space pattern (1:1) was 50 nm, line widths of 100 line patterns among the line patterns were measured to obtain a value (3σ) three times the standard deviation (a) of an average value calculated from the measurement results to thus evaluate in-plane uniformity of line width (CDU) (nm). The smaller the value of 3σ obtained as described above, the higher the in-plane uniformity (CDU) of each line CD formed on the resist film.

The results of the evaluations are shown in Table 7.

TABLE 7

| | | | Resolving | | | | PED | Dry | |
|---|---|---|---|---|---|---|---|---|---|
| | | Sensitivity | Power | Pattern | LER | | Stability | Etching | CDU |
| | Composition | (mJ/cm²) | (nm) | Shape | (nm) | Scum | (%) | Resistance | (nm) |
| 1F | N1 | 12.8 | 25 | Rectangular | 4.0 | A | 0.2 | Very Good | 3.5 |
| | | | | Shape | | | | | |
| 2F | N2 | 12.7 | 25 | Rectangular | 4.0 | A | 0.2 | Very Good | 3.6 |
| | | | | Shape | | | | | |
| 3F | N3 | 12.8 | 23 | Rectangular | 4.0 | A | 0.4 | Very Good | 3.5 |
| | | | | Shape | | | | | |
| 4F | N6 | 14.8 | 35 | Rectangular | 4.0 | A | 0.4 | Very Good | 3.5 |
| | | | | Shape | | | | | |
| 5F | N8 | 12.8 | 30 | Rectangular | 4.0 | A | 0.4 | Very Good | 3.7 |
| | | | | Shape | | | | | |
| 6F | N9 | 14.7 | 25 | Rectangular | 4.0 | A | 0.4 | Good | 3.5 |
| | | | | Shape | | | | | |
| Comparative | Comparative | 15.8 | 50 | Slightly | 5.0 | C | 1.0 | Good | 4.3 |
| Example 1F | Composition | | | Reversed | | | | | |
| | NR1 | | | taper | | | | | |
| Comparative | Comparative | 15.8 | 50 | Slightly | 5.0 | C | 2.0 | Poor | 4.4 |
| Example 2F | Composition | | | Reversed | | | | | |
| | NR2 | | | taper | | | | | |
| Comparative | Comparative | 15.5 | 40 | Reversed | 5.0 | B | 1.0 | Poor | 4.3 |
| Example 3F | Composition | | | taper | | | | | |
| | NR3 | | | | | | | | |
| Comparative | Comparative | 15.5 | 35 | Rectangular | 5.0 | A | 0.6 | Good | 4.6 |
| Example 4F | Composition | | | Shape | | | | | |
| | NR4 | | | | | | | | |

From the results shown in Table 7, it is found that the radiation-sensitive or actinic ray-sensitive resin compositions of Examples 1F to 6F containing the polymer compound (A) are more excellent in all of sensitivity, resolving power, pattern shape, and LER performance in EUV exposure with less generation of scum, and are more excellent in PED stability, than the radiation-sensitive or actinic ray-sensitive resin compositions of Comparative Examples 1F to 4F not containing the polymer compound (A).

### Examples 1C to 6C and Comparative Examples 1C to 4C

### (1) Preparation of Resist Composition and Production of Resist Film

A composition shown in Table 8 to be described below was subjected to microfiltration with a membrane filter having a hole diameter of 0.1 μm to obtain a resist composition.

With this resist composition, a 6-inch Si wafer previously subjected to a hexamethyldisilazane (HMDS) treatment was coated using a spin coater Mark 8 manufactured by Tokyo Electron Limited, and dried on a hot plate for 90 seconds at 100° C. to obtain a resist film having a thickness of 50 nm.

### (2) EB Exposure and Development

Using an electron beam drawing apparatus (HL750 manufactured by Hitachi, Ltd., acceleration voltage: 50 KeV), pattern irradiation was performed on the wafer on which the resist film obtained in the paragraph (1) was formed. At this time, drawing was performed so as to form lines and spaces (1:1). The wafer after the drawing was heated on a hot plate for 60 seconds at 110° C. Then, an organic developer described in Table 8 was developed for 30 seconds by paddling, and rinsing was performed using a rinse liquid described in Table 8. Next, the wafer was rotated at the rotation speed of 4,000 rpm for 30 seconds, and then heated for 90 seconds at 90° C. to obtain a resist pattern with a line and space pattern (1:1) having a line width of 50 nm.

The obtained resist pattern was evaluated in the same manner as in Example 1E, with respect to sensitivity, resolving power, pattern shape, line edge roughness (LER), PEB time dependence, in-plane uniformity of line width (CDU), and PED stability. The results of the evaluations are shown in Table 8.

TABLE 8

| | | | | | Resolving | | | PEB | | |
|---|---|---|---|---|---|---|---|---|---|---|
| | | | Rinse | Sensitivity | Power | Pattern | LER | Time | PED | CDU |
| Example | Composition | Developer | Liquid | (μC/cm²) | (nm) | Shape | (nm) | Dependence | Stability | (nm) |
| 1C | N1 | S8 | S11 | 15.0 | 25 | Rectangular | 4.1 | 0.2 | 0.2 | 3.5 |
| | | | | | | Shape | | | | |
| 2C | N2 | S8 | S11 | 15.0 | 25 | Rectangular | 4.1 | 0.2 | 0.2 | 3.6 |
| | | | | | | Shape | | | | |
| 3C | N3 | S9 | S12 | 15.6 | 22 | Rectangular | 4.0 | 0.2 | 0.2 | 3.5 |
| | | | | | | Shape | | | | |
| 4C | N6 | S10 | S11 | 15.2 | 25 | Rectangular | 4.2 | 0.2 | 0.2 | 3.5 |
| | | | | | | Shape | | | | |
| 5C | N8 | S8 | S11 | 15.8 | 25 | Rectangular | 4.0 | 0.2 | 0.2 | 3.7 |
| | | | | | | Shape | | | | |
| 6C | N9 | S9 | S10 | 15.2 | 25 | Rectangular | 4.0 | 0.2 | 0.2 | 3.5 |
| | | | | | | Shape | | | | |
| Comparative | Comparative | S8 | S11 | 15.2 | 40 | Slightly | 5.0 | 0.8 | 0.7 | 4.3 |
| Example 1C | Composition | | | | | Reversed | | | | |
| | NR1 | | | | | taper | | | | |
| Comparative | Comparative | S8 | S11 | 15.8 | 40 | Slightly | 5.0 | 2.1 | 2.0 | 4.3 |
| Example 2C | Composition | | | | | Reversed | | | | |
| | NR2 | | | | | taper | | | | |
| Comparative | Comparative | S8 | S11 | 15.2 | 30 | Reversed | 5.0 | 1.1 | 1.0 | 4.4 |
| Example 3C | Composition | | | | | taper | | | | |
| | NR3 | | | | | | | | | |
| Comparative | Comparative | S8 | S11 | 15.2 | 25 | Rectangular | 5.0 | 0.4 | 0.4 | 4.5 |
| Example 4C | Composition | | | | | Shape | | | | |
| | NR4 | | | | | | | | | |

Abbreviated component names other than the names described above, used in the examples or comparative examples, will be described below.

<Developer and Rinse Liquid>

S8: Butyl Acetate

S9: Pentyl Acetate

S10: Anisole

S11: I-Hexanol

S12: Decane

From the results shown in Table 8, it is found that the radiation-sensitive or actinic ray-sensitive resin compositions of Examples 1C to 6C containing the polymer compound (A) are more excellent in all of sensitivity, resolving power, pattern shape, and LER performance in EB exposure, have lower PEB time dependence, and are more excellent in PED stability, than the radiation-sensitive or actinic ray-sensitive resin compositions of Comparative Examples 1C to 4C not containing the polymer compound (A).

What is claimed is:

1. A radiation-sensitive or actinic ray-sensitive resin composition comprising:
a polymer compound (A) including a structural part (a) that is decomposed by irradiation with actinic rays or radiation to generate an acid anion on a side chain and a repeating unit (b) that is represented by the following Formula (I), 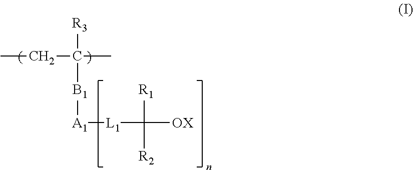
in the formula, R₃ represents a hydrogen atom, an organic group, or a halogen atom, A₁ represents an aromatic ring group or an alicyclic group, R₁ and R₂ each independently represent an alkyl group, a cycloalkyl group, or an aryl group, at least two of A₁, R₁, or R₂ may be bonded to each other to form a ring, B₁ and L₁ each independently represent a single bond or a divalent linking group, X represents a hydrogen atom or an organic group, n represents an integer of 1 or greater, and in a case where n represents an integer of 2 or greater, a plurality of L₁'s, a plurality of R₁'s, a plurality of R₂'s, and a plurality of X's may be the same as or different from each other, respectively.

2. The radiation-sensitive or actinic ray-sensitive resin composition according to claim 1,
wherein the structural part (a) that is decomposed by irradiation with actinic rays or radiation to generate an acid anion on a side chain has a sulfonium salt structure that is represented by the following Formula (PZI) or an iodonium salt structure that is represented by the following Formula (PZII), 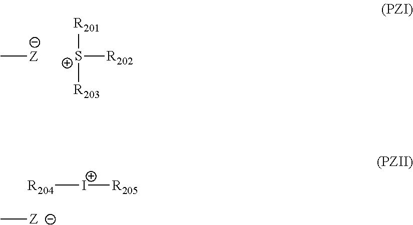
in Formula (PZI), R₂₀₁ to R₂₀₃ each independently represent an organic group, two of R₂₀₁ to R₂₀₃ may be bonded to each other to form a ring structure, the ring structure may include an oxygen atom, a sulfur atom, an ester bond, an amido bond, or a carbonyl group, and Z⁻ represents an acid anion that is generated by decomposition by irradiation with actinic rays or radiation, and
in Formula (PZII), R₂₀₄ and R₂₀₅ each independently represent an aryl group, an alkyl group, or a cycloalkyl group, the aryl group of R₂₀₄ and R₂₀₅ may be an aromatic hetero ring group having an oxygen atom, a nitrogen atom, or a sulfur atom, and Z⁻ represents an acid anion that is generated by decomposition by irradiation with actinic rays or radiation.

3. The radiation-sensitive or actinic ray-sensitive resin composition according to claim 2,
wherein the structural part (a) that is decomposed by irradiation with actinic rays or radiation to generate an acid anion on a side chain has the sulfonium salt structure that is represented by Formula (PZI).

4. The radiation-sensitive or actinic ray-sensitive resin composition according to claim 1,
wherein the polymer compound (A) has a repeating unit (A1) including a structural part (a) that is decomposed by irradiation with actinic rays or radiation to generate an acid anion on a side chain.

5. The radiation-sensitive or actinic ray-sensitive resin composition according to claim 4,
wherein the repeating unit (A1) including the structural part (a) that is decomposed by irradiation with actinic rays or radiation to generate an acid anion on a side chain is a repeating unit that is represented by the following Formula (4), and 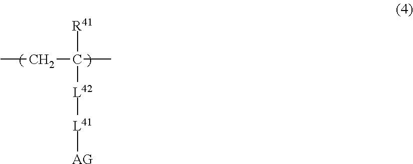
in the formula, R⁴¹ represents a hydrogen atom or a methyl group, L⁴¹ represents a single bond or a divalent linking group, L⁴² represents a divalent linking group, and AG represents a structural part that is decomposed by irradiation with actinic rays or radiation to generate an acid anion on a side chain.

6. The radiation-sensitive or actinic ray-sensitive resin composition according to claim 1,
wherein the polymer compound (A) further contains a repeating unit (c) that is represented by the following Formula (II), and 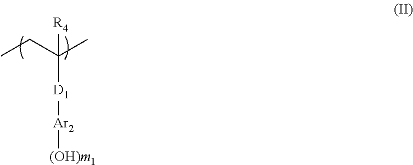
in the formula, R₄ represents a hydrogen atom, an organic group, or a halogen atom, D₁ represents a single bond or a divalent linking group, Ar₂ represents an aromatic ring group, and m₁ represents an integer of 1 or greater.

7. The radiation-sensitive or actinic ray-sensitive resin composition according to claim 5,
wherein the polymer compound (A) further contains a repeating unit (c) that is represented by the following Formula (II), and 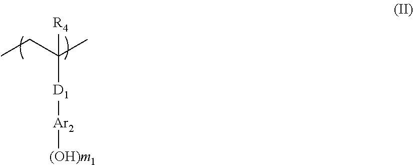
in the formula, R₄ represents a hydrogen atom, an organic group, or a halogen atom, D₁ represents a single bond or a divalent linking group, Ar₂ represents an aromatic ring group, and m₁ represents an integer of 1 or greater.

8. The radiation-sensitive or actinic ray-sensitive resin composition according to claim 1,
wherein the repeating unit (b) is represented by the following Formula (I-2), 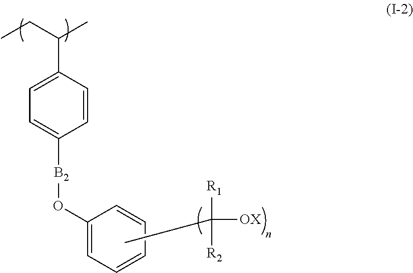
in the formula, R₁ and R₂ each independently represent an alkyl group, a cycloalkyl group, or an aryl group, B₂ represents a single bond or a divalent linking group, X represents a hydrogen atom or an organic group, n represents an integer of 1 or greater, and in a case where n represents an integer of 2 or greater, a plurality of R₁'s, a plurality of R₂'s, and a plurality of X's may be the same as or different from each other, respectively.

9. The radiation-sensitive or actinic ray-sensitive resin composition according to claim 6,
wherein the repeating unit (b) is represented by the following Formula (I-2), 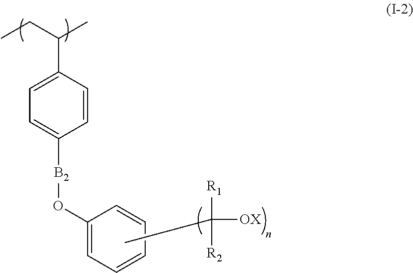
in the formula, R₁ and R₂ each independently represent an alkyl group, a cycloalkyl group, or an aryl group, B₂ represents a single bond or a divalent linking group, X represents a hydrogen atom or an organic group, n represents an integer of 1 or greater, and in a case where n represents an integer of 2 or greater, a plurality of R₁'s, a plurality of R₂'s, and a plurality of X's may be the same as or different from each other, respectively.

10. The radiation-sensitive or actinic ray-sensitive resin composition according to claim 7,
wherein the repeating unit (b) is represented by the following Formula (I-2), 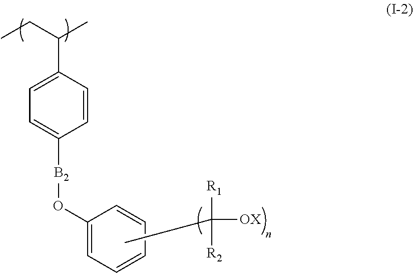
in the formula, R₁ and R₂ each independently represent an alkyl group, a cycloalkyl group, or an aryl group, B₂ represents a single bond or a divalent linking group, X represents a hydrogen atom or an organic group, n represents an integer of 1 or greater, and in a case where n represents an integer of 2 or greater, a plurality of R₁'s, a plurality of R₂'s, and a plurality of X's may be the same as or different from each other, respectively.

11. The radiation-sensitive or actinic ray-sensitive resin composition according to claim 1, that is a chemically amplified negative tone resist composition.

12. A resist film that is formed of the radiation-sensitive or actinic ray-sensitive resin composition according to claim 1.

13. A mask blank comprising:
the resist film according to claim 12.

14. A resist pattern forming method comprising:
exposing the resist film according to claim 12; and
developing the exposed resist film.

15. A resist pattern forming method comprising:
exposing the mask blank having the resist film according to claim 12; and
developing the exposed mask blank.

16. The resist pattern forming method according to claim 14,
wherein the exposure is performed using electron beams or extreme ultraviolet rays.

17. An electronic device manufacturing method comprising:
the resist pattern forming method according to claim 14.
